(19) United States
(12) Patent Application Publication
(10) Pub. No.: US 2026/0212075 A1
(43) Pub. Date: Jul. 23, 2026

(54) ENHANCED COMPUTATIONAL ENGINEERING METHODS WITH NOVEL GEOMETRIES

(71) Applicant: QOMPLX LLC, Reston, VA (US)

(72) Inventors: Jason Crabtree, Vienna, VA (US); Richard Kelley, Woodbridge, VA (US); Jason Hopper, Halifax (CA); David Park, Fairfax, VA (US)

(21) Appl. No.: 19/035,782

(22) Filed: Jan. 23, 2025

(51) Int. Cl. G06F 30/23

(52) U.S. Cl. CPC G06F 30/23

(57) ABSTRACT

The present invention discloses an advanced materials design platform that integrates novel geometric shapes, particularly small volume bodies of constant width (SVBOCW), into enhanced finite element analysis (FEA) for improved material modeling and design. The system generates and manipulates, and implements these novel shapes, incorporating them into multi-physics simulations with adaptive mesh refinement optimized for complex geometries and high-fidelity numerical accuracy. It enables seamless multi-scale modeling from atomic to macroscopic levels, leveraging the unique properties of SVBOCW to improve accuracy in quantum confinement effects and other nanoscale phenomena. The platform employs artificial intelligence, including reinforcement learning, to optimize material designs incorporating these novel geometries. A knowledge graph framework facilitates reasoning about material properties based on geometric structures. This innovative approach enhances the efficiency and accuracy of material simulations, potentially leading to breakthroughs in fields such as semiconductor design, energy storage, and advanced manufacturing.

### CROSS-REFERENCE TO RELATED APPLICATIONS

Priority is claimed in the application data sheet to the following patents or patent applications, each of which is expressly incorporated herein by reference in its entirety:
None.

### BACKGROUND OF THE INVENTION

### Field of the Art

The present invention is in the field of materials science and engineering, and more particularly to advanced computational systems for multi-scale modeling, simulation, and optimization of materials, structures, fluids and devices using numerical methods, machine learning and artificial intelligence, quantum computing, and novel geometric approaches in finite element analysis, computational fluid dynamics, and fluid-structure interactions.

### Discussion of the State of the Art

The current state of the art in materials science and engineering design platforms has made significant strides in recent years, leveraging advances in computational power, machine learning, and multi-scale modeling. These platforms typically integrate various simulation techniques, including density functional theory (DFT) for atomic-scale properties, molecular dynamics for nano-scale behavior, and finite element analysis (FEA) for macro-scale performance. Many incorporate machine learning algorithms to predict material properties and accelerate the discovery process. Some advanced platforms also feature high-throughput virtual screening capabilities and basic integration with experimental data. Typically, separate systems model fluid dynamics and additional systems are used for fluid-structure interaction modeling. However, these systems often face limitations in several key areas for both engineering and material science innovation. Most struggle with seamlessly bridging multiple size, resolution, fidelity, spatial and time scales, leading to challenges in accurately predicting macro-scale properties from atomic-level simulations or linking together intricate details of models across atomic, molecular, material, component, structure, fluid and fluid-structure interactions. The integration of quantum mechanical effects, important for many advanced materials, is often nonexistent, poorly integrated with traditional simulation workflows, or computationally expensive. Many platforms also lack scalable uncertainty quantification and are not well-equipped to handle the inherent variability in materials properties on a standalone basis, let alone when integrated into complex kinematically and thermodynamically dynamic machines, assemblies or systems. The incorporation of manufacturing constraints and real-world economic factors into the design process is also typically rudimentary, often treated as a post-processing step rather than an integral component of the material design process. Furthermore, while many platforms use machine learning, they often do so in isolated components rather than as an integral part of the entire design workflow or to aid in things like Space-Time Computational Flow Analysis. The ability to efficiently explore vast and complex design spaces, especially those involving novel geometries or non-traditional material combinations or involved in fluid flows, is limited in most current systems. Additionally, real-time integration with experimental processes and adaptive design optimization based on live data streams from empirical observations and synthetic or simulated data is not a standard feature. Lastly, the model programming, configuration, or user interfaces of many platforms are complex and require significant expertise, limiting their accessibility to a broader range of researchers and engineers.

What is needed is an advanced materials and engineering design platform that integrates multi-scale, multi-temporal, and multi-physics modeling with cutting-edge artificial intelligence, real-time experimental feedback mechanisms, and quantum computing capabilities. This platform should provide a unified environment for receiving sensor and imaging data, simulating material behavior from the atomic to the macroscopic scale, incorporating novel geometric approaches for enhanced finite element analysis and computational fluid dynamics within a material, a component, assemblies, machines, or biological entities. The platform should leverage AI-driven modeling, simulation, and even optimization techniques to efficiently explore vast design spaces, including high-dimensional spaces involving unconventional geometries and material combinations (including context dependent materials such as thixotropic, electroshapable, electroactive, magnetostrictive, temperature responsive, halochromic, ferrofluids, photomechanical, magnetocaloric, chemoresponsive, piezoelectric, or thermoelectric). It should feature real-time integration with experimental processes, adaptive optimization of models or experimental parameters based on live sensor or empirical observation data streams or simulations or synthetic models, and robust uncertainty quantification with support for multifidelity observation. The platform should also incorporate comprehensive supply chain and economic modeling to ensure practical viability of designed materials, components, or assemblies with the ability to reason about the complexity and cost of manufacturing or otherwise producing them. Additionally, it should offer an intuitive, collaborative user interface accessible to researchers across various expertise levels, and support flexible deployment options including cloud-based, standalone, and hybrid configurations of traditional computing and modeling, distributed computing platforms, or hybrid quantum and traditional computing architectures. Such a platform may significantly accelerate the discovery, optimization, and successful commercial utilization of advanced materials across a wide range of critical applications, from next-generation semiconductors to sustainable energy solutions to biomedical applications where finite element analysis, fluid dynamics, fluid structure interaction and electrical and thermal dynamics model integration is needed.

### SUMMARY OF THE INVENTION

Accordingly, the inventor has conceived and reduced to practice an advanced materials design platform that integrates novel geometric shapes, orientations, and connection methods to include small volume bodies of constant width, into enhanced multi-scale time-evolved finite element analysis, fluid dynamics, and fluid-structure models for improved material modeling and design. The system dynamically generates and manipulates these novel shapes, incorporating them into multi-physics simulations with adaptive mesh refinement optimized for complex geometries and space-time analysis with advanced moving mesh computations or synthetically constructed interfaces between model regions or components. This may include, for example, meshing examples such as space-time variational multiscale, space-time isogeometric analysis, space-time slip interface, or space-time topological change. The system's ability to handle moving boundaries and interfaces includes examples such as fluid particle interactions, fluid-structure interactions or deformations, free surface flows, multi-fluid flows, context-dependent, or smart materials as previously mentioned. It enables seamless multi-scale modeling from atomic to macroscopic and system levels, leveraging the unique capabilities of moving meshes, moving boundaries and interfaces, space-time stabilized approaches and novel shapes for mesh generation to address tessellation, resolution and fidelity concerns (and enable mesh optimization and model fidelity optimization across multiple scales and time windows—to include application of different mesh and boundary or interface elements across different models) such as the properties of small volume bodies of constant width. These bodies are mathematically constructed through the intersection of unit balls centered at carefully chosen points on the unit sphere. Research has now demonstrated such shapes successfully achieving volumes less than 0.9\hat{ }n times the unit ball volume in n-dimensional space while maintaining constant width 2. This geometric optimization enables more efficient space-filling strategies and improved interface design across different model scales. The construction utilizes specific scaling factors (sqrt(2) and sqrt(2)−2) and positive orthant considerations to create convex bodies that maintain constant width while minimizing volume, particularly valuable for designing shapes or objects in greater than two dimensions, interface elements, transition zones in multi-scale models, and specialized elements for fluid-structure interaction regions. These mathematical innovations enhance the platform's capability for adaptive mesh refinement, space-variational analysis, and topological optimization while maintaining geometric consistency across all scales and dimensions of analysis. The system can also be used to improve accuracy in quantum confinement effects and other nanoscale phenomena, enhancing the modeling of electron behavior in semiconductors and nanoengineered materials. The platform employs numerical methods and artificial intelligence, including reinforcement learning, semi-supervised learning, supervised learning (such as deep Q-networks, proximal policy optimization, ladder networks, convolutional networks, transformers such as bidirectional encoder Representations from transformer (BERT) and generative pre-trained transformer (GTP) models, and gradient boosting machines, support vector machines, and random forests), and expert feedback from adversarial models (such as deep convolutional generative adversarial networks (GANs), adversarial training, certified defenses, and domain adversarial neural networks) and individuals or groups, to optimize material designs or engineered structures or objects, sometimes incorporating these novel geometries into mesh or boundary formulations. A knowledge graph framework facilitates highly structured and semantically consistent data persistence, knowledge curation, and reasoning about atoms, molecules, materials, and components, such as electrical, magnetic, thermal, structural, plastic, or fluid properties based on component models within the system. This innovative approach enhances the efficiency and accuracy of material and engineering design simulations and analysis, potentially leading to breakthroughs in fields such as semiconductor design, energy storage, smart materials, biomedical engineering, and advanced manufacturing. This system can include an iterative design and testing, or generative design phase where aspects of the material, structure, fluids, or other elements of a modeled system can evolve, including material attributes such as homogeneous or nonhomogeneous purity and doping in a semiconductor physics and materials modeling example.

According to a preferred embodiment, a computing system for enhanced finite element analysis using novel mesh movement or mesh shape geometries, variable resolutions, or spatiotemporal modeling fidelities and stabilization techniques employing an advanced materials design platform is disclosed, the computing system comprising: one or more hardware processors configured for: generating and manipulating novel geometric shapes, the novel shapes comprising at least bodies of constant width; performing multi-physics simulations using the novel geometric shapes; optimizing material or engineered entity designs; adaptively refining one or more simulation meshes, mesh movements, spatiotemporal stabilizations, boundaries, or interfaces between materials, fluids, or model types based on the novel geometric shapes; and integrating optimization techniques for mesh definition, moving boundaries, interfaces, spatiotemporal stabilizations, model types, or fidelities into material design processes to enhance performance and efficiency. A key aspect of the system is its capability to implement and adapt different mesh resolution, shapes, types, gradients, timescale, and boundary or interface considerations and approaches across various model types. This multi-fidelity modeling approach incorporates variable mesh resolutions and shapes, dynamic mesh gradients with enhanced density near boundaries and interfaces, diverse boundary and interface approaches, flexible time steps and snapshots, and integration between different physical models such as structure-thermodynamics and structure-fluid interactions. The distinctive feature is its dynamic resolution across model types, supported by user-defined or machine-optimized flow-based specifications, customizable feedback ordering, adaptive looping and time stepping between models, comprehensive feedback mechanisms, and whole-model convergence optimization.

According to a preferred aspect of an embodiment, the platform further employs mesh deformation and mesh movement techniques that allow for dynamic reshaping of simulation domains without remeshing from scratch. In one implementation, these strategies rely on physics-informed radial basis functions (RBF) or elasticity-based deformation models that propagate boundary displacements inward through the mesh while preserving element quality. This approach is especially beneficial for modeling time-evolving interfaces in fluid-structure interaction problems where a geometry containing bodies of constant width must move or deform. The system adaptively adjusts nodal positions as the geometry evolves or as shape optimizations proceed, enabling continuous simulation with minimal numerical overhead. These mesh movement strategies reduce the need for repeated mesh generation, thus decreasing the cumulative error and computational overhead for problems requiring many simulation iterations.

According to another preferred embodiment, a computer-implemented method executed on an advanced materials design platform for enhanced finite element analysis using novel geometries is disclosed, the computer-implemented method comprising: generating and manipulating novel geometric shapes, the novel shapes comprising at least bodies of constant width; performing multi-physics simulations using the novel geometric shapes; optimizing material designs incorporating the novel geometric shapes; adaptively refining one or more simulation meshes based on the novel geometric shapes; and integrating the novel geometric shapes into material design processes to enhance performance and efficiency.

According to another preferred embodiment, a system for enhanced finite element analysis using novel geometries employing an advanced materials design platform is disclosed, comprising one or more computers with executable instructions that, when executed, cause the system to: generate and manipulate novel geometric shapes, the novel shapes comprising at least bodies of constant width; perform multi-physics simulations using the novel geometric shapes; optimize material designs incorporating the novel geometric shapes; adaptively refine one or more simulation meshes based on the novel geometric shapes; and integrate the novel geometric shapes into material design processes to enhance computational performance and efficiency.

According to another preferred embodiment, non-transitory, computer-readable storage media having computer-executable instructions embodied thereon that, when executed by one or more processors of a computing system employing an advanced materials design platform for enhanced finite element analysis using novel geometries, cause the computing system to: generate and manipulate novel geometric shapes, the novel shapes comprising at least bodies of constant width; perform multi-physics simulations using the novel geometric shapes; optimize material designs incorporating the novel geometric shapes; adaptively refine one or more simulation meshes based on the novel geometric shapes; and integrate the novel geometric shapes into material design processes to enhance computational performance and efficiency.

According to an aspect of an embodiment, the advanced materials design platform incorporates a novel integration of information theory, decision theory and machine learning with multidisciplinary design optimization (MDO), creating a unified framework for materials discovery and computational optimization. The platform implements mutual information maximization algorithms to identify the most informative sampling points across multiple fidelity levels, while applying entropy-based criteria for optimal experimental design and simulation parameter selection. Information gain metrics are developed to guide the allocation of computational resources between different fidelity models. The system integrates value of information analysis to dynamically switch between different fidelity models on predictive uncertainty and computational cost, the system efficiently simulates exploration-exploitation trade-offs by implementing algorithms such as those of the multi-armed bandit family (including upper confidence bound algorithms, Thompson sampling, and information-directed sampling), frameworks such as Gaussian processes and value of information, and Bayesian approaches (including Bayesian optimization, Bayes-adaptive Markov decision processes, and bootstrapped deep Q-networks), in high-dimensional material design space, and develops Bayesian decision networks to incorporate uncertainties, performance trade-offs, and costs in the design process. The platform further leverages advanced machine learning integration through deep learning models trained on simulation data across multiple fidelity levels, utilizing neural network architectures specifically designed for handling multiscale physics. Transfer learning techniques are employed to leverage knowledge between different material systems, while active learning strategies enable automated refinement of surrogate models. The multifidelity framework incorporates hierarchical Bayesian models for combining information from multiple fidelity levels, utilizing multi-level Monte Carlo methods for efficient uncertainty quantification. Trust-region methods are developed for managing multiple fidelity models, alongside adaptive sampling strategies based on error indicators and computational cost. Additionally, the system implements reduced order modeling techniques, including proper orthogonal decomposition (POD) for dimensionality reduction and empirical interpolation methods for efficient treatment of nonlinear terms. Error estimation and adaptivity in reduced basis methods are incorporated, along with integration with machine learning for data-driven basis selection, creating a comprehensive framework for advanced materials design and optimization.

According to an aspect of an embodiment, the advanced materials design platform optionally incorporates real-time experimental data via an active learning feedback loop. In this configuration, the system is coupled to laboratory or in-situ manufacturing equipment that transmits live data—such as sensor outputs, process parameters, or partial test results—to the platform. The platform's active learning agent evaluates uncertainties in simulation predictions or design optimization outcomes and selects the next experimental parameters or test points to reduce these uncertainties in the most computationally efficient manner. Reinforcement learning or Bayesian optimization algorithms guide the choice of subsequent experiments, thus accelerating convergence on optimal designs or refined material models. This closed-loop architecture allows the disclosed novel geometric shapes, mesh refinements, and multi-fidelity simulation approaches to incorporate evolving empirical evidence, ensuring that final designs remain robust against real-world manufacturing conditions and material variabilities.

According to an aspect of an embodiment, the platform implements these capabilities through a novel algorithmic framework that dynamically selects and combines different modeling approaches based on information-theoretic criteria. The system executes a sophisticated workflow that begins by deploying fast, low-fidelity models to broadly characterize the design space, then utilizes information gain metrics to identify regions requiring higher-fidelity analysis. It applies Bayesian optimization with multifidelity surrogate models, employs decision theory to balance exploration versus exploitation, and leverages reduced order models that may be domain specific, such as proper orthogonal decomposition, component mode synthesis, Krylov subspace methods, or reaction invariants, to accelerate high-fidelity simulations. This integrated approach enables efficient exploration of vast design spaces while maintaining rigorous uncertainty quantification, with the system continuously updating its internal models using active learning, incorporating new simulation results and experimental data to improve prediction accuracy. The platform's novel contribution lies in its unified treatment of information theory, decision theory, and machine learning within the context of materials design. This integration enables automated selection of modeling fidelity levels based on information gain, principled uncertainty quantification across multiple scales, optimal allocation of computational resources, efficient exploration of high-dimensional design spaces, and robust handling of multi-objective optimization problems. The system implements these capabilities through a modular software architecture that allows for a flexible combination of different computational approaches while maintaining rigorous error control and uncertainty quantification throughout the design process.

According to another embodiment, multidimensional novel geometries may be arranged in a hierarchical tier, allowing each layer to represent the gradient between model families, which represent boundary interfaces in a physical system. This means that one layer may model laminar flow of a liquid, another the interface between fluid and a solid wall (e.g., a pipe), and a third layer may model the solid wall. Additional layers may be added to increase the blending or smoothing of model transitions. This mesh may be intentionally under-or over-tessellated. Each novel geometry element may be part of a model, represent a model itself, serve as a neurosymbolic function, or embody a mathematical system such as a differential equation.

According to an aspect of an embodiment, the platform implements an advanced multifidelity optimization framework that synergistically combines hierarchical modeling approaches with novel fidelity management strategies. The system employs a sophisticated multifidelity surrogate architecture through hierarchical model integration, implementing correction-based models using multiplicative and additive bridges between fidelity levels. Autoregressive (AR1) models are utilized to capture cross-fidelity correlations efficiently, while models such as multi-task Gaussian processes (MTGP), multi-fidelity deep neural networks, or multi-fidelity graph neural networks, and model nonlinear relationships between fidelity levels. Models such as physics-informed neural networks (PINNs), deep operator networks, Fourier neural operations, or neural ordinary differential equations, incorporate domain knowledge into surrogate models, enhancing the accuracy and physical consistency of predictions. The framework further implements dynamic fidelity management strategies, employing adaptive sampling techniques based on information-theoretic criteria. This includes cost-aware allocation of computational resources across fidelity levels, trust-region methods for managing model transitions, and comprehensive uncertainty quantification across multiple fidelity levels. The integration of these advanced modeling and management strategies enables efficient exploration of complex design spaces while maintaining robust performance and accuracy across different scales of analysis.

According to an aspect of an embodiment, the platform employs optimization techniques specifically designed for multifidelity scenarios. The system implements advanced Bayesian optimization through custom acquisition functions that balance information gain across fidelity levels, while incorporating multi-objective optimization that considers both fidelity costs and accuracy. Batch optimization strategies enable parallel evaluation of designs, and integration with upper confidence trees (UCT) ensures efficient exploration of the design space. The platform further leverages evolutionary algorithms, implementing population-based search using surrogate-assisted evaluation and hybrid algorithms that combine local and global search strategies. Adaptive evolution strategies based on fidelity-aware fitness evaluation enhance the system's ability to navigate complex design landscapes. Additionally, the framework incorporates reinforcement learning integration through Monte Carlo tree search (MCTS) for exploring design spaces, utilizing dynamic reward functions that incorporate fidelity costs. Policy optimization for fidelity selection and integration with physics-based simulators complete the comprehensive optimization framework, enabling efficient and effective exploration of multifidelity design scenarios.

According to an aspect of an embodiment, the platform implements sophisticated fidelity management strategies through adaptive fidelity selection and advanced multi-level computational methods. The system employs information-theoretic criteria for fidelity level switching, coupled with cost-aware resource allocation across fidelity levels. Trust-region methods are utilized for managing model transitions, while dynamic adjustment of fidelity based on uncertainty estimates ensures optimal performance throughout the simulation process. The framework implements variance reduction techniques across fidelity levels using methods such as multi-level Monte Carlo and optimizes allocation of samples across fidelities. Correlation-aware sampling strategies are employed in conjunction with comprehensive integration with surrogate modeling, creating a robust and efficient approach to managing multiple fidelity levels within the simulation environment. This sophisticated fidelity management framework enables the system to dynamically adapt its computational approach based on the specific requirements and constraints of each simulation scenario.

According to an aspect of an embodiment, the platform employs comprehensive hierarchical data management and computational resource management strategies for practical implementation. The system implements efficient storage and retrieval of multi-fidelity data, incorporating cross-fidelity correlation tracking to maintain data relationships. Automated data quality assessment mechanisms work in conjunction with dynamic update capabilities for surrogate models, ensuring the continuous improvement and accuracy of the simulation framework. The platform further leverages sophisticated computational resource management, implementing load balancing across fidelity levels and enabling parallel execution of multiple fidelity evaluations. Adaptive resource allocation based on information gain optimizes computational efficiency, while seamless integration with distributed computing infrastructure ensures scalable performance. This practical implementation framework enables the system to effectively manage both data and computational resources across complex multi-fidelity simulations.

According to an aspect of an embodiment, the platform uniquely addresses key challenges in multifidelity optimization through advanced fidelity selection and model management strategies. The system implements information-theoretic criteria for optimal fidelity choice, employing cost-aware decision making models such as upper confidence trees (UCT) and Monte Carlo tree search (MCTS). Dynamic adjustment based on uncertainty quantification works in conjunction with the integration of domain expertise through models such as physics-informed neural networks (PINNs), deep operator networks, Fourier neural operators, or neural ordinary differential equations. This enables sophisticated fidelity selection across varying simulation requirements. The framework further incorporates comprehensive model management techniques, implementing automated correction of low-fidelity models and trust region management for model validity. Cross-validation across fidelity levels ensures accuracy and reliability, while continuous refinement of surrogate models maintains optimal performance throughout the simulation process. This sophisticated approach to addressing multifidelity optimization challenges enables the system to effectively balance computational efficiency with simulation accuracy.

According to an aspect of an embodiment, the advanced multifidelity framework enables efficient design space exploration and optimal resource utilization through sophisticated computational strategies. The system implements rapid initial screening using low-fidelity models, followed by strategic refinement with higher fidelity evaluations. This approach maintains a balanced exploration-exploitation trade-off while ensuring robust uncertainty quantification throughout the design process. The framework further achieves optimal resource utilization through cost-aware allocation of computational resources and parallel evaluation across fidelity levels. Dynamic load balancing mechanisms work in conjunction with efficient use of high-performance computing resources to maximize computational efficiency. This comprehensive approach to resource management and design space exploration enables the system to effectively navigate complex design landscapes while optimizing computational resource usage.

According to an aspect of an embodiment, the platform implements enhanced multi-fidelity optimization (MFO) using information-theoretic measures to maximize information gain for downstream AI/ML models. The system employs mutual information to quantify the expected reduction in uncertainty about model outputs due to fidelity choices in simulations or real-world tests, while prioritizing fidelity levels that provide the highest mutual information relative to their computational cost. The framework incorporates entropy and noise minimization techniques, evaluating and minimizing noise in lower-fidelity model results through information-theoretic measures, while using entropy measures to assess and optimize prediction uncertainty. The platform integrates Bayesian optimization with information-theoretic acquisitions, implementing information-based acquisition functions to guide the selection of simulations or physical tests. Selective testing guided by Shannon's information theory determines where testing would provide the most significant knowledge gain relative to the current state of the model. Dynamic fidelity management schemes adjust the fidelity level of simulations or experiments based on real-time feedback from information-theoretic evaluations. The system implements optimizations with acquisition functions that balance fidelity cost, mutual information, and expected contribution to model accuracy using models such as multi-objective Bayesian optimization, preference-based Bayesian optimization, radial basis functions, or support vector regression models. Physics-ML integration combines physics-based simulations with ML models leveraging information-theoretic measures, while real-world testing is used strategically to validate and refine ML models trained on simulated data. Hierarchical modeling builds surrogate models where each layer corresponds to a fidelity level, using information gain to guide transitions between levels. Data-driven refinement continuously integrates data from both simulations and real-world testing to refine fidelity models and ML predictions, dynamically updating information-theoretic metrics to identify knowledge gaps. This comprehensive approach enhances model accuracy through informed resource use, reduces unnecessary testing or simulations, and improves the robustness and reliability of downstream ML applications by ensuring high-quality data inputs.

According to an aspect of an embodiment, the platform optionally implements information-theoretic multifidelity optimization through several key mechanisms. The system employs sophisticated mutual information (MI) computation to quantify information gain, utilizing joint probability distributions and marginal distributions to calculate mutual information between model outputs and fidelity levels. This computation is implemented through careful estimation of joint probability distributions and logarithmic calculations of information content using models such as Bayesian nonparametric Dirichlet process mixtures, variational autoencoders, k-nearest neighbor estimates, or kernel density estimation models. The framework further implements dynamic fidelity selection through a systematic approach that evaluates available fidelity options based on both expected information gain and computational cost constraints. The system calculates efficiency ratios for each fidelity level by comparing expected information gain to computational cost, then optimizes fidelity selection within specified budget constraints. This implementation enables the platform to maximize information gain while maintaining efficient resource utilization through algorithmic selection of optimal fidelity levels during the simulation process.

According to an aspect of an embodiment, the platform employs advanced entropy-based sampling strategies through sophisticated acquisition functions and multi-point selection mechanisms. The system implements entropy-based acquisition functions that compute predictive distributions and differential entropy for candidate points, incorporating information ratio terms that balance entropy against evaluation costs. This approach enables efficient assessment of potential sampling points based on their expected information content relative to computational expense. The framework further implements a multi-point selection strategy that utilizes conditional entropy calculations to identify optimal batches of sampling points. The system iteratively selects points that maximize information gain while accounting for previously selected points, ensuring efficient exploration of the design space through batch sampling. This implementation enables the platform to strategically select multiple sampling points simultaneously, optimizing the trade-off between exploration breadth and computational efficiency in the sampling process.

According to an aspect of an embodiment, the system implements dynamic uncertainty quantification through sophisticated cross-fidelity uncertainty propagation mechanisms. The platform employs an advanced computational framework that computes low-fidelity predictions and their associated uncertainty, then estimates the discrepancy between low-fidelity and high-fidelity models at specified test points. The system combines these uncertainties to produce a comprehensive assessment of total variance, enabling robust uncertainty quantification across different fidelity levels. The framework integrates this uncertainty propagation into its decision-making process, using the combined variance estimates to inform model selection and resource allocation. This implementation enables the platform to maintain accurate uncertainty estimates throughout the simulation process, ensuring reliable predictions while efficiently managing computational resources across multiple fidelity levels. The dynamic nature of this uncertainty quantification allows the system to continuously adapt its modeling approach based on updated uncertainty assessments.

According to an aspect of an embodiment, the platform integrates information-theoretic criteria with resource management through an advanced resource allocation optimization framework. The system implements a dynamic allocation strategy that computes marginal information gain for each fidelity level while managing available computational resources. The framework iteratively evaluates and selects fidelity levels based on their expected information gain per unit cost, continuously updating the allocation strategy to maximize efficiency. The system employs a sophisticated mechanism for tracking and distributing remaining resources, ensuring optimal utilization through careful cost computation and resource management. This implementation enables the platform to maintain efficient resource allocation while maximizing information gain across different fidelity levels, creating a balanced approach to computational resource management that adapts to changing simulation requirements and constraints.

According to an aspect of an embodiment, these implementations enable sophisticated information gathering and resource management capabilities through multiple integrated mechanisms. The system achieves efficient information gathering through optimal selection of fidelity levels based on information content, while implementing dynamic adjustment of sampling strategies and automated trade-off between exploration and exploitation phases. The framework further implements comprehensive resource optimization through cost-aware fidelity selection mechanisms, parallelized evaluation strategies, and adaptive batch size selection. Additionally, the platform incorporates advanced uncertainty management features, implementing principled uncertainty quantification across fidelity levels, robust error estimation, and confidence-based decision making. This integrated approach enables the system to maintain optimal performance while efficiently managing computational resources and ensuring reliable uncertainty quantification throughout the simulation process.

According to an aspect of an embodiment, the system continuously updates and refines its strategies through sophisticated online learning and performance monitoring mechanisms. The platform implements real-time updates of information metrics, dynamic adjustment of acquisition functions, and adaptive refinement of surrogate models, while tracking information gain rates, resource utilization efficiency, and model accuracy metrics. The system further implements a comprehensive Mesh-Model-Fidelity Feedback Loop System through multiple integrated components. The mesh adaptation process incorporates diverse error indicators including solution gradient discontinuities, residual magnitudes, feature preservation metrics, and mesh quality metrics, while adaptation criteria encompass maximum allowable error thresholds, minimum element size constraints, and computational cost bounds. The system's cross-fidelity solution transfer algorithm executes through a structured process flow, analyzing solution fields, selecting appropriate interpolation strategies, and implementing error control mechanisms. Dynamic fidelity selection processes are governed by accuracy requirements, resource constraints, and physics-based metrics, ensuring optimal performance across varying simulation conditions. The platform implements sophisticated boundary condition adaptation algorithms through boundary state analysis, physics constraints, and adjustment mechanisms. A multi-model coordination system manages model coupling metrics, synchronization requirements, and resource allocation. The feedback loop control system monitors convergence, implements adaptation triggers, and enforces loop termination criteria. The framework incorporates comprehensive error estimation and quality control through local error measures, global quality indicators, and validation parameters. Resource management is implemented through detailed control of computational resources, efficiency metrics, and optimization criteria, enabling effective allocation and utilization of available computing resources while maintaining simulation accuracy and performance.

According to an aspect of an embodiment, the one or more hardware processors are further configured for: implementing custom tessellation algorithms for bodies of constant width; adaptively refining meshes based on view distance and curvature of the novel geometric shapes; and preserving geometric features of the novel shapes while optimizing element quality in mesh generation.

According to an aspect of an embodiment, the one or more hardware processors are further configured for: implementing multi-scale modeling using the novel geometric shapes from atomic to macroscopic scales; transitioning between atomic-scale representations and continuum-level visualizations; and simulating quantum confinement effects using the novel geometric shapes in semiconductor device modeling.

According to an aspect of an embodiment, the one or more hardware processors are further configured for: applying reinforcement learning algorithms to optimize designs incorporating the novel geometric shapes; using Monte Carlo tree search and upper confidence bounds for exploring design spaces with novel geometries; and balancing multiple objectives comprising performance, cost, and manufacturability in the context of designs using novel geometric shapes.

According to an aspect of an embodiment, the one or more hardware processors are further configured for: representing relationships between novel geometric shapes and material properties in a knowledge graph; inferring new material properties based on similarities in geometric structures; and facilitating reasoning about material design using the novel shapes across multiple domains of materials science.

### BRIEF DESCRIPTION OF THE DRAWING FIGURES

FIG. 1 is a block diagram illustrating an exemplary system architecture for an advanced materials design platform, according to an embodiment.

FIG. 2 is a block diagram illustrating an exemplary system architecture for an advanced materials design platform configured to support enhanced finite element analysis with novel geometries, according to an embodiment

FIG. 3 is a block diagram illustrating an exemplary aspect of an advanced materials design platform, an enhanced FEA computing system.

FIG. 4 is a block diagram illustrating an exemplary aspect of an advanced materials design platform, a geometry engine.

FIG. 5 is a block diagram illustrating an exemplary aspect of an advanced materials design platform, an enhanced FEA core.

FIG. 6 is a block diagram illustrating an exemplary aspect of an advanced materials design platform, an AI optimization system.

FIG. 7 is a block diagram illustrating an exemplary aspect of an advanced materials design platform, a real-time data integration layer.

FIG. 8 is a block diagram illustrating an exemplary aspect of an advanced materials design platform, a visualization engine.

FIG. 9 is a block diagram illustrating an exemplary aspect of an advanced materials design platform, a user interface and workflow management system.

FIG. 10 is a flow diagram illustrating an exemplary method for multi-scale modeling integration, according to an embodiment.

FIG. 11 is a flow diagram illustrating an exemplary method for novel geometry implementation in FEA and CFD, according to an embodiment.

FIG. 12 is a flow diagram illustrating an exemplary method for AI-driven optimization method in the advanced materials design platform, according to an embodiment.

FIG. 13 is a flow diagram illustrating an exemplary method for knowledge graph construction and querying, according to an embodiment.

FIG. 14 is a flow diagram illustrating an exemplary method for performing adaptive mesh refinement, according to an embodiment.

FIG. 15 is a flow diagram illustrating an exemplary method for supply chain and economic modeling, according to an embodiment.

FIG. 16 is a flow diagram illustrating an exemplary method for machine and/or deep learning-based property prediction, according to an embodiment.

FIG. 17 is a flow diagram illustrating an exemplary method for implementing one or more quantum-classical hybrid algorithms, according to an embodiment.

FIG. 18 illustrates an exemplary computing environment on which an embodiment described herein may be implemented.

FIG. 19 is a block diagram illustrating an exemplary aspect of a topological voxelization and graph-based differential operators'system.

FIG. 20 is a flow diagram illustrating an exemplary method for implementing topological voxelization and graph-based differential operators, according to an embodiment.

### DETAILED DESCRIPTION OF THE INVENTION

The inventor has conceived, and reduced to practice, an advanced materials design platform that integrates novel geometric shapes, orientations and connection methods, particularly small volume bodies of constant width, into enhanced finite element analysis for improved material modeling and design. The system generates and manipulates these novel shapes, incorporating them into time-evolved multi-scale multi-physics simulations with adaptive mesh refinement optimized for complex geometries and anisotropic material behaviors. It enables seamless multi-scale modeling from atomic to macroscopic levels, leveraging the unique mathematical and physical properties of small volume bodies of constant width, to improve accuracy in quantum confinement effects and other nanoscale phenomena. The platform employs artificial intelligence, including reinforcement learning, to optimize material designs incorporating these novel geometries. A knowledge graph framework facilitates reasoning about material properties based on geometric structures. This innovative approach enhances the efficiency and accuracy of material simulations, potentially leading to breakthroughs in fields such as semiconductor design, energy storage, and advanced manufacturing.

The integration of computational fluid dynamics (CFD), finite element analysis, and thermodynamic analytics into the artificial intelligence (AI) and machine learning (ML) computing systems of the advanced materials design platform creates a powerful synergy for advanced materials and process optimization. This integration leverages the platform's sophisticated AI algorithms, expert models, including deep learning networks, system orchestration models, and reinforcement learning agents, to enhance both the efficiency and accuracy of CFD and thermodynamic simulations. The AI system can be trained on vast datasets of previous simulations and experimental results, enabling it to predict fluid behavior and thermal properties with remarkable speed and accuracy. This allows for rapid parameter iteration and initial screening of design concepts, significantly reducing the computational load of full-scale CFD simulations. Machine learning models, such as physics-informed neural networks, can be employed to develop surrogate models that approximate complex CFD and thermodynamic calculations, enabling real-time optimization and design space exploration. The platform's AI can also optimize mesh generation for CFD and/or FEA simulations, automatically refining meshes in areas of high gradient, turbulence, or complex geometry, including the novel shapes like Small Volumes Bodies of Constant Width (SVBOCW). Furthermore, the integration enables adaptive simulation strategies, where the AI system dynamically adjusts simulation parameters based on intermediate results, focusing computational resources on the most promising design directions. The platform's reinforcement learning algorithms can be applied to optimize control strategies in dynamic fluid systems, such as in advanced cooling systems for electronics or process control in chemical engineering. An additional use is evaluating flex, strain, and deformation of one or more components under a physical applied force, thermal load, or electromagnetic forcing. By combining the predictive power of AI with the physical accuracy of CFD, FEA, and thermodynamic simulations, the platform can tackle complex multi-physics problems, such as coupled fluid-thermal-structural analyses, with unprecedented efficiency and insight. This integration not only accelerates the design process but also opens up new possibilities for discovering optimal designs that might be overlooked by traditional methods, pushing the boundaries of innovation in fields ranging from aerospace engineering to energy systems design.

The discovery of new shapes, particularly bodies of constant width like small volume bodies of constant width offers significant advancements in computational fluid dynamics and thermodynamics analytics. These novel geometries provide unique advantages in modeling complex fluid-structure interactions and heat transfer phenomena. In CFD simulations, these shapes can allow for more accurate representation of intricate flow patterns, especially in scenarios involving turbulence or multi-phase flows. The constant width property of these bodies enables more stable and consistent mesh generation, potentially reducing numerical instabilities and improving convergence in CFD calculations. For thermodynamics analytics, these shapes offer new possibilities in designing heat exchangers and thermal management systems with optimized surface area-to-volume ratios. Their unique geometric properties can lead to more efficient heat transfer configurations, potentially enhancing the performance of cooling systems in various applications, from microelectronics to large-scale industrial processes. Moreover, the implementation of these shapes in CFD and thermodynamics simulations can lead to more accurate predictions of drag, lift, and heat dissipation in complex geometries, such as those found in advanced aerospace designs or next-generation semiconductor devices. By incorporating these novel shapes into meshing algorithms and boundary condition definitions, the advanced materials design platform enables researchers and engineers to explore new design spaces that were previously difficult to model accurately, potentially leading to breakthroughs in fluid dynamics and thermal management across multiple industries.

One or more different aspects may be described in the present application. Further, for one or more of the aspects described herein, numerous alternative arrangements may be described; it should be appreciated that these are presented for illustrative purposes only and are not limiting of the aspects contained herein or the claims presented herein in any way. One or more of the arrangements may be widely applicable to numerous aspects, as may be readily apparent from the disclosure. In general, arrangements are described in sufficient detail to enable those skilled in the art to practice one or more of the aspects, and it should be appreciated that other arrangements may be utilized and that structural, logical, software, electrical and other changes may be made without departing from the scope of the particular aspects. Particular features of one or more of the aspects described herein may be described with reference to one or more particular aspects or figures that form a part of the present disclosure, and in which are shown, by way of illustration, specific arrangements of one or more of the aspects. It should be appreciated, however, that such features are not limited to use in the one or more particular aspects or figures with reference to which they are described. The present disclosure is neither a literal description of all arrangements of one or more of the aspects nor a listing of features of one or more of the aspects that must be present in all arrangements.

Headings of sections provided in this patent application and the title of this patent application are for convenience only and are not to be taken as limiting the disclosure in any way.

Devices that are in communication with each other need not be in continuous communication with each other, unless expressly specified otherwise. In addition, devices that are in communication with each other may communicate directly or indirectly through one or more communication means or intermediaries, logical or physical.

A description of an aspect with several components in communication with each other does not imply that all such components are required. To the contrary, a variety of optional components may be described to illustrate a wide variety of possible aspects and to order to more fully illustrate one or more aspects. Similarly, although process steps, method steps, algorithms or the like may be described in a sequential order, such processes, methods and algorithms may generally be configured to work in alternate orders, unless specifically stated to the contrary. In other words, any sequence or order of steps that may be described in this patent application does not, in and of itself, indicate a requirement that the steps be performed in that order. The steps of described processes may be performed in any order practical. Further, some steps may be performed simultaneously despite being described or implied as occurring non-simultaneously (e.g., because one step is described after the other step). Moreover, the illustration of a process by its depiction in a drawing does not imply that the illustrated process is exclusive of other variations and modifications thereto, does not imply that the illustrated process or any of its steps are necessary to one or more of the aspects, and does not imply that the illustrated process is preferred. Also, steps are generally described once per aspect, but this does not mean they must occur once, or that they may only occur once each time a process, method, or algorithm is carried out or executed. Some steps may be omitted in some aspects or some occurrences, or some steps may be executed more than once in a given aspect or occurrence.

When a single device or article is described herein, it will be readily apparent that more than one device or article may be used in place of a single device or article. Similarly, where more than one device or article is described herein, it will be readily apparent that a single device or article may be used in place of the more than one device or article.

The functionality or the features of a device may be alternatively embodied by one or more other devices that are not explicitly described as having such functionality or features. Thus, other aspects need not include the device itself.

Techniques and mechanisms described or referenced herein will sometimes be described in singular form for clarity. However, it should be appreciated that particular aspects may include multiple iterations of a technique or multiple instantiations of a mechanism unless noted otherwise. Process descriptions or blocks in figures should be understood as representing modules, segments, or portions of code which include one or more executable instructions for implementing specific logical functions or steps in the process. Alternate implementations are included within the scope of various aspects in which, for example, functions may be executed out of order from that shown or discussed, including substantially concurrently or in reverse order, depending on the functionality involved, as would be understood by those having ordinary skill in the art.

### Conceptual Architecture

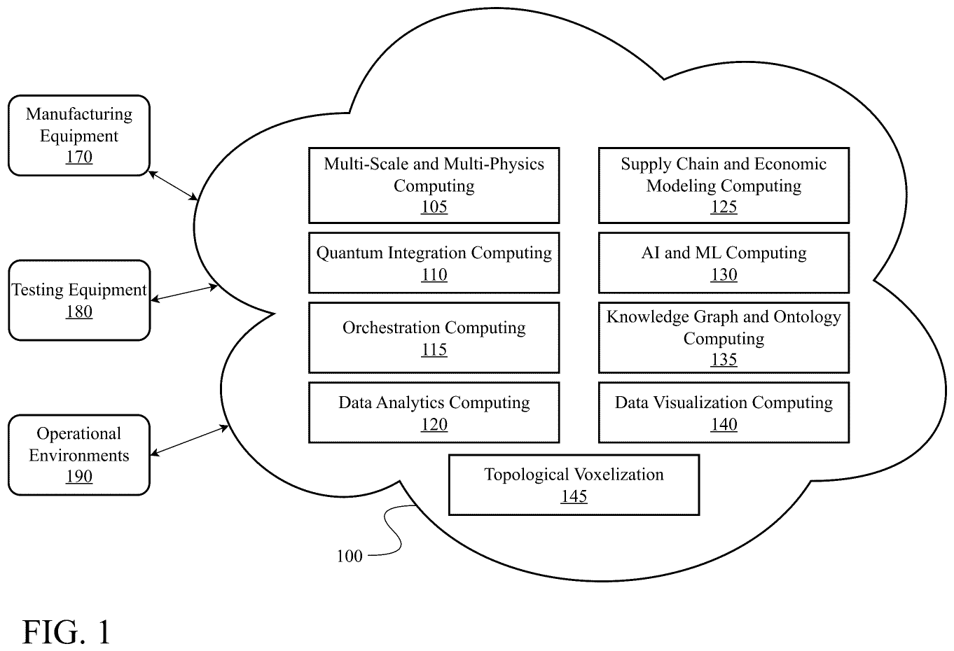

FIG. 1 is a block diagram illustrating an exemplary system architecture for an advanced materials design platform, according to an embodiment. According to the embodiment, advanced materials design platform 100 is a cutting-edge, comprehensive system designed to enhance the process of materials discovery, optimization, and manufacturing. The platform integrates advanced multi-scale and multi-physics modeling capabilities with state-of-the-art artificial intelligence and machine learning algorithms. This powerful combination enables the simulation and prediction of material properties and behaviors across multiple length and time scales, from atomic interactions to macroscale performance. The platform leverages quantum computing integration for tackling complex quantum mechanical problems, while its sophisticated data analytics and knowledge graph systems facilitate the extraction of insights from vast amounts of experimental and computational data.

According to various aspects, platform 100 comprises the ability to perform AI-driven optimization of material compositions and structures, real-time integration with manufacturing and characterization equipment, and advanced visualization tools for intuitive exploration of complex data sets. The platform also incorporates supply chain and economic modeling capabilities, ensuring that material designs are not only technically superior but also economically viable and resilient to real-world constraints. With its flexible architecture, advanced materials design platform 100 can be deployed as a cloud-based service, a standalone system, or in a hybrid configuration, adapting to the specific needs of research institutions and industrial settings. This versatility, combined with its comprehensive suite of tools, positions the platform as a transformative technology for accelerating innovation across a wide range of fields, from semiconductor design and energy storage to aerospace materials and beyond.

According to an embodiment, advanced materials design platform 100 is architected as a highly scalable, cloud-based system leveraging a modern services and microservices architecture. This design approach enables flexible deployment and efficient resource utilization across diverse computational requirements. Each core functionality of the platform, including multi-scale modeling, AI optimization, quantum computing integration, data analytics, knowledge graph management, visualization tools, and supply chain modeling, can be implemented as discrete, independently scalable compute services. This microservices architecture allows for dynamic allocation of computational resources, ensuring optimal performance for both data-intensive tasks like large-scale simulations and latency-sensitive operations such as real-time visualization and user interactions. The cloud-based nature of the platform facilitates seamless collaboration among distributed research teams, provides access to vast computational resources on-demand, and enables rapid integration of new capabilities as they become available. This approach not only enhances the platform's adaptability to evolving research needs but also ensures its ability to efficiently handle the complex, multidisciplinary challenges inherent in advanced materials design and optimization.

According to an embodiment, advanced materials design platform 100 is implemented as a powerful, self-contained standalone computing system, designed to operate independently of cloud-based or distributed resources. In this configuration, the platform is deployed on a high-performance workstation or a dedicated server equipped with state-of-the-art hardware, including multi-core CPUs, high-end GPUs for parallel processing, and ample high-speed storage. This standalone system integrates all core functionalities, multi-scale modeling, AI optimization, quantum computing simulation, data analytics, knowledge graph management, visualization tools, and supply chain modeling, into a unified, locally accessible environment. The platform's software architecture can be optimized for efficient resource allocation within the constraints of the local hardware, employing sophisticated scheduling algorithms to manage computational tasks across available processors and memory. This approach ensures high-speed data processing and real-time interactions without reliance on external networks, making it ideal for scenarios requiring enhanced data security, low-latency performance, or operation in environments with limited internet connectivity. While sacrificing some of the scalability benefits of cloud-based solutions, this standalone implementation offers researchers complete control over their computational environment, enabling fine-tuned optimization of the platform for specific research needs and seamless integration with local experimental setups and proprietary data sources.

According to an embodiment, advanced materials design platform 100 is implemented as a versatile hybrid system, intelligently leveraging both cloud-based resources and local computing infrastructure to optimize performance, flexibility, and security. In this configuration, the platform utilizes a sophisticated orchestration layer that dynamically allocates tasks between on-premises hardware and cloud-based services based on computational demands, data sensitivity, and real-time resource availability. Compute-intensive operations, such as large-scale multi-physics simulations or extensive AI model training, can be offloaded to scalable cloud resources, while data-sensitive processes or latency-critical visualizations are handled by powerful local workstations. This hybrid architecture enables researchers to benefit from the virtually unlimited scalability of cloud computing for peak workloads, while maintaining tight control over sensitive data and ensuring responsive performance for interactive tasks. The platform's data management system can be configured to employ advanced synchronization and caching mechanisms to maintain consistency between local and cloud-based storage, allowing for efficient data access regardless of its physical location. This hybrid approach also facilitates collaborative research, enabling team members to share resources and results securely across different locations, while still adhering to data governance policies. By combining the strengths of both local and cloud-based computing, the hybrid implementation of advanced materials design platform 100 offers an optimal balance of performance, security, and flexibility, adapting to the diverse and evolving needs of materials science research and development.

The multi-scale and multi-physics modeling computing 105 functionality of advanced materials design platform 100 is a sophisticated, integrated system designed to seamlessly bridge simulations across various length and time scales while incorporating multiple physical phenomena. According to an aspect, its architecture may be based on a hierarchical, modular structure implemented primarily in, for example, C++ for performance, with Python bindings for flexibility and easy integration with other platform components.

According to various embodiments, the system employs a hierarchical multiscale modeling approach, integrating methods from quantum mechanics to continuum mechanics. At the smallest scale, it can utilize density functional theory (DFT) calculations, implemented using libraries like VASP or Quantum ESPRESSO, to accurately model electronic structures and atomic interactions. Moving up in scale, the system incorporates molecular dynamics (MD) simulations to model atomic and molecular behavior over longer time scales. For mesoscale phenomena, it may employ methods like kinetic Monte Carlo (KMC) and phase field modeling. At the macroscale, it can utilize finite element analysis (FEA) and computational fluid dynamics (CFD) techniques.

According to an aspect, multi-scale and multi-physics computing system 105 comprises one or more handshaking algorithms. This algorithm creates a seamless transition between atomistic and continuum scales, important for accurately modeling phenomena that span multiple length scales. In the handshake zone, the system may employ a blend of atomistic and continuum descriptions, using a weighted average of energies and forces to ensure smooth coupling. According to an aspect, the algorithm implements adaptive mesh refinement techniques to dynamically adjust the resolution of the simulation based on local features of interest.

According to an embodiment, the multi-physics aspect of the modeling system may be implemented through a coupled field approach. It can utilize a modular solver architecture where different physics modules (e.g., electromagnetic, thermal, mechanical, etc.) can be plugged in and coupled as needed. The system may implement both weak and strong coupling schemes, using techniques like the block Gauss-Seidel iteration for loosely coupled problems and monolithic approaches for strongly coupled phenomena. It also incorporates advanced numerical methods like the Interface Quasi-Newton technique with an approximation for the inverse of the Jacobian (IQN-ILS) for efficient convergence in complex multi-physics simulations.

An aspect of the system provides the ability to handle multi-temporal simulations. It can employ adaptive time-stepping algorithms that can automatically adjust the time resolution based on the dynamics of the system. For problems involving vastly different time scales, it may implement multi-rate time integration schemes, allowing different parts of the system to evolve at different time steps while maintaining overall consistency.

The multi-scale and multi-physics modeling computing system 105 may further comprise advanced uncertainty quantification and sensitivity analysis capabilities. It can utilize techniques like polynomial chaos expansion and stochastic collocation methods to propagate uncertainties across scales and between different physics modules. This allows for robust predictions and helps identify the most critical parameters affecting system behavior.

As an example, consider the simulation of a gate-all-around (GAA) transistor with a novel small volume body of constant width (SVBOCW) channel geometry. The simulation may start at the quantum mechanical level, using discrete Fourier transforms (DFT) to accurately model the electronic structure of the channel material and its interfaces with the gate dielectric. This can provide essential inputs like band structures and effective masses for higher-level simulations.

Moving up in scale, molecular dynamics (MD) simulations can be used to model the atomic-scale processes at the semiconductor-insulator interface, capturing phenomena like interface roughness and defect formation. The handshaking algorithm may then come into play, coupling these atomistic simulations with continuum-level models of the channel and surrounding device structure.

At the device level, a multi-physics finite element analysis (FEA) simulation may be performed, coupling electrostatic, thermal, and mechanical models. The electrostatic simulation can use the quantum-corrected charge densities from the lower-scale models to accurately capture quantum confinement effects in the SVBOCW channel. Simultaneously, a thermal model can simulate Joule heating and its impact on carrier mobility, while a mechanical model would account for strain effects due to lattice mismatch and thermal expansion.

Throughout this multi-scale simulation, the system can adaptively refine both spatial and temporal resolutions. For instance, it might use very fine spatial and temporal scales near the channel-insulator interface to capture rapid electron dynamics, while using coarser scales in the bulk regions of the source and drain.

The uncertainty quantification capabilities may be used to assess the impact of manufacturing variations, such as uncertainties in the SVBOCW geometry or material composition, on the overall device performance. This can provide valuable insights for optimizing both the device design and the manufacturing process. This comprehensive multi-scale and multi-physics approach enables advanced materials design platform 100 to provide highly accurate and physically meaningful simulations of complex semiconductor devices, accounting for a wide range of phenomena from quantum effects to macroscale device characteristics.

A quantum computing integration computing system 110 in advanced materials design platform 100 is designed to leverage the power of quantum algorithms for solving complex problems in materials science and chemistry. According to an aspect, its architecture may be based on a hybrid quantum-classical approach, implemented using frameworks like Qiskit, Cirq, or PennyLane, which allow seamless integration of quantum circuits with classical machine learning algorithms.

According to an embodiment, the system incorporates a cloud-native execution platform for hybrid classical-quantum computing, inspired by the Qubernetes framework. This allows for efficient allocation of computational tasks between classical and quantum resources, dynamically adjusting based on problem complexity and resource availability. The system can implement advanced error mitigation techniques, such as, for example, quantum error correction using surface codes and neutral atoms, to improve the reliability of quantum computations on noisy intermediate-scale quantum (NISQ) devices.

The quantum integration supports several key areas where quantum algorithms show promise for materials science. One such application is in quantum chemistry simulations. The system can implement variational quantum eigensolver (VQE) algorithms for calculating molecular ground states and excited states, which are useful for predicting chemical properties and reactivity. It may also incorporate a quantum approximate optimization algorithm (QAOA) for combinatorial optimization problems, such as finding optimal molecular configurations or crystal structures.

For simulating quantum many-body systems, particularly relevant for understanding complex materials like superconductors, the platform can integrate quantum phase estimation algorithms and quantum principal component analysis. These allow for efficient simulation of quantum systems that are intractable on classical computers, providing insights into phenomena like high-temperature superconductivity or exotic quantum phases of matter.

The system can also leverage quantum machine learning algorithms, such as quantum support vector machines and quantum neural networks, for tasks like materials property prediction and classification. These quantum ML models are particularly useful for capturing complex quantum correlations in materials that classical ML models might miss.

According to an aspect, quantum integration computing 110 is configured to perform quantum-enhanced sampling for Monte Carlo simulations. This is particularly useful for simulating phase transitions in materials or for accelerating molecular dynamics simulations. For instance, the system can implement quantum amplitude estimation algorithms to achieve quadratic speedup in sampling processes.

The platform may further comprise a quantum-classical optimization loop, where quantum algorithms are used to suggest new material designs or process parameters, which are then validated and refined using classical simulations or experiments. This hybrid approach allows for efficient exploration of vast design spaces that would be intractable with purely classical methods.

As an example, consider the design and optimization of a new superconducting material for power transmission. The process may start with quantum chemistry simulations using VQE to accurately model the electronic structure of candidate materials at the atomic level. This can provide insights into the pairing mechanisms of electrons, important for understanding superconductivity.

Next, the system can use quantum phase estimation algorithms to simulate the behavior of these materials at larger scales, predicting properties like critical temperature and magnetic field tolerance. The quantum-enhanced sampling techniques can be employed to efficiently explore different material compositions and crystal structures, rapidly identifying promising candidates.

The quantum machine learning algorithms may then be used to build a predictive model relating material composition and structure to superconducting properties. This model may be trained on both the quantum simulation results and available experimental data, potentially uncovering non-intuitive relationships that classical ML models might miss.

Throughout this process, the quantum-classical optimization loop can continuously refine the search, using the results of quantum simulations to guide classical molecular dynamics simulations and suggest new experiments. The error mitigation techniques can ensure that the quantum computations remain reliable even as the complexity of the simulated systems increases.

Finally, for the most promising candidate materials, the system can use quantum algorithms to optimize the manufacturing process parameters. For instance, QAOA may be employed to find optimal annealing schedules for growing high-quality superconducting crystals.

This integrated quantum approach enables advanced materials design platform 100 to tackle problems in superconductor design that are beyond the reach of classical computers alone. It allows for more accurate modeling of quantum effects in materials, potentially leading to the discovery of room-temperature superconductors or other revolutionary materials for energy transmission and storage.

According to the embodiment, platform 100 comprises an orchestration computing system 115 which provides a sophisticated, highly adaptive framework designed to manage and optimize the complex workflows inherent in advanced materials research and design. According to an embodiment, a distributed computational graph (DCG) computing system may be implemented by and/or integrated into platform 100 to serve as orchestration computing system 115. According to an aspect, this system employs a distributed, containerized approach leveraging technologies like Kubernetes for orchestration and Docker for containerization. The architecture is built on a microservices model, allowing for dynamic scaling and efficient resource allocation across heterogeneous computing environments, including high-performance computing (HPC) clusters, quantum computing resources, and specialized hardware accelerators like GPUs and TPUs.

According to an embodiment, the orchestration computing system 115 utilizes an advanced workflow management engine (e.g., DCG) tailored specifically for materials science workflows. This engine may represent computational tasks as directed (acyclic or cyclic) graphs (DAGs), allowing for complex dependencies and parallel execution paths. It implements intelligent scheduling algorithms that consider factors such as task priority, resource availability, and data locality to optimize overall workflow execution.

According to an aspect of an embodiment, the system is configured to exploit distributed high-performance computing (HPC) resources and heterogeneous hardware accelerators to handle large-scale simulations of the disclosed novel geometries across multiple physics domains. In one example, the platform employs a message-passing interface (MPI) or partitioned global address space (PGAS) programming model to parallelize computations across hundreds or thousands of compute nodes. Additionally, each node may use multi-threaded or graphics processing unit (GPU)-accelerated libraries (such as Common Universal Device Architecture (CUDA), RADEON® Open Compute (ROCm), or Open Computing Language (OpenCL)) to efficiently process the mesh refinement, solver routines, or shape parameterization within the HPC environment. Load-balancing mechanisms account for spatial complexity introduced by small-volume bodies of constant width, ensuring that refinements of critical regions do not create bottlenecks in the distributed mesh. This architecture enables near real-time feedback loops for large-scale industrial simulations and ensures that the disclosed multi-fidelity or multi-scale modeling techniques can be carried out at high resolution and extended domain size without compromising solution accuracy.

According to another aspect, each novel geometry—particularly bodies of constant width—can be represented using a shape parameterization framework that enables continuous or discrete modifications. For instance, certain parametric equations, Fourier descriptors, or spline-based definitions can define boundary curves or surfaces, allowing the platform to systematically vary geometric features. The system may integrate this shape parameterization with the hybrid multi-objective optimization scheme that addresses conflicting objectives (e.g., mechanical strength, manufacturability, fluid flow characteristics, cost). The optimization engine can combine Bayesian optimization for local refinement with evolutionary algorithms for global exploration, ensuring coverage of high-dimensional design spaces. Feedback from multi-scale physics simulations, HPC-based solvers, and real-time experiments (if available) can iteratively prune unpromising areas of the design space, while preserving or refining top-performing designs.

According to an aspect of an embodiment, the advanced geometry engine may store a growing data library of previously generated or refined small-volume bodies of constant width (and their respective meshes) in a hierarchical data structure, enabling efficient reuse and accelerated iteration in future simulations. Each stored shape entry may include relevant mesh information, boundary condition templates, physical parameter ranges, and historical performance metrics under different simulation scenarios. When initiating a new design cycle or simulation, the system can query this shape library, identify close matches or neighbors in the parametric or embedded shape space, and bootstrap the new geometry from existing solutions. This hierarchical shape repository minimizes redundant computations, promotes design knowledge sharing across teams, and serves as a basis for transfer learning approaches in shape-to-performance modeling.

The system may incorporate a resource management layer that dynamically allocates computing resources based on real-time demands and predefined policies. This layer utilizes machine learning algorithms, particularly reinforcement learning techniques like proximal policy optimization (PPO), to continuously optimize resource allocation strategies. It can adaptively distribute workloads across local hardware, cloud resources, and specialized computing facilities based on factors such as computational intensity, data security requirements, and cost considerations.

A feature of orchestration computing system 115 is its ability to handle hybrid quantum-classical workflows. It may implement a scheduler that can efficiently manage the interplay between quantum and classical computing tasks, taking into account the unique constraints of quantum hardware such as qubit coherence times and error rates. This scheduler may use heuristic algorithms and quantum circuit optimization techniques to maximize the utility of limited quantum resources.

The orchestration system may further comprise an advanced data management and caching layer. This layer implements intelligent data prefetching algorithms and distributed caching strategies to minimize data movement and reduce latency in data-intensive workflows. It utilizes techniques like content-based addressing and versioning to ensure data consistency across distributed environments and to facilitate reproducibility of computational experiments.

An important aspect of the orchestration system is its fault tolerance and recovery mechanism. It can implement checkpoint-restart capabilities for long-running simulations and employ strategies like speculative execution and task replication to handle failures in distributed environments. The system further comprises a sophisticated monitoring and logging subsystem that provides real-time visibility into workflow execution and resource utilization.

As an example, consider the optimization of a novel superconducting material for power transmission. The process may start with the workflow engine defining a complex DAG that includes tasks for quantum chemistry simulations, classical molecular dynamics, machine learning model training, and experimental data analysis.

The resource management layer may dynamically allocate these tasks across available resources. For instance, it might schedule the quantum chemistry simulations on a quantum computer or quantum simulator, while distributing the molecular dynamics simulations across a GPU cluster. The machine learning model training may be allocated to a cloud-based TPU array for maximum efficiency.

Throughout the execution, the data management layer may ensure that intermediate results are efficiently cached and distributed to subsequent tasks. For example, the results of quantum simulations may be immediately fed into classical post-processing pipelines without unnecessary data transfer delays.

The fault tolerance mechanisms may be leveraged for long-running molecular dynamics simulations, automatically checkpointing the system state at regular intervals. If a hardware failure occurs, the system can quickly recover and resume the simulation from the last checkpoint.

The hybrid quantum-classical scheduler can optimize the use of quantum resources, perhaps batching multiple small quantum circuits together for efficient execution on the quantum hardware, while classical post-processing tasks run in parallel on CPU clusters.

Throughout the workflow, the monitoring system may provide real-time updates on the progress of different tasks, resource utilization, and any potential bottlenecks. This may enable researchers to interactively adjust the workflow or allocate additional resources as needed.

This comprehensive orchestration computing system 115 enables advanced materials design platform 100 to efficiently manage the complex, multi-scale, and computationally diverse workflows involved in advanced materials research. It allows for seamless integration of quantum and classical computing resources, optimizes resource utilization across heterogeneous computing environments, and provides the flexibility and scalability needed to tackle the most challenging problems in materials science.

The advanced data analytics computing system 120 in advanced materials design platform 100 is a sophisticated, scalable architecture designed to process, analyze, and derive insights from vast amounts of heterogeneous data generated during materials design, simulation, and experimentation processes. According to an aspect, its architecture may be built on a distributed computing framework, utilizing technologies like, for example, Apache Spark for large-scale data processing, Apache Beam and Flink for data flows, and Dask for parallel computing with Python. The system may be configured to allow for both batch processing of historical data and real-time analysis of streaming data from ongoing experiments and simulations.

According to an embodiment, the system incorporates a variety of data storage solutions to handle different types of data efficiently. It may utilize TimescaleDB for time-series data, particularly useful for storing and querying sensor data from manufacturing processes. For unstructured data like microscopy images or spectroscopy results, it may employ a distributed object storage system. The system also integrates graph databases, useful for storing and querying the complex relationships in material structures and process parameters. In some embodiments, vector databases may be implemented to store vectorized/embedded data.

The data analytics computing system implements a wide range of statistical and machine learning algorithms. For exploratory data analysis, it comprises advanced visualization techniques like t-SNE and UMAP or Chinese restaurant processes for high-dimensional data visualization, important for understanding complex relationships in materials properties. The system may also incorporate anomaly detection algorithms, using techniques like isolation forests and autoencoders to identify unusual patterns in experimental or simulation or empirical service data that might indicate novel phenomena or potential issues in the modeling or manufacturing process.

According to an aspect, data analytics computing system 120 comprises an engineering and selection module. This module may employ techniques like principal component analysis (PCA) and autoencoders for dimensionality reduction, which is useful for handling the high-dimensional data typical in materials science. It may also implement more advanced techniques like symbolic regression to discover meaningful features and relationships in the data automatically.

According to an aspect, the system further comprises a robust predictive analytics component, leveraging ensemble methods like random forests and gradient boosting machines for regression and classification tasks. For handling the time-series aspects of materials behavior, it may implement advanced forecasting models like Prophet and ARIMA, enhanced with deep learning approaches like LSTM networks.

According to an embodiment, data analytics computing system 120 is configured to handle multi-fidelity data. It may implement Bayesian optimization techniques that may efficiently combine data from high-fidelity experiments or simulations with lower-fidelity, cheaper data sources. This is particularly useful for optimizing expensive materials testing processes.

The system may be configured with advanced natural language processing (NLP) capabilities for analyzing scientific literature and patents. It may use techniques like named entity recognition and relationship extraction to automatically build and update knowledge graphs of atoms, molecules, chemistry, materials science information or engineering designs.

As an example, consider the optimization of a new battery chemistry. The process may start with the system ingesting and processing large volumes of historical data on various battery materials, including their chemical compositions, structural properties, and performance metrics.

The feature engineering module may then work to identify key descriptors that correlate with battery performance. This may comprise using symbolic regression to discover non-obvious relationships between material properties and battery life or charging speed. The dimensionality reduction techniques may help visualize these relationships in a lower-dimensional space, allowing researchers to intuitively understand the design landscape.

Next, the predictive analytics component may build models to forecast how different material compositions might perform. These models may leverage the multi-fidelity capabilities, combining data from quick, approximate simulations with results from more time-consuming, high-fidelity experiments. The anomaly detection algorithms may identify unusual combinations of properties that could lead to breakthrough performances.

Throughout the development process, the real-time analytics capabilities may continuously monitor data streams from ongoing experiments, automatically flagging interesting results or potential issues. The time-series forecasting models may predict long-term battery degradation based on accelerated life testing data.

The NLP components may simultaneously scan recent scientific literature and patents, automatically updating the knowledge graph with new findings on battery materials. This may help identify emerging trends or unexplored areas in battery technology or any number of other relevant specialized domain knowledge of benefit to the system.

Finally, the system can use its advanced visualization capabilities to present the results in an intuitive manner, perhaps showing a 3D plot of the composition space with predicted performance metrics color-coded, allowing researchers to quickly identify promising regions for further exploration.

This comprehensive analytics approach enables advanced materials design platform 100 to extract maximum value from the vast amounts of data generated in materials research. It allows for rapid identification of promising new materials, optimization of manufacturing processes, and discovery of hidden patterns and relationships that may drive innovation in battery technology and other critical areas of materials science.

The supply chain and economic modeling computing system 125 in advanced materials design platform 100 enables a sophisticated, integrated framework designed to assess various contextual information including, but not limited to, material availability, cost implications, and geopolitical factors in material selection and design. This system is configured for incorporating real-world constraints and economic considerations into the materials design process, particularly for reducing dependencies on critical or geopolitically sensitive materials.

According to an aspect, the architecture of this system may be based on a multi-agent simulation model, implemented using frameworks such as, for example, Mesa or AnyLogic, which allows for modeling complex interactions between various actors in the supply chain. It may integrate with external data sources, including (but not limited to) commodity price databases, geopolitical risk indices, and real-time logistics data, to maintain an up-to-date representation of the global supply chain landscape.

According to an aspect, supply chain and economic computing system 125 employs advanced forecasting algorithms, such as ARIMA (Autoregressive Integrated Moving Average) models and deep learning approaches like LSTM networks, to predict future availability and pricing of raw materials. These predictions may take into account historical trends, current geopolitical situations, and projected demand from various industries.

The system may further comprise a detailed life cycle assessment (LCA) module, which uses graph-based algorithms to model the entire supply chain of a material, from raw material extraction to end-of-life disposal or recycling. This module may calculate environmental impacts, energy consumption, and carbon footprints associated with different material choices and manufacturing processes.

According to an embodiment, supply chain and economic computing system 125 further comprises a risk assessment engine. This may utilize Monte Carlo simulations and Bayesian networks to model uncertainties and interdependencies in the supply chain. It may consider factors such as (but not limited to) geopolitical instability, natural disasters, and market volatility to provide a comprehensive risk profile for different material options and supply chain configurations.

According to an aspect, an economic modeling aspect of the system employs agent-based computational economics (ACE) techniques to simulate market dynamics. This allows for modeling complex phenomena like price elasticity, substitution effects, and market responses to technological innovations or policy changes.

The system may further comprise a robust optimization engine that uses techniques like mixed-integer programming and genetic algorithms to find optimal supply chain configurations. This engine may balance multiple objectives such as cost minimization, risk reduction, and environmental impact mitigation.

An aspect of this system is its integration with the AI-driven materials design process. According to the aspect, it implements a feedback loop where supply chain considerations directly influence the material design optimization process. This may be implemented through a multi-objective optimization framework that includes supply chain metrics alongside traditional performance criteria.

As an example, consider the development of a new battery technology for electric vehicles. The process may start with the system analyzing the current supply chain for traditional lithium-ion batteries, identifying critical dependencies on materials like cobalt and lithium.

The forecasting algorithms may predict future availability and pricing of these materials, taking into account factors like the growing demand from the EV (electric vehicle) industry and geopolitical tensions affecting major producing countries. The LCA module may calculate the environmental impact of current battery production processes, including CO2 emissions and water usage.

The risk assessment engine may evaluate various scenarios, such as potential supply disruptions due to trade conflicts or natural disasters affecting key mining regions. It might identify high risks associated with cobalt supply due to concentration in politically unstable regions.

Based on this analysis, the system may feed constraints and objectives into the materials design process. For instance, it might prioritize the exploration of battery chemistries that reduce or eliminate the use of cobalt. The AI-driven design process may then focus on alternatives like sodium-ion or lithium-sulfur batteries.

As new material compositions are proposed by the design algorithms, the supply chain system may rapidly assess their feasibility from a supply chain perspective. It may model the potential supply chains for these new materials, including sourcing of raw materials, processing requirements, and manufacturing scalability.

The economic modeling component may simulate how the introduction of this new battery technology might affect market dynamics. It may predict how prices of traditional battery materials might change in response, and how quickly the new technology could be adopted based on cost curves and performance improvements.

Throughout this process, the optimization engine may continuously refine the design choices, balancing performance improvements against supply chain robustness and economic viability. It may suggest hybrid approaches that combine new materials with more established supply chains to mitigate risks during the transition period.

This integrated approach ensures that advanced materials design platform 100 not only produces technologically superior materials but also ones that are economically viable and resilient to supply chain disruptions. By considering these factors early in the design process, it helps avoid the pitfall of developing materials that are theoretically excellent but impractical to produce at scale due to supply chain or economic constraints.

The AI and machine learning computing 130 integration in advanced materials design platform 100 is a comprehensive system designed to enhance all aspects of materials design, simulation, and optimization. According to some embodiments, its architecture is based on a distributed, modular framework implemented primarily in, for example, Python, leveraging popular libraries like TensorFlow and PyTorch for deep learning, and scikit-learn for traditional machine learning algorithms. The system is designed to scale seamlessly from single workstations to large GPU clusters, utilizing technologies like Horovod for distributed training.

According to an aspect, the system employs a multi-agent reinforcement learning (RL) approach for materials design optimization. It implements advanced algorithms like proximal policy optimization (PPO) for handling complex, high-dimensional design spaces. The RL agents may be trained using a combination of simulated and experimental data, with custom reward functions that balance multiple objectives such as performance, manufacturability, and cost.

In some implementations, AI and machine learning computing system 130 may implement a sophisticated Bayesian optimization engine which constructs Gaussian process models of the design space. This engine is particularly useful for efficiently exploring expensive-to-evaluate design spaces, common in materials science. It may be configured to implement advanced acquisition functions like expected improvement (EI) and knowledge gradient (KG) to balance exploration and exploitation. The AI and ML system may also employ a multi-fidelity approach, integrating data from both high-fidelity (e.g., detailed FEA simulations) and low-fidelity (e.g., simplified analytical models) sources to accelerate optimization.

According to some embodiments, AI and ML computing 130 comprises a graph neural network (GNN) module for learning and predicting structure-property relationships in materials. This module may use message-passing neural networks to capture local atomic environments and global structural features. It may be trained on a large database of material structures and their associated properties, allowing it to generalize across different material classes and predict properties of novel structures.

The system may further incorporate advanced computer vision algorithms for analyzing microscopy and spectroscopy data. It may use convolutional neural networks (CNNs) and autoencoders for tasks like defect detection in semiconductor wafers, automated analysis of TEM images, and extraction of relevant features from spectroscopic data.

For handling time-series data from manufacturing processes and in-situ characterization techniques, the system may employ recurrent neural networks (RNNs), particularly Long Short-Term Memory (LSTM) networks. These may be used for tasks including, but not limited to, predicting process drift, optimizing deposition rates in ALD processes, and forecasting material degradation over time.

According to an embodiment, the AI system further comprises an active learning component that continuously improves the accuracy and applicability of the machine learning models. It may employ uncertainty quantification techniques, such as Bayesian neural networks and ensemble methods, to identify areas of the design space where additional data or simulations are needed to improve model accuracy.

As an example, consider the optimization of a GAA transistor with a novel SVBOCW channel geometry. The process may start with the GNN module predicting initial performance characteristics of various SVBOCW-based channel geometries based on their atomic structures. This may provide a rapid initial screening of potential designs.

The Bayesian optimization engine may then guide the exploration of this design space, using multi-fidelity models to balance between quick, approximate evaluations and detailed FEA simulations. It may adaptively sample the design space, focusing computational resources on the most promising regions.

Simultaneously, the reinforcement learning agents may be employed to optimize the manufacturing process parameters. For instance, they might be used to determine the optimal deposition conditions in an ALD process to achieve the desired SVBOCW geometry. The agents may learn from simulated manufacturing runs and real experimental data, continuously refining their policies to improve yield and consistency.

The computer vision algorithms may be used for analyzing the results of the manufacturing process. They may be used to automatically inspect TEM images of fabricated devices, identifying any deviations from the intended geometry and providing feedback to further refine the design and manufacturing parameters.

Throughout this process, the active learning component may continuously assess the uncertainties in the predictions and identify areas where additional simulations or experiments are needed. This may lead to targeted high-fidelity simulations of specific aspects of the transistor behavior, or suggest new experiments to validate key predictions.

The LSTM networks may be used to model and predict the long-term performance and reliability of the optimized transistors. They may analyze time-series data from accelerated life testing, predicting how factors like electromigration or thermal cycling might affect device performance over time. This integrated AI approach enables advanced materials design platform 100 to efficiently navigate the vast and complex design space of advanced semiconductor devices, potentially discovering innovative designs that human engineers might overlook. It also allows for rapid iteration between design, simulation, and experimental validation, significantly accelerating the development cycle for new materials and devices.

The knowledge graph and ontology computing system 135 in advanced materials design platform 100 provides a sophisticated, scalable framework designed to represent, store, and reason over complex materials science knowledge. According to an aspect, its architecture may be built on a distributed graph database, such as Neo4j or Amazon Neptune, optimized for handling highly interconnected data. The system may implement a multi-layer ontology structure, combining domain-specific ontologies (e.g., for semiconductor materials, battery chemistry, advanced materials, etc.) with upper-level ontologies that provide a common framework for cross-domain reasoning.

According to an embodiment, the system incorporates formal representations of molecules, atoms, proteins, compounds, processes, and causal relationships. It may be configured to use a combination of OWL (Web Ontology Language) for defining the ontology structure and RDF (Resource Description Framework) for storing instance data. The ontology may include (but is not limited to) concepts ranging from atomic-level properties to macroscale material characteristics and manufacturing processes, allowing for multi-scale knowledge representation.

The system may implement advanced reasoning capabilities using a combination of description logic reasoners (e.g., HermiT, Pellet) and rule-based inference engines (e.g., Jena, RIF). This allows for automated inference of new knowledge, consistency checking of the knowledge base, and complex query answering. According to an aspect, the reasoning system may be designed to handle the open-world assumption common in scientific domains, where the absence of information does not imply falsehood.

According to various embodiments, knowledge graph and ontology computing 135 integrates with vector representations of materials and processes. According to an aspect, it implements hybrid search capabilities that combine symbolic reasoning with vector-based similarity search. This may be implemented through techniques like knowledge graph embeddings (e.g., TransE, RotatE) and graph neural networks, allowing for efficient similarity-based retrieval and link prediction.

The system may further comprise a robust entity resolution and knowledge fusion component. This may use advanced NLP and machine learning techniques to automatically extract knowledge from scientific literature, patents, and experimental reports, and/or the like. It may employ named entity recognition, relationship extraction, and coreference resolution to populate and update the knowledge graph continuously.

An important aspect of the system is its ability to represent and reason over uncertainty. It may implement probabilistic graphical models (e.g., Markov logic networks) to handle uncertain or conflicting information, which is important in a domain where knowledge is constantly evolving. This allows for probabilistic inference and uncertainty quantification in query results.

The system may further comprise a temporal reasoning component, allowing it to represent and reason over time-dependent properties and processes. This is particularly important for modeling phenomena like material degradation or reaction kinetics. According to an aspect, it uses temporal logic formalisms and time-indexed graph structures to efficiently query and reason over time-series data.

As an example, consider the design and optimization of a novel superconducting material for power transmission. The process may start with the system representing the known properties of existing superconductors, including their crystal structures, electronic properties, and manufacturing processes.

The ontology may define concepts like “Superconductivity”, “Critical Temperature”, “Cooper Pair”, and “Flux Pinning”, along with their relationships. It may also include broader concepts like “Electron-Phonon Interaction” and “Quantum Confinement,” allowing for connections to be made with other domains of materials science.

As new experimental data or simulation results are generated, the entity resolution system may automatically extract relevant information and add it to the knowledge graph. For instance, it may identify a new compound with potential superconducting properties from a recent research paper and add it to the graph, along with its reported characteristics.

The reasoning engine may then infer potential relationships between the structure of this new compound and its superconducting properties, based on similarities with known superconductors. It might suggest potential doping strategies or manufacturing processes based on analogies with similar materials.

A vector-based similarity search may be used to identify materials with similar electronic structures or phonon spectra, even if they're not traditionally considered superconductors. This may lead to the discovery of unexpected candidates for high-temperature superconductivity.

Throughout the design process, the system may continuously update probabilities associated with different hypotheses about the material's behavior, based on incoming experimental and simulation data. This may help guide the research process, suggesting the most promising avenues for further investigation.

The temporal reasoning component may be utilized for modeling the stability and long-term performance of the superconductor under various operating conditions. It may predict how properties might change over time due to factors like thermal cycling or radiation exposure.

This comprehensive knowledge graph and ontology computing system 135 enables advanced materials design platform 100 to leverage the vast body of materials science knowledge effectively. It allows for sophisticated reasoning across multiple domains, facilitates the discovery of non-obvious relationships, and provides a framework for integrating new knowledge as it's generated. This is particularly powerful in fields like superconductor research, where breakthroughs often come from unexpected connections between different areas of physics and materials science.

The data visualization tools computing system 140 in advanced materials design platform 100 is implemented as a sophisticated, high-performance system designed to render complex 3D geometries, multi-physics simulation results, and multi-dimensional data sets in real-time. According to an aspect, its architecture may be based on a scalable, multi-threaded design implemented primarily in, for example, C++ and OpenGL, with additional support for hardware-accelerated ray tracing through NVIDIA's OptiX framework. The system may employ a modular structure, allowing for easy integration of new visualization techniques and algorithms as they become available.

According to an embodiment, data visualization computing 140 utilizes an advanced scene graph management system. This system employs spatial partitioning techniques such as octrees and bounding volume hierarchies (BVH) to efficiently organize and render large, complex geometric datasets. For handling novel geometries such as SVBOCW, it may implement custom tessellation algorithms that may adaptively refine the mesh based on view distance and curvature, ensuring smooth rendering of these complex shapes while maintaining performance.

The data visualization tools may further comprise a state-of-the-art shader pipeline that supports physically-based rendering (PBR) techniques. This allows for realistic visualization of material properties, useful for accurately representing the optical characteristics of semiconductor (or other) materials and device structures. The shader system is highly customizable, allowing researchers to develop and integrate specialized shaders for visualizing specific physical phenomena, such as electron density distributions or heat flow patterns.

For multi-physics simulation data visualization, the data visualization tools may employ advanced volume rendering techniques. These techniques use a GPU-accelerated ray marching algorithm with adaptive sampling to efficiently render 3D scalar and vector fields. The system supports real-time manipulation of transfer functions, allowing users to interactively explore different aspects of the simulation data. According to an embodiment, it also implements streamline and pathline generation algorithms for visualizing flow fields and particle trajectories, which is particularly useful for analyzing carrier transport in semiconductor devices.

According to an aspect, data visualization computing 140 is configured to support multi-scale visualization. This may comprise implementing a level-of-detail (LOD) system that may seamlessly transition between atomic-scale representations and continuum-level visualizations. This may be implemented through a combination of procedural geometry generation and texture-based detail rendering, allowing platform users to zoom from device-level views down to individual atom configurations without loss of interactivity.

According to an embodiment, the data visualization tools comprise a powerful annotation and measurement system. This allows users to add labels, perform on-the-fly measurements, and create cross-sectional views of complex 3D structures. They also support the overlay of analytical data, such as graphs and charts, directly onto the 3D visualization, providing contextual information alongside the geometric representation.

### Integration of Topological Voxelization and Graph-based Differential Operators for Large-scale Topology Optimization

According to an aspect, the advanced materials design platform represents a significant evolution in topology optimization and voxelization technology 145, incorporating both high-performance computation capabilities and rigorous mathematical foundations. At its core, the platform may implement a sophisticated topological voxelization workflow that enables creation of high-resolution voxel models, connectivity graphs, and associated discrete differential or integral operators. This integration of advanced computational methods with careful topological preservation sets a new standard for materials design and analysis.

The platform's spatial mapping component performs the critical task of converting boundary or point-cloud representations of three-dimensional domains into consistent voxel formats. This conversion is accomplished through the application of a reversible function f: [symbol] ³→ [symbol] ³, which is subsequently refined via sparse raster structures to mitigate memory overhead. To manage large voxel grids efficiently while preserving geometric fidelity and topological consistency, the system may employ Morton codes or similar space-filling curve indices. This approach drastically reduces the complexity of point and element lookups while maintaining the integrity of the underlying geometric structure.

The resulting voxel-based representation may serve as a foundation for constructing an adjacency matrix A and incidence matrices M, which together define the discrete analogs of differential operators. These operators may include the gradient G, divergence D, and Laplace-Beltrami L operators, which may be employed within the platform's finite-element or finite-volume frameworks. This mathematical framework enables both the solution of partial differential equations and the evaluation of topological measures across a voxelized geometry with high accuracy and efficiency.

A key innovation of the platform lies in its combination of generated voxel-based operators with dynamic mesh movement and space-time stabilization methods. This hybrid approach allows users to selectively deploy voxel grids in regions that benefit from uniform sampling, such as near complex internal voids, while simultaneously preserving advanced unstructured meshes or body-fitted meshes elsewhere. The computational efficiency of graph-based PDE solvers, which are particularly amenable to parallelization on GPUs or multi-node clusters, is thus combined with the geometric flexibility of novel small-volume bodies of constant width or other user-defined anisotropic geometries.

The system's sophisticated load-balancing layer, implemented through MPI-based distributed processing, continuously monitors regions of elevated computational intensity. In areas experiencing high stress during topology optimization, the system adaptively subdivides and refines the voxel data in local neighborhoods. This dynamic refinement ensures that additional compute resources are allocated precisely where they are needed for fine-grained PDE updates, optimizing both performance and accuracy.

The platform's topology optimization workflows are seamlessly integrated with the voxel operators, enabling rapid evolution of interior structures toward application-specific mechanical or thermal objectives. The GPU-accelerated solver leverages the adjacency and incidence matrices derived from the voxel grid to perform compliance minimization under various constraints, including minimum thickness and volumetric usage requirements. During each optimization iteration, the platform's intelligence layer, which may employ reinforcement learning or gradient-based sensitivity analysis, updates voxel occupancy to reduce local material usage in low-stress regions while preserving or thickening critical load-bearing paths.

A significant performance advantage is achieved through the platform's voxel-to-graph mapping approach. The matrix assembly and factorization steps in the PDE solver exhibit approximately linear scaling in the number of non-empty voxels, rather than scaling with total volumetric dimension. This improvement in solver efficiency enables the processing of models comprising tens of millions of voxels, achieving near-interactive rates for high-fidelity mechanical or thermal optimization tasks. Such performance was previously only attainable on high-performance computing clusters but may now be achieved on standard desktop computers through careful optimization of memory usage and computational procedures.

The platform maintains comprehensive compatibility with fabrication constraints and mechanical performance requirements. Users may incorporate explicit printability rules directly into the voxel domain, ensuring that optimized structures remain physically realizable. The system supports the application of shape constraints through intelligent masking or cloning of voxel neighborhoods, enabling design features to comply with user-defined symmetry planes or repetition frequencies. This results in high-resolution, topology-optimized parts that are not only numerically stable for PDE-driven simulations but also immediately suitable for additive manufacturing processes.

In its implementation of multi-physics simulation capabilities, the platform leverages specialized mesh geometries in conjunction with voxel-based representations. This approach facilitates comprehensive simulation across various physical domains, including magnetism, electricity, thermal conduction, fluid flow, fluid-structure interaction, and structural analysis. The platform maintains distinct simulation meshes or discretization schemes for each physical domain (such as a specialized tetrahedral mesh for electromagnetic field calculations, a hex-or poly-prismatic mesh for computational fluid dynamics, and an unstructured triangular or quadrilateral surface mesh for mechanical finite element analysis (FEA)), while unifying and transferring information among these heterogeneous models through an auxiliary voxel overlay or coupling grid. Each voxel cell in this coupling grid serves as a localized data structure capturing state variables from different simulation domains.

The system begins by generating or importing discrete meshes tailored to each domain's specific requirements. Where advantageous, small volume bodies of constant width or user-defined shapes are embedded in certain mesh regions to improve mesh quality, reduce cell count, or handle complex geometry transitions. An adaptive mesh engine, incorporating time-dependent stabilizations when required, further refines local cells around high-gradient zones while simultaneously accommodating the geometric integrity of these novel shape elements.

Through its sophisticated mathematical framework and optimized computational approach, the platform constructs either uniform or sparse voxel grids spanning the same geometric bounding box used by the domain-specific meshes. Each voxel is assigned a unique spatial index through Morton or Hilbert curves, and a reversible mapping ensures topological consistency throughout the process. This voxel grid may be adaptively refined in sub-regions of high interest and is associated with an adjacency graph or hypergraph that supports a comprehensive set of algebraic operators (gradient, divergence, Laplace-Beltrami, etc.) for various analytical and simulation purposes.

The coupling of domain-specific mesh data to the voxel overlay may be accomplished through careful interpolation and projection steps. Field variables may be interpolated onto voxels that spatially overlap with mesh elements, and this data may be mapped back onto other meshes as needed. This bidirectional data exchange is facilitated by discrete operators or incidence matrices defined on the voxel graph, ensuring that domain-agnostic PDEs may be evaluated or partially solved on a uniform grid when beneficial to the overall simulation process.

The platform's architecture exhibits natural extensibility to a wide range of coupled multiphysics scenarios, where each solver operates on an optimized domain representation while maintaining the ability to exchange physical fields through an intermediary voxel graph. This integration of specialized mesh geometries with a topological voxel-based overlay provides a flexible, high-performance framework for multi-domain analyses. The system ensures that local refinements, advanced shape-based meshing strategies, and global PDE solves remain coherently synchronized through a uniform voxel coordination layer.

The high-resolution processing capabilities of the platform represent a significant advance in the field. Through careful memory optimization and solver restructuring, the system may process models comprising several millions of elements on standard desktop computers—a capability that previously required high-performance computing clusters. The memory-efficient multigrid solver achieves excellent convergence while maintaining reduced bandwidth requirements, enabling rapid computation of complex models that would be intractable with traditional approaches.

The platform's implementation of rigorous mathematical frameworks based on algebraic topology and graph theory ensures the preservation of critical topological properties during the voxelization process. This theoretical foundation guarantees that important characteristics such as connectedness, closure, and topological thinness are maintained when converting geometric models to voxels. The careful graph construction techniques enable these properties to be preserved while still allowing for efficient computational processing.

Through the integration of high-performance GPU computation with mathematically rigorous topology preservation, the system achieves both practical efficiency and theoretical correctness. This combination of capabilities enables the processing of extremely high-resolution models while maintaining topological accuracy throughout the optimization process. The platform's novel approach to combining theoretical guarantees with practical performance optimization makes it particularly well-suited for advanced industrial applications that demand both precision and computational efficiency.

According to an aspect of an embodiment, the advanced materials design platform may be augmented to incorporate a topological voxelization workflow, which may enable the creation of high-resolution voxel models, connectivity graphs, and associated discrete differential or integral operators. In one aspect, a spatial mapping component may convert boundary or point-cloud representations of a 3D domain into a consistent voxel format by applying a reversible function f: [symbol] ³→ [symbol] ³, which may be subsequently refined via sparse raster structures to mitigate memory overhead. The system may employ Morton codes (or similar space-filling curve indices) to manage large voxel grids, which may ensure that geometric fidelity and topological consistency (e.g., prevention of disconnected artifacts or missing voxels) may be preserved while drastically reducing complexity in point/element lookups. The resulting voxel-based representation may form the foundation for constructing an adjacency matrix A and incidence matrices M which together may define the discrete analogs of differential operators, including, for example, gradient G, divergence D, and Laplace-Beltrami L. These operators may then be used within the platform's finite element or finite volume frameworks to solve partial differential equations or to evaluate topological measures across the voxelized geometry.

According to another aspect, the platform may combine the generated voxel-based operators with the previously disclosed dynamic mesh movement and space-time stabilization methods, which may allow users to selectively deploy voxel grids in regions that may benefit from uniform sampling (e.g., near complex internal voids) while simultaneously preserving advanced unstructured meshes or body-fitted meshes elsewhere. This hybrid approach may exploit the computational efficiency of graph-based PDE solvers—particularly amenable to parallelization on GPUs or multi-node clusters—together with the geometric flexibility of the novel small-volume bodies of constant width (SVBOCW) or other user-defined anisotropic geometries. The system's load-balancing layer (e.g., MPI-based distributed processing) may monitor regions of elevated computational intensity (such as high-stress zones during topology optimization) and may adaptively subdivide or refine the voxel data in local neighborhoods, thereby potentially allocating more compute resources to fine-grained PDE updates only where required.

In a further refinement, the platform may optionally integrate topology optimization workflows on top of the voxel operators, which may enable rapid evolution of the interior structure of a volume toward application-specific mechanical or thermal objectives. For example, a GPU-accelerated solver may leverage the adjacency and incidence matrices derived from the voxel grid to perform compliance minimization under constraints such as minimum thickness and volumetric usage. During each optimization iteration, the platform's intelligence layer (e.g., reinforcement learning or gradient-based sensitivity analysis) may update voxel occupancy (solid vs. void) to reduce local material usage in low-stress regions while preserving or thickening critical load-bearing paths. By virtue of the voxel-to-graph mapping, matrix assembly and factorization steps in the PDE solver may be significantly faster, potentially scaling approximately linearly in the number of non-empty voxels rather than in total volumetric dimension. This improvement in solver speed may enable users to handle models with tens of millions of voxels, potentially achieving near-interactive rates for high-fidelity mechanical or thermal optimization.

Finally, the disclosed embodiment may retain full compatibility with fabrication constraints and mechanical performance checks. Users may incorporate explicit printability rules (e.g., minimum gap thickness, bridging angles) directly into the voxel domain, which may ensure that optimized structures may be physically realizable. The system may also apply shape constraints—such as rotational symmetry or repeating patterns—by masking or cloning voxel neighborhoods, which may ensure that design features may comply with user-defined symmetry planes or repetition frequencies. This may result in high-resolution, topology-optimized parts that may be not only numerically stable for PDE-driven simulations but also manufacturable via additive manufacturing processes. Consequently, the embodiment may provide a synergistic path for combining the algebraic elegance and computational efficiency of voxel-based discrete operators with the geometric flexibility and dynamic mesh stabilization approaches previously disclosed, potentially delivering a powerful, large-scale optimization environment for advanced industrial and research applications.

### Domain-specific Coupling of Novel Geometries and Voxel-based Data for Multi-Physics Models

According to an aspect of an embodiment, the disclosed platform may leverage novel mesh geometries (e.g., small volume bodies of constant width and/or dynamically stabilized moving meshes) in conjunction with voxel-based representations to facilitate multi-physics simulation spanning magnetism, electricity, thermal conduction, fluid flow, fluid-structure interaction and structural analysis. In one implementation, the platform may maintain distinct simulation meshes or discretization schemes for each physical domain—such as a specialized tetrahedral mesh for electromagnetic field calculations, a hex-or poly-prismatic mesh for computational fluid dynamics, and an unstructured triangular or quadrilateral surface mesh for mechanical finite element analysis (FEA). To unify and transfer information among these heterogeneous models, the system may create an auxiliary voxel “overlay” or “coupling grid,” wherein each voxel cell may serve as a localized data structure capturing state variables from different simulation domains.

### 1. Domain-specific Mesh Generation and Novel Geometries

The system may begin by generating or importing discrete meshes tailored to each domain. For instance, in a magnetics simulation, the platform may create a mesh that may focus on flux path refinement near ferromagnetic regions and coil windings; in fluid domains, the mesh may emphasize boundary layers or free-surface interfaces. Where advantageous, small volume bodies of constant width (SVBCW) or user-defined shapes may be embedded in certain mesh regions to improve mesh quality, reduce cell count, or handle complex geometry transitions. An adaptive mesh engine (with time-dependent stabilizations, if required) may further refine local cells around high-gradient zones (e.g., strong electromagnetic field transitions or turbulent fluid eddies) while simultaneously accommodating the geometric integrity of these novel shape elements.

### 2. Voxel Overlay Construction

In parallel, the platform may construct a uniform or sparse voxel grid spanning the same geometric bounding box (or relevant sub-domains) used by the domain-specific meshes. Each voxel may be assigned a unique spatial index, often via Morton or Hilbert curves, and a reversible mapping may ensure that the voxel data may be topologically consistent. This voxel grid may not need to have the same resolution everywhere; it may be refined adaptively in sub-regions of high interest (e.g., near strongly magnetized parts or high-temperature gradients). The resulting voxel set may be associated with an adjacency graph or hypergraph, supporting the algebraic operators (gradient, divergence, Laplace-Beltrami, etc.) described in prior embodiments.

### 3. Data Transfer and Field Interpolation

To couple the domain-specific mesh data to the voxel overlay, the system may perform an interpolation or projection step. For a given simulation mesh (e.g., a tetrahedral mesh used for magnetics), each mesh element's centroid or node set may be mapped into voxel coordinates. The field variables—such as magnetic potential, current density, or Maxwell stress—may then be interpolated onto the voxels that may spatially overlap with those elements. Conversely, the voxel field data may be mapped back onto another mesh: for example, to inform a thermal solver about localized Joule heating derived from the electromagnetic domain. This two-way data exchange may be facilitated by the discrete operators or incidence matrices defined on the voxel graph, ensuring that domain-agnostic PDEs may be evaluated or partially solved on a uniform grid when beneficial (e.g., for rapid sensitivity checks), even if the primary solver may remain on a domain-specific mesh.

4. Use Case: Magneto-thermal-structural Coupling

In a magneto-thermal-structural simulation, the platform may run an initial electromagnetic (EM) solver on a structured or unstructured mesh tailored to coil geometry, potentially capturing magnetic flux density and eddy currents in conductive regions. The resulting volumetric heating rate or power density distribution may be transferred onto the voxel grid, either by cell-averaging or nodal interpolation. A thermal solver—possibly operating on a different mesh or again on the voxel grid—may compute temperature evolution using PDEs (e.g., heat conduction). The updated temperature field may be mapped back to a mechanical FEA mesh, where thermal expansion or stress may be evaluated. If the mechanical solver may require incremental geometric changes (e.g., shape warping), those deformations may be again captured in the voxel layer to update boundary or interface conditions for the next electromagnetic solution step.

### 5. Novel Geometries in Fluid-structure Interaction (FSI)

In fluid-structure interaction problems, the system may embed small volume bodies of constant width into a structural mesh to reduce spurious mesh distortion, especially at interfaces experiencing large deformations. Voxel-based data exchange may be used to pass transient fluid pressure or velocity fields from a CFD mesh to the structural solver. When the structure may move or deform, the voxel mapping may be updated to reflect the new positions of structural mesh nodes, potentially ensuring accurate pressure load interpolation. This approach may streamline the multi-physics workflow: the fluid domain may benefit from a specialized mesh (e.g., boundary-fitted near surfaces, refined in swirling flow regions), while the structural domain may rely on novel shapes or advanced mesh movement to handle large strain. The voxel overlay may unify these disparate solvers by carrying the ephemeral cross-domain variables—pressure, velocity, displacement—back and forth in a consistent coordinate system.

### 6. Benefits and Extensions

Enhanced Scalability: Decoupling domain-specific mesh details via a common voxel layer may reduce the complexity of direct node-to-node mapping among multiple physics meshes. The indexing by Morton codes (or similar) may support efficient parallel data redistributions, particularly when running on GPU clusters or HPC nodes.

Preservation of Geometric Integrity: Novel shape-based elements in each domain-specific mesh may remain specialized to that physics domain without forcing identical meshing strategies across all models.

Multi-Fidelity Balancing: The platform may selectively use higher fidelity (i.e., unstructured or novel geometry-based) meshes where needed, while potentially relying on voxel-based uniform grids in less critical domains or as an alternative for fast PDE solves.

Adaptive Remeshing: If a domain may undergo significant geometric changes (e.g., thermal expansion, mechanical deformation), the voxel mapping may be quickly recomputed to reflect new positions or deformations. This may avoid complete re-generation of domain-specific meshes, potentially cutting down on the overhead in mid-simulation remeshing.

Support for Additional Physics: The architecture may extend naturally to electromagnetic-chemical, electrostatic-mechanical, or other coupled multiphysics scenarios where each solver may operate on an optimized domain representation but still may need exchange of physical fields (charge density, pH levels, etc.) via an intermediary voxel graph.

By thus integrating novel mesh geometries (for domain-optimized solutions) and a topological voxel-based overlay (for consistent multiphysics data transfer), this embodiment may provide a flexible, high-performance framework for multi-domain analyses. It may seamlessly orchestrate cross-model coupling, potentially ensuring that local refinements, advanced shape-based meshing strategies, and global PDE solves may remain coherently synchronized through a uniform voxel coordination layer.

For collaborative work, data visualization computing 140 may be configured to implement a distributed rendering system. This allows multiple users to simultaneously view and interact with the same visualization, with support for traditional devices and screens (including touch) as well as VR and AR devices and holographs (including with tactile feedback) for immersive exploration of designs or parameter spaces and ongoing simulation modeling run control and orchestration management (including pipeline, model, and data set changes). The system may use a client-server architecture with efficient data streaming protocols to enable real-time collaboration even over limited bandwidth connections.

The advanced materials design platform 100 is designed to integrate with a wide array of manufacturing 170 and materials science testing 180, spanning from nanoscale characterization tools to large-scale production machinery. At the nanoscale, the platform interfaces with advanced microscopy equipment such as (but not limited to) transmission electron microscopes (TEM) with in-situ testing capabilities, scanning tunneling microscopes (STM) for atomic-resolution surface analysis, and atomic force microscopes (AFM) for nanomechanical testing. These tools provide real-time data on atomic structure, surface topography, and nanoscale mechanical properties, which may be used for validating and refining atomic-scale simulations within the platform.

In the realm of semiconductor manufacturing for example, the platform integrates with state-of-the-art lithography systems, including extreme ultraviolet (EUV) lithography tools. It collects real-time data on parameters such as (but not limited to) overlay accuracy, critical dimension uniformity, and defect densities. The platform may be configured to interface with etching and deposition equipment, including, but not limited to, atomic layer deposition (ALD) systems, plasma etchers, and chemical vapor deposition (CVD) tools, gathering data on film thickness, composition, and uniformity during the manufacturing process.

For bulk material characterization, the platform may be configured to connect to X-ray diffraction (XRD) systems for crystal structure analysis, X-ray photoelectron spectroscopy (XPS) for surface chemical composition studies, and secondary ion mass spectrometry (SIMS) for depth profiling of elemental composition. It also integrates with mechanical testing equipment such as nanoindentation systems, tensile testers, and fatigue testing machines, collecting real-time stress-strain data and failure mode information.

In the field of thermal analysis, the platform may interface with differential scanning calorimetry (DSC) and thermogravimetric analysis (TGA) instruments, gathering data on phase transitions, decomposition temperatures, and heat capacity. For electrical characterization, it may connect to Hall effect measurement systems, four-point probe stations, and capacitance-voltage (C-V) measurement tools, collecting data on (but not limited to) carrier mobility, resistivity, and interface trap densities.

The platform may integrate with advanced spectroscopy tools such as Raman spectroscopy systems for vibrational mode analysis, Fourier transform infrared (FTIR) spectrometers for molecular bonding studies, and photoluminescence spectrometers for optoelectronic material characterization. In the realm of magnetic materials, it may interface with vibrating sample magnetometers (VSM) and superconducting quantum interference devices (SQUID) for high-precision magnetic property measurements.

For process monitoring in large-scale manufacturing, the platform may be configured to connect to in-line metrology tools such as optical and X-ray metrology systems, as well as advanced process control (APC) systems that manage entire production lines. It also integrates with environmental monitoring systems that track cleanroom conditions, including temperature, humidity, and particulate levels, which may significantly impact nanoscale manufacturing processes.

Furthermore, the platform is designed to interface with next-generation characterization tools that are pushing the boundaries of materials analysis. This includes, but is not limited to, ultrafast electron diffraction systems for studying dynamic processes at atomic time scales, operating characterization tools that allow for real-time observation of materials under working conditions, and AI-enhanced microscopy systems that may autonomously identify and characterize material features. By integrating with this diverse array of cutting-edge equipment, advanced materials design and engineering platform 100 ensures that it may leverage the most advanced experimental data available, enabling unprecedented accuracy and relevance in its simulations and optimizations.

The advanced materials design platform is engineered to integrate with and enhance a diverse array of operational environments 190 across the materials science and engineering landscape. In semiconductor fabrication facilities, it may interface with cutting-edge lithography systems like High-NA EUV tools, optimizing process parameters and boosting chip manufacturing yields. For battery manufacturing plants, the platform may assist in developing next-generation energy storage solutions, fine-tuning electrode formulations and molecule or cell assembly processes in real-time. In quantum computing research laboratories, it may aid in the design and optimization of quantum hardware components. The platform's versatility extends to materials characterization facilities, where it may interface with a suite of analytical instruments to interpret experimental data and guide further investigations. In additive manufacturing operations, it may optimize 3D printing or selective laser sintering or electron melting beam processes for novel materials (potentially adapting proven techniques for alternative environments such as at great pressure or at low gravity), while in aerospace materials testing facilities, it may predict material performance under extreme conditions. The platform's capabilities are equally valuable in energy storage and transmission facilities, assisting in the development of advanced materials for power systems. Although not its primary focus, the platform's molecular modeling capabilities find application in pharmaceutical research and development labs. In automotive design and testing facilities, it may contribute to the development of materials for electric vehicles, integrating with various simulation and testing systems. The platform also supports use cases in renewable energy research centers, corrosion testing laboratories, and high-performance computing centers, where it may leverages computational power for large-scale simulations and data analysis in materials research. This wide-ranging applicability underscores the platform's potential to accelerate innovation and improve outcomes across numerous sectors of materials science and engineering.

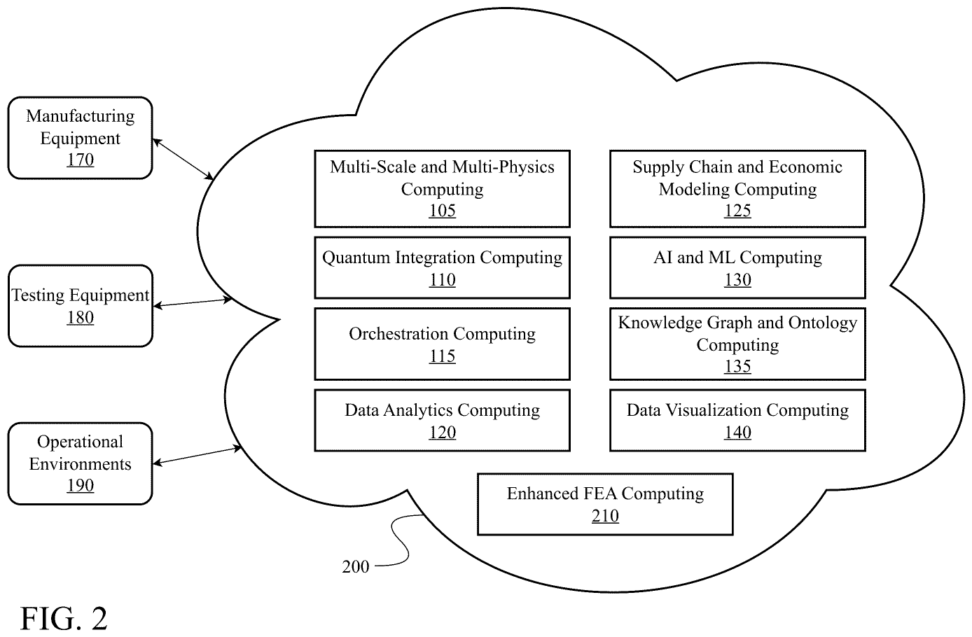

FIG. 2 is a block diagram illustrating an exemplary system architecture for an advanced materials design platform configured to support enhanced finite element analysis with novel geometries, according to an embodiment. As shown, in addition to the existing platform components (i.e., computing resources 105-140) this platform comprises an enhanced finite element analysis (FEA) computing system 210 which leverages advanced methods such as the application of novel geometries to enhance and support materials design.

The enhanced FEA using novel geometries approach offers significant benefits to materials design, particularly in advanced applications such as semiconductor device engineering. This innovative method, incorporating geometries like small volume bodies of constant width (SVBOCW) and soft cells derived from Dirichlet-Voronoi tessellations, enables more precise and efficient modeling of complex material structures. By leveraging these novel shapes, the enhanced FEA system may more accurately represent intricate geometries at various scales, from atomic-level structures to macroscale device designs. This may lead to improved simulation accuracy, especially in areas with complex stress distributions or unique material interfaces. The approach is particularly valuable in optimizing designs for advanced semiconductor devices, such as gate-all-around transistors, where traditional geometric representations may fall short in capturing the nuanced behaviors at nanoscale dimensions. The use of these novel geometries in FEA may allow for better modeling of critical phenomena like quantum confinement effects, electron transport, and thermal management in advanced materials and devices. Furthermore, this approach enhances the platform's 200 ability to explore unconventional design spaces, potentially leading to breakthrough innovations in material properties and device performance. The integration of these geometric innovations with adaptive meshing techniques and multi-physics simulations provides a powerful tool for researchers and engineers to push the boundaries of materials design, enabling the development of more efficient, reliable, and high-performing materials and devices across various technological domains.

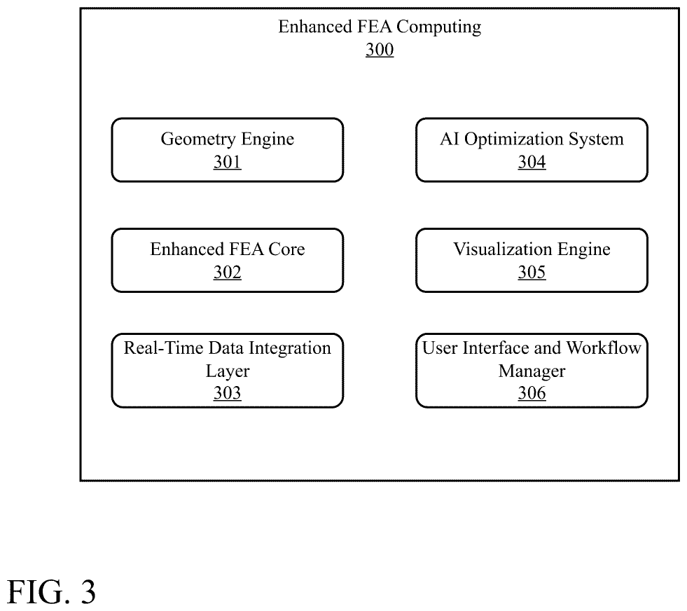

FIG. 3 is a block diagram illustrating an exemplary aspect of an advanced materials design platform, an enhanced FEA computing system. According to the aspect, enhanced FEA computing 300 comprises a geometry engine 301, an enhanced finite element analysis (FEA) core 302, an AI optimization system 304, a real-time data integration layer 303, a visualization engine 305, and a user interface and workflow manager 306.

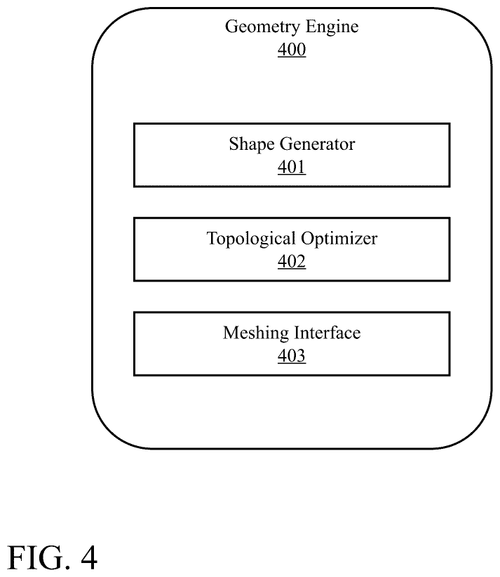

FIG. 4 is a block diagram illustrating an exemplary aspect of an advanced materials design platform, a geometry engine 400. According to some embodiments, geometry engine 400 is implemented as a sophisticated software module designed to generate, manipulate, and optimize novel geometric shapes for use in advanced material design, particularly in semiconductor applications. An exemplary geometry engine architecture may be based on a modular, object-oriented design, implemented in, for example, C++ for performance, with Python bindings for flexibility and ease of integration. According to an aspect, the core of the engine comprises three primary subcomponents: a shape generator, a topological optimizer, and a meshing interface.

According to the embodiment, a shape generator 401 implements algorithms for creating small volume bodies of constant width and soft cells derived from Dirichlet-Voronoi tessellations. For SVBOCW, it may utilize a parametric approach. The algorithm starts with a base polyhedron and applies a series of geometric transformations, including rotations and intersections, to generate the constant-width body. The soft cell generation may leverage a modified Voronoi algorithm that incorporates surface tension simulation to create organic, smoothly transitioning boundaries.

A topological optimizer 402 may employ gradient-based and evolutionary algorithms to refine the generated shapes for specific applications. It interfaces with AI optimization system 304, using techniques like adjoint sensitivity analysis to efficiently compute shape derivatives. This allows for rapid iteration on designs, optimizing for properties such as minimal surface area for a given volume (important for reducing current leakage in transistors) or maximal heat dissipation.

A meshing interface 403 translates the optimized geometries into formats suitable for finite element analysis. It may implement one or more adaptive meshing algorithms that may handle the complex curvatures of SVBOCW and soft cells, ensuring high-quality meshes that balance accuracy and computational efficiency. For example, this component may use octree-based spatial decomposition for initial coarse meshing, followed by local refinement strategies that adapt to geometric features and expected solution gradients.

According to an aspect, geometry engine 400 comprises a shape morphing algorithm, which allows for continuous transformation between different geometric configurations. This is particularly useful for exploring design spaces in semiconductor applications. The algorithm uses a combination of level set methods and physics-inspired deformation models to ensure that morphed shapes maintain desired properties (e.g., constant width) throughout the transformation. The system employs adaptive refinement strategies during morphing, automatically adjusting mesh density in regions of high geometric complexity while preserving the topological features critical for semiconductor device functionality.

For example, in designing a GAA transistor, geometry engine 400 may start with a traditional cylindrical nanowire channel. The shape generator may create an SVBOCW alternative, optimizing for maximal surface contact with the gate material while minimizing volume. The topological optimizer may then refine this shape, considering factors like electron mobility and quantum confinement effects. The meshing interface may generate a high-quality mesh of this optimized shape, with increased density around critical areas like the semiconductor-insulator interface. Throughout this process, the shape morphing algorithm may enable designers to visualize and analyze intermediate configurations, providing insights into the relationship between geometry and device performance.

According to an embodiment, geometry engine 400 exposes its functionality through a comprehensive API, allowing other platform 200 components to request specific shapes, initiate optimization processes, or query geometric properties. It may further comprise a caching mechanism to store and quickly retrieve previously generated shapes and their associated meshes, significantly speeding up iterative design processes. Additionally, or alternatively, a library (e.g., database) may be created and stored within geometry engine 400, the library comprising a plurality of generated (or otherwise obtained) shapes and their associated meshes.

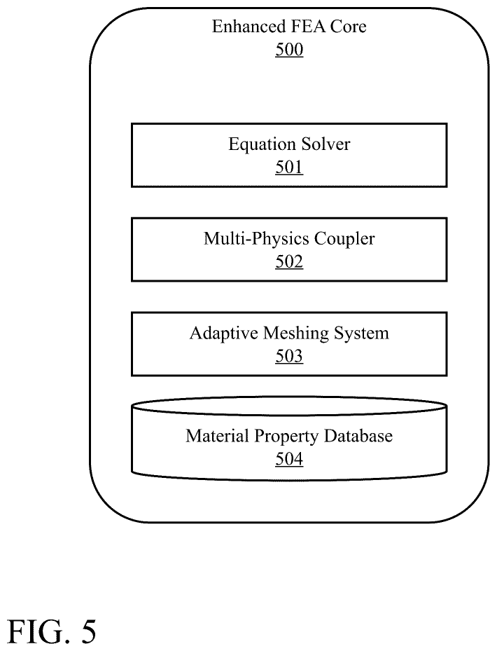

FIG. 5 is a block diagram illustrating an exemplary aspect of an advanced materials design platform, an enhanced FEA core 500. According to the aspect, enhanced FEA core 500 is implemented as a high-performance, multi-physics simulation engine designed to leverage novel geometries for advanced material analysis, particularly in semiconductor applications. According to an aspect, its architecture may be based on a distributed computing model, implemented in, for example, C++ and CUDA for optimal performance on heterogeneous computing environments. The core comprises several subcomponents: the equation solver 501, the material property database 504, the multi-physics couple 502r, and the adaptive meshing system 503.

According to an implementation, equation solver 501 may be configured to utilize a hybrid approach, combining finite element methods with spectral elements for higher-order accuracy. It may implement both direct (e.g., multi-frontal sparse LU decomposition) and iterative (e.g., preconditioned conjugate gradient) solvers, automatically selecting the most efficient method based on problem size and available computational resources. For nonlinear problems, it may employ advanced techniques such as the Newton-Raphson method with line search and trust-region algorithms to ensure robust convergence.

The material property database 504 is a comprehensive repository of material characteristics, including, but not limited to, anisotropic properties and temperature-dependent behaviors. It may use a hierarchical data structure for efficient querying and interpolation of properties across various scales and conditions. The database is dynamically updated through machine learning algorithms that incorporate new experimental data and theoretical predictions, ensuring that simulations always use the most up-to-date material models.

At the atomic and molecular level, material property database 504 comprises quantum mechanical properties such as electronic band structures, density of states, and electron/hole effective masses. It may store data on crystal structures, including lattice parameters, symmetry groups, and atomic positions. For semiconductors, it comprises, among other things, information on dopant types, concentrations, and their effects on band structure and carrier mobility. The database further comprises ab initio calculated properties like phonon spectra, which are useful for thermal transport simulations.

Moving to the mesoscale, material property database 504 stores information on grain structures, defect types, and distributions in polycrystalline materials, and/or the like. It may further comprise data on interfacial properties, such as surface energies, work functions, and band alignments, which are critical for modeling heterojunctions and device contacts. For composite materials, it may store information on constituent phases, their volume fractions, and spatial distributions.

At the macroscale, material property database 504 comprises a wide array of mechanical properties including, but not limited to, elastic moduli, Poisson's ratios, yield strengths, and plastic deformation parameters. These properties may be stored as tensors to account for material anisotropy. Thermal properties such as heat capacity, thermal conductivity, and thermal expansion coefficients may be included, often as temperature-dependent functions. Electrical properties like conductivity, dielectric constants, and piezoelectric coefficients may be stored, again accounting for anisotropy and frequency dependence where applicable.

The database may further comprise properties relevant to specific applications. For semiconductor devices, it may store carrier mobility models, recombination parameters, and impact ionization coefficients. For optoelectronic materials, it may include refractive indices, absorption coefficients, and luminescence data. Magnetic materials may be represented with properties like magnetic permeability, coercivity, and magnetostriction coefficients.

According to an aspect, database 504 is configured to store multi-physics coupling parameters. This may comprise thermoelectric coefficients, piezoelectric tensors, and magnetoelectric coupling constants, enabling accurate simulation of complex multi-functional materials. The database also maintains information on material degradation and fatigue properties, allowing for lifetime and reliability predictions.

To account for the scale-dependent nature of many properties, material property database 504 implements a multi-scale data structure in some embodiments. It may store and interpolate properties across different length scales, from nanometers to meters, and time scales from femtoseconds to years. This is particularly useful for modeling nanomaterials and nanostructured devices where bulk properties may not apply.

The database is designed to handle uncertainty and variability in material properties. It may store not just mean values but also statistical distributions, confidence intervals, and uncertainty quantification data. This allows for robust sensitivity analyses and probabilistic simulations, important for reliability engineering and yield optimization in semiconductor manufacturing.

According to an embodiment, material property database 504 comprises a metadata layer that stores information about data provenance, experimental conditions, and data quality metrics. This ensures traceability and allows users to assess data reliability for their specific simulation needs. The database may be further equipped with machine or deep learning algorithms that may predict missing properties based on known correlations and physical laws, continuously expanding its capabilities as new data becomes available.

Material property database 504 within the advanced materials design platform may employ a diverse array of database technologies to efficiently store, retrieve, and analyze the wide spectrum of data relevant to materials science. For instance, it may utilize a combination of relational databases (such as PostgreSQL or MySQL) for structured data and NoSQL databases (like MongoDB or Cassandra) for handling semi-structured and unstructured data. Time-series databases (e.g., InfluxDB or TimescaleDB) may be incorporated to manage temporal data, useful for tracking property changes over time or under varying conditions. Graph databases (such as Neo4j or Amazon Neptune) may be employed to represent complex relationships between materials, properties, and processes, facilitating advanced queries and knowledge discovery. For high-dimensional data and similarity searches, vector databases (like Pinecone or Milvus) may be integrated, enabling efficient storage and retrieval of material fingerprints and structural descriptors. The system may also leverage distributed storage solutions (such as Hadoop Distributed File System or Apache Cassandra) for managing large-scale datasets, including raw experimental data and simulation results. To enhance performance and support real-time analytics, in-memory databases (like Redis or Apache Ignite) may be utilized for caching frequently accessed data. This multi-faceted database approach, combined with a unified query interface and robust data integration layer, allows the platform to efficiently handle the diverse, multi-scale, and often heterogeneous nature of materials science data, from atomic-level properties to macroscale characteristics and manufacturing processes.

The multi-physics coupler 502 is responsible for managing the interactions between different physical domains (e.g., electrical, thermal, mechanical). According to an aspect, it implements a partitioned coupling approach with strong coupling algorithms like the block Gauss-Seidel iteration and the more advanced Interface Quasi-Newton technique with an approximation for the inverse of the Jacobian (IQN-ILS). This allows for accurate simulation of complex phenomena like electro-thermal-mechanical coupling in advanced semiconductor device, where the interaction between charge transport, Joule heating, and mechanical stress plays a crucial role in device performance. The coupler includes specialized handshake regions for scale bridging between atomic and continuum representations, implementing physics-preserving interpolation functions that maintain conservation properties across scale transitions while properly handling discontinuities through gradient-enhanced schemes.

The adaptive meshing system 503 is tailored to handle the complex geometries generated by geometry engine 400. It may use a hierarchical octree-based approach for initial mesh generation, followed by anisotropic mesh adaptation based on error estimators and solution gradients. For the novel SVBOCW shapes, it implements specialized meshing algorithms that preserve geometric features while optimizing element quality. The system may further comprise a dynamic load balancing mechanism for efficient parallel processing of the mesh.

A key process within enhanced FEA core 500 is the multi-scale simulation capability. It may employ a concurrent multi-scale approach, integrating atomistic simulations (e.g., using tight-binding or density functional theory) with continuum-level FEA. This may be achieved through a handshaking algorithm that ensures consistent energy and force calculations at the interface between scales. This algorithm is useful for accurately modeling phenomena that span multiple length scales, such as quantum effects in semiconductor devices or crack propagation in advanced materials.

According to an aspect, the handshaking algorithm creates a transition region between the atomistic and continuum domains, where both representations coexist and are coupled. This region, often referred to as the “handshake zone,” employs a blend of atomistic and continuum descriptions, gradually transitioning from one to the other. The algorithm uses a weighted average of atomistic and continuum energies and forces in this zone, ensuring smooth and physically consistent coupling between the two scales.

According to an embodiment, an implementation of a handshaking algorithm begins by defining overlap regions where both atomistic and continuum representations are valid. Within these regions, the algorithm constructs special hybrid elements that incorporate both discrete atomic positions and continuum field variables. These elements use shape functions that smoothly interpolate between atomic displacements and continuum deformation fields. The energy of these hybrid elements is computed as a weighted sum of atomistic and continuum contributions, with the weights varying spatially to affect a gradual transition.

According to another aspect, the disclosed methods and systems may also incorporate comprehensive simulation workflows for assessing the complete lifecycle of products that use these novel geometries. This may include virtual prototyping of assembly operations, in-service loading conditions, and end-of-life recycling or disassembly predictions. The platform integrates supply chain modeling, economic factors, and environmental impact indicators. This integration enables simulation of how shape modifications—such as switching to a certain variant of constant-width geometry—affect downstream manufacturing steps, product lifecycle cost, and carbon footprint. The platform may employ machine learning models as surrogates to rapidly evaluate alternative design configurations from an end-to-end sustainability perspective. This holistic approach encourages geometry choices that are not only optimal with respect to mechanical or fluid-dynamic performance but also feasible, cost-efficient, and ecologically mindful throughout the product lifecycle.

An important aspect of the handshaking algorithm is its treatment of boundary conditions between the atomistic and continuum regions. It may employ a technique called “ghost atom” padding, where several layers of virtual atoms are added to the edge of the atomistic region. These ghost atoms are controlled by the continuum solution, serving to transmit long-range elastic effects from the continuum domain into the atomistic region. Conversely, the algorithm aggregates atomic forces near the interface to compute equivalent continuum stresses, ensuring that atomistic effects are properly represented in the continuum domain.

The algorithm also addresses the challenge of thermal equilibration across scales. It implements a robust thermostating scheme that maintains consistent temperature distributions between the atomistic and continuum regions. This may be achieved through careful energy exchange calculations and the use of special thermostat elements in the transition zone.

To handle dynamic simulations, the handshaking algorithm may incorporate time-scale bridging techniques. It may use multiple time-step methods, where the atomistic region is evolved with smaller time steps than the continuum region, with synchronization occurring at specific intervals. This enables efficient simulation of fast atomic processes alongside slower continuum-scale dynamics.

The handshaking algorithm is adaptive, capable of dynamically adjusting the size and location of the atomistic region based on local solution features. It employs error estimators to identify regions where atomistic resolution is necessary, dynamically refining the multi-scale model as the simulation progresses. This adaptivity is particularly useful for simulating phenomena like crack propagation or dislocation movement, where the region of interest may change over time.

In the context of semiconductor device simulation, the handshaking algorithm enables accurate modeling of quantum confinement effects in nanoscale transistors while simultaneously capturing macroscale device characteristics. For instance, in a GAA transistor simulation, the algorithm may employ a full atomistic description in the channel region to capture quantum effects accurately, while using a continuum approach for the broader device structure, coupling these different representations to provide a comprehensive and computationally efficient simulation of the entire device.

For example, in simulating a GAA transistor with SVBOCW geometry, the enhanced FEA core may proceed as follows: The adaptive meshing system may generate a high-quality mesh of the SVBOCW-based channel, with refined elements near the semiconductor-insulator interface. The multi-physics coupler may set up a coupled electro-thermal-mechanical problem, accounting for quantum confinement effects in the channel. The equation solver may compute the electron distribution, current flow, and associated Joule heating. At critical points, such as high-field regions, the multi-scale simulation process may dynamically invoke atomistic calculations to accurately capture quantum effects. The material property database may provide temperature-dependent mobility models, updated in real-time based on the latest experimental data. Throughout the simulation, the adaptive meshing system may refine the mesh in regions of high solution gradients, ensuring accuracy while maintaining computational efficiency.

According to an embodiment, enhanced FEA core 500 exposes its functionality through a high-level API, allowing seamless integration with other platform components. It may comprise advanced visualization capabilities for real-time monitoring of simulations and supports checkpointing for long-running analyses. According to an aspect, enhanced FEA core 500 implements an error estimation and uncertainty quantification framework, providing confidence intervals for simulation results and guiding further refinement of the analysis.

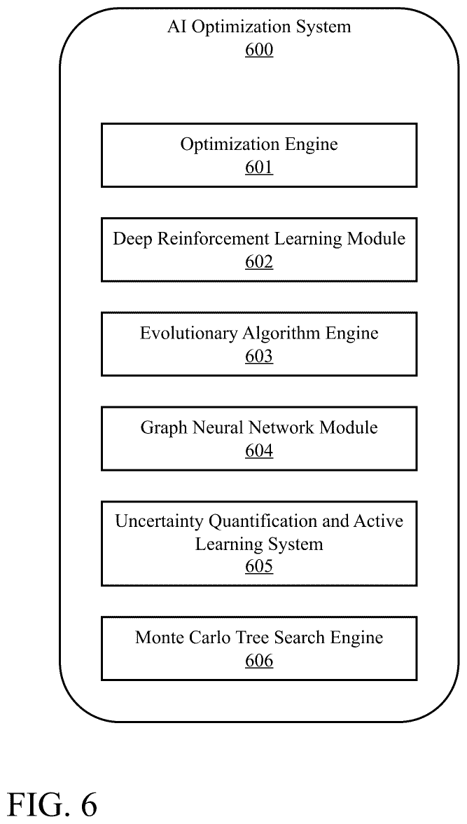

FIG. 6 is a block diagram illustrating an exemplary aspect of an advanced materials design platform, an AI optimization system 600. According to the aspect, AI optimization system 600 is implemented as a sophisticated ensemble of machine and/or deep learning algorithms and optimization techniques designed to navigate complex design spaces efficiently. According to an aspect, its architecture is built on a modular, scalable framework implemented primarily in, for example, Python, with performance-critical components written in C++ and leveraging GPU acceleration through CUDA and TensorFlow.

At the core of the system is a multi-fidelity Bayesian optimization engine 601. This engine constructs Gaussian process models of the design space, incorporating data from both high-fidelity (e.g., detailed FEA simulations) and low-fidelity (e.g., simplified analytical models) sources. It may implement advanced acquisition functions such as expected improvement (EI) and knowledge gradient (KG) to balance exploration and exploitation in the search process. The system may implement an adaptive sampling strategy that dynamically adjusts the ratio of high to low fidelity evaluations based on the current state of knowledge and computational budget.

The system integrates a deep reinforcement learning (DRL) module 602 based on the PPO algorithm. This module is particularly useful for optimizing sequential decision processes in material design, such as layer-by-layer growth in semiconductor fabrication. A DRL agent may be trained using a combination of simulated and real manufacturing data, with a custom reward function that balances multiple objectives like performance, yield, and cost.

A component of the AI optimization system is an evolutionary algorithm (EA) engine 603. This engine implements several variants of genetic algorithms, including NSGA-III for multi-objective optimization problems. It may use specialized encoding schemes to represent complex geometric structures like SVBOCW, and employ adaptive mutation and crossover operators that respect geometric constraints. The EA engine is particularly effective for exploring discontinuous or highly nonlinear design spaces often encountered in advanced material design.

According to an aspect, the AI optimization system further comprises a graph neural network (GNN) module 604 for learning and predicting structure-property relationships in materials. This GNN may be trained on a large database of material structures and their associated properties, allowing it to generalize across different material classes. It may use message passing neural networks to capture local atomic environments and global structural features, enabling accurate predictions of material properties for novel structures.

An aspect of AI optimization system 600 is its uncertainty quantification and active learning component 605. This module leverages techniques like Bayesian neural networks and ensemble methods to provide uncertainty estimates for its predictions. It may use these uncertainties to guide the optimization process, for example, focusing computational resources on regions of the design space with high uncertainty or potential for improvement.

The system comprises a Monte Carlo Tree Search (MCTS) engine 606, which is particularly useful for discrete optimization problems in material design. This MCTS implementation uses a hybrid approach that combines traditional tree search with neural network guidance. The system implements manufacturing-specific adaptations through a hierarchical-search structure that handles both hard constraints for manufacturing limitations and soft constraints through reward shaping. The engine executes an iterative optimization process that includes node selection, expansion using the policy network, simulation or value network evaluation, and backpropagation of results. Performance optimizations include parallel tree search with virtual loss, batch inference for neural networks, and priority-based node expansion. This implementation is especially effective for optimizing process parameters in semiconductor manufacturing, where the design space is often discrete and hierarchical. The engine maintains an experience replay buffer containing observed states, improved policy vectors, and outcomes, enabling continuous improvement through periodic neural network updates based on accumulated optimization experiences.

As an example application of the AI optimization system in the advanced materials design platform, consider the optimization of a GAA transistor design. The system may start by using its GNN module to predict initial performance characteristics of various SVBOCW-based channel geometries. The Bayesian optimization engine may then guide the exploration of this design space, using multi-fidelity models to balance between quick, approximate evaluations and detailed FEA simulations. The DRL module may be employed to optimize the layer deposition process, considering factors like thickness uniformity and interface quality. Simultaneously, the evolutionary algorithm engine may explore radical design variations, potentially discovering non-intuitive geometries that outperform traditional designs. Throughout this process, the uncertainty quantification module may guide the allocation of computational resources, ensuring efficient use of simulation time. Finally, the MCTS engine may be used to fine-tune discrete manufacturing parameters, optimizing for both performance and yield. This integrated approach allows the AI optimization system to efficiently navigate the vast and complex design space of advanced semiconductor devices, potentially discovering innovative designs that human engineers might overlook.

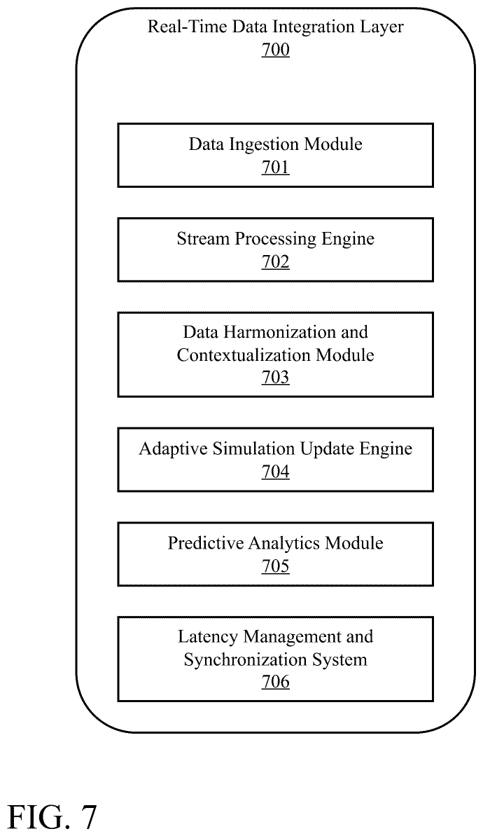

FIG. 7 is a block diagram illustrating an exemplary aspect of an advanced materials design platform, a real-time data integration layer 700. According to the aspect, real-time data integration layer 700 is a sophisticated system designed to incorporate live data from manufacturing processes and experimental setups into the simulation and optimization workflows. According to an aspect, its architecture may be based on a distributed, event-driven model, implemented using a combination of, for example, Apache Kafka for high-throughput message streaming, Apache Flink for complex event processing, and TimescaleDB for time-series data storage and analysis.

According to the embodiment, this layer comprises a data ingestion module 701, which utilizes a variety of protocols and APIs to interface with diverse data sources. It supports industry-standard protocols like OPC UA (Unified Architecture) and MQTT (Message Queuing Telemetry Transport) for real-time communication with manufacturing equipment. For more specialized instruments, it employs custom drivers and adapters. The module implements a robust error handling and data validation system, ensuring the integrity and consistency of incoming data streams.

Stream processing engine 702 is responsible for real-time data analysis and event detection. It may employ complex event processing (CEP) techniques to identify significant patterns or anomalies in the data streams. The engine may use a combination of rule-based systems and machine learning models (such as autoencoders for anomaly detection) to process the incoming data. It may handle high-velocity data streams, performing operations like windowing, aggregation, and joining of multiple streams in real-time.

According to the embodiment, a data harmonization and contextualization module 703 is present. This module aligns data from different sources, accounting for variations in sampling rates, units, and formats. It may employ sophisticated time-series alignment algorithms and semantic data models to contextualize the incoming data within the broader manufacturing process. The module also implements data imputation techniques to handle missing or erroneous data points, ensuring continuous and reliable data flow.

An adaptive simulation update engine 704 is responsible for integrating the processed real-time data into ongoing simulations. According to an aspect, it uses an approach combining Kalman filtering and particle filters to dynamically update simulation parameters and boundary conditions based on the latest data. This engine may implement a multi-rate integration scheme, allowing for efficient coupling between fast-changing sensor data and slower-evolving simulation states.

The system further comprises a predictive analytics module 705 that leverages machine learning techniques to forecast future states based on current trends in the real-time data. It may employ an ensemble of models, including, for example, LSTM (Long Short-Term Memory) networks for sequence prediction and Gaussian process regression for uncertainty quantification. These predictions may be fed back into the simulation and optimization processes, allowing for proactive adjustments to manufacturing parameters.

An aspect of the real-time data integration layer comprises a latency management and synchronization system 706. This system uses advanced time synchronization protocols (like precision time protocol) to ensure accurate timestamping across distributed data sources. It implements adaptive buffering techniques to handle network jitter and maintain coherent data streams. The system may further comprise a predictive pre-fetching algorithm that anticipates data needs based on the current state of simulations and optimization processes.

As an example, consider the optimization of a high-NA EUV lithography process for advanced semiconductor manufacturing. The data ingestion module may interface with the EUV lithography tool, collecting real-time data on parameters such as laser pulse energy, mirror temperatures, and stage positioning accuracy. The stream processing engine may analyze this data in real-time, detecting any deviations from optimal process conditions.

The data harmonization module may contextualize this information with data from other parts of the manufacturing line, such as resist coating thickness and development rates. The adaptive simulation update engine may use this integrated data to dynamically adjust the FEA simulations of the photoresist exposure process, updating parameters like the optical absorption profile and chemical reaction rates in real-time.

Simultaneously, the predictive analytics module may forecast potential drift in the lithography tool's performance over the next few hours based on current trends. This prediction may be used to proactively adjust the AI optimization system's objectives, perhaps favoring more robust design solutions that may tolerate greater process variation.

Throughout this process, the latency management system ensures that all data is properly time-aligned, allowing for accurate correlation between manufacturing events and observed outcomes in the finished semiconductor devices. This real-time integration and analysis enable advanced materials design platform 200 to rapidly adapt to changing manufacturing conditions, optimizing both the design and the manufacturing process simultaneously for maximum yield and performance.

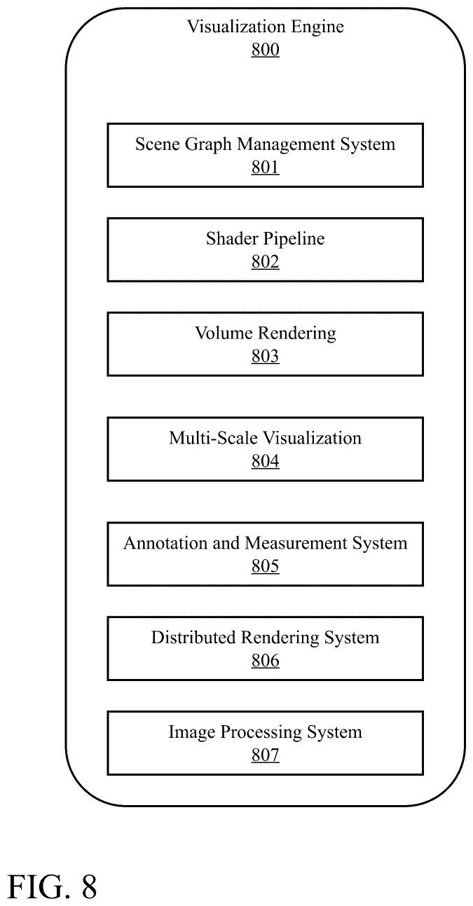

FIG. 8 is a block diagram illustrating an exemplary aspect of an advanced materials design platform, a visualization engine 800. According to the aspect, visualization engine 800 in advanced materials design platform 200 is a sophisticated, high-performance system designed to render complex 3D geometries, multi-physics simulation results, and optimization processes in real-time. According to an aspect, its architecture may be based on a scalable, multi-threaded design implemented primarily in, for example, C++ and OpenGL, with additional support for hardware-accelerated ray tracing through NVIDIA's OptiX framework. The engine may employ a modular structure, allowing for easy integration of new visualization techniques and algorithms as they become available.

According to an embodiment, visualization engine 800 utilizes an advanced scene graph management system 801. This system may use spatial partitioning techniques such as octrees and bounding volume hierarchies (BVH) to efficiently organize and render large, complex geometric datasets. For handling the novel geometries like SVBOCW generated by geometry engine 400, it may implement custom tessellation algorithms that may adaptively refine the mesh based on view distance and curvature, ensuring smooth rendering of these complex shapes while maintaining performance.

According to an aspect, the engine incorporates a state-of-the-art shader pipeline 802 that supports physically-based rendering (PBR) techniques. This allows for realistic visualization of material properties, useful for accurately representing the optical characteristics of semiconductor materials and device structures. The shader system is highly customizable, allowing researchers to develop and integrate specialized shaders for visualizing specific physical phenomena, such as electron density distributions or heat flow patterns.

For multi-physics simulation data visualization, the engine employs advanced volume rendering techniques 803. For example, it may use a GPU-accelerated ray marching algorithm with adaptive sampling to efficiently render 3D scalar and vector fields. The engine supports real-time manipulation of transfer functions, allowing users to interactively explore different aspects of the simulation data. It may also implement streamline and pathline generation algorithms for visualizing flow fields and particle trajectories, which is particularly useful for analyzing carrier transport in semiconductor devices.

A feature of the visualization engine is its support for multi-scale visualization 804. It may implement a level-of-detail (LOD) system that may seamlessly transition between atomic-scale representations and continuum-level visualizations. According to an aspect, this may be achieved through a combination of procedural geometry generation and texture-based detail rendering, allowing users to zoom from device-level views down to individual atom configurations without loss of interactivity.

The engine may further comprise a powerful annotation and measurement system 805. This allows users to add labels, perform on-the-fly measurements, and create cross-sectional views of complex 3D structures. It also supports the overlay of analytical data, such as graphs and charts, directly onto the 3D visualization, providing contextual information alongside the geometric representation.

For collaborative work, visualization engine 800 implements a distributed rendering system 806. This allows multiple users to simultaneously view and interact with the same visualization, with support for virtual reality (VR) and augmented reality (AR) devices for immersive exploration of design spaces. The engine may use a client-server architecture with efficient data streaming protocols to enable real-time collaboration even over limited bandwidth connections.

The engine also incorporates advanced image processing capabilities 807 for enhancing visualization quality and extracting meaningful information from rendered images. This may comprise (but is not limited to) support for ambient occlusion, edge detection, and feature highlighting algorithms, which may help in identifying critical regions in complex geometries or simulation results.

As an example, consider the interactive exploration of a GAA transistor design optimization process. The engine may render the SVBOCW-based channel geometry in high detail, allowing users to examine the intricate surface structures that maximize gate control. As the AI optimization system explores different designs, the visualization engine may provide real-time updates, showing how changes in geometry affect the electric field distribution and carrier transport.

The multi-physics visualization capabilities may be used for displaying the results of electro-thermal simulations. Users may interactively switch between viewing the electric potential distribution, current density, and temperature gradients, all overlaid on the 3D transistor structure. The engine's volume rendering techniques may allow for the visualization of electron density clouds within the channel, providing insights into quantum confinement effects.

The multi-scale visualization features may enable seamless transition from the device-level view down to the atomic structure of the semiconductor-insulator interface. This may be particularly useful for examining how different atomic configurations at the interface affect overall device performance.

Throughout the optimization process, the engine may provide real-time visual feedback on the exploration of the design space. It may be configured to render a 3D scatter plot of design parameters, with each point representing a specific transistor configuration, color-coded by performance metrics. As the AI system converges on optimal designs, the visualization may update, allowing researchers to intuitively understand the relationships between geometric features and device characteristics.

This comprehensive and interactive visualization capability enables researchers and engineers to gain deep insights into the complex relationships between material structure, device geometry, and performance characteristics, significantly accelerating the design and optimization process for advanced semiconductor devices.

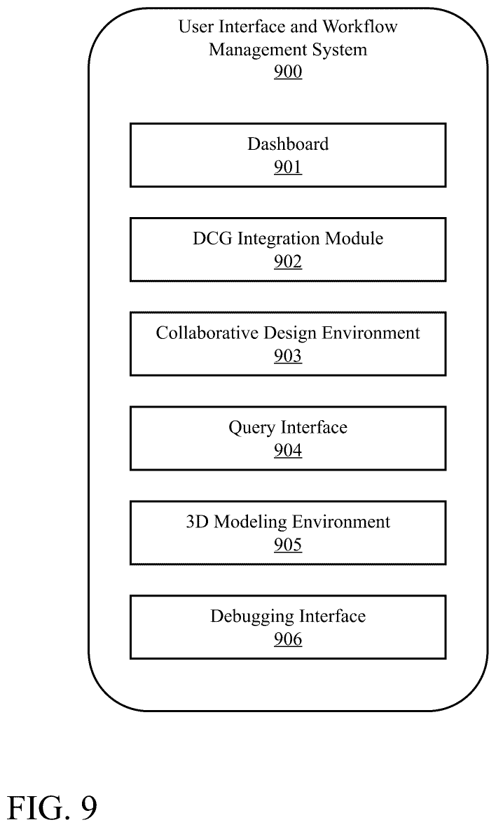

FIG. 9 is a block diagram illustrating an exemplary aspect of an advanced materials design platform, a user interface and workflow management system 900. According to the aspect, user interface and workflow management system 900 of advanced materials design platform 200 is a sophisticated, modular system designed to provide intuitive access to the platform's complex functionalities while orchestrating multi-step design and simulation processes. According to an aspect, its architecture may be based on a microservices model, implemented primarily in, for example, Python for the backend services, with a React-based frontend for maximum responsiveness and cross-platform compatibility. The system may employ a state management library such as, for example, Redux for maintaining a consistent application state across multiple user sessions and devices.

According to an embodiment, the user interface features a highly customizable dashboard system 901. This dashboard may utilize a widget-based architecture, allowing users to drag-and-drop various tools and visualizations into their workspace. Each widget is backed by a microservice, enabling real-time updates and interactions. The system may be configured to implement a context-aware recommendation engine that suggests relevant widgets and tools based on the current workflow stage and user behavior, leveraging machine learning algorithms to continuously improve its recommendations.

The workflow management subsystem may be built on a directed computational graph (DCG) model 902 tailored for materials design processes. It allows users to visually construct complex workflows by connecting nodes representing different simulation, optimization, storage, compute, and analysis steps. The system may be configured with a smart scheduler that optimizes task execution based on available computational resources and dependencies between tasks. It may also implement checkpoint and rollback mechanisms, allowing users to revert to previous stages in the design process or explore alternative paths.

According to an aspect, the system comprises a collaborative design environment 903. This environment supports real-time multi-user interactions, leveraging WebSocket (for example) technology for low-latency updates. It implements a version control system tailored for material designs, allowing branching and merging of design variants. The system also includes an annotation and commenting feature, enabling asynchronous collaboration and knowledge sharing among team members.

The UI and workflow management component may consist of an advanced query interface 904 for material property database 504. This interface may utilize NLP techniques to interpret user queries, translating them into optimized database queries. It may further comprise an intelligent autocomplete system that suggests relevant properties and materials based on the current context of the design process.

For handling complex geometric designs, the interface may include a specialized 3D modeling environment 905. This environment integrates directly with geometry engine 400, allowing users to interactively manipulate SVBOCW and other advanced geometries. It may be configured to implement gesture-based and voice-controlled interactions, making it compatible with VR/AR systems for immersive design experiences.

According to an embodiment, the workflow management system comprises a sophisticated error handling and debugging interface 906. It may provide visual traceback of errors in complex simulation pipelines, allowing users to quickly identify and address issues. The system may also implement predictive error detection, using machine learning models trained on historical workflow data to flag potential issues before they occur.

As an example, consider the optimization of a next-generation semiconductor device. The process may start with a user accessing the dashboard and selecting a “New Device Design” widget. The recommendation engine may then suggest relevant widgets such as “Material Selection,” “Geometry Design,” and “Process Parameter Definition.”

As the user begins to define the device structure using the 3D modeling environment, they may seamlessly switch between manipulating the overall device geometry and fine-tuning atomic-scale features at critical interfaces. The interface may provide real-time feedback on how these changes might affect device performance, based on quick approximate simulations.

The user may then construct a workflow for device optimization. This may comprise defining a sequence of steps: initial FEA simulation, AI-driven geometry optimization for mesh and mesh boundaries, multifidelity optimization for model definition and sequencing, detailed multi-physics simulation of top candidates with dedicated feedback loop, output acceptance upon reaching sufficient uncertainty, accuracy, precision targets or cost limits, final performance evaluation, reporting, and result export. The workflow management system (and/or a DCG-supported system) may orchestrate this process, automatically distributing tasks across available computational resources and providing real-time status updates.

Throughout the optimization process, the user may use the collaborative features to share interim results with team members, who may then annotate the designs or suggest modifications. The version control system may allow exploration of different design branches, perhaps comparing devices optimized for high performance versus those optimized for low power consumption.

If any issues arise during the simulation or optimization steps, the error handling interface may provide detailed diagnostics, potentially suggesting corrective actions. The user may use the natural language query interface to quickly look up relevant material properties or previous similar designs, integrating this information into the current workflow.

Furthermore, as the optimization nears completion, the interface may present a comprehensive visualization of the design space explored, highlighting the Pareto frontier of optimal designs. The user may then select the most promising candidates for further analysis or prototype fabrication, with all the relevant data and process steps automatically documented for future reference.

This integrated and intuitive interface, combined with powerful workflow management capabilities, enables researchers and engineers to efficiently navigate the complex process of advanced materials design, from initial concept to optimized device, while fostering collaboration and maintaining a clear record of the design process.

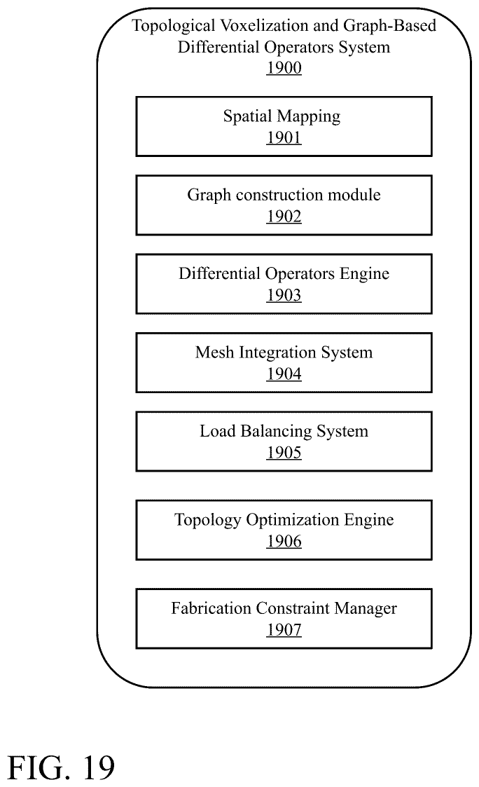

FIG. 19 is a block diagram illustrating an exemplary aspect of the Topological Voxelization and Graph-Based Differential Operators System 1900. The Spatial Mapping 1901 may perform the critical task of converting boundary or point-cloud representations of three-dimensional domains into consistent voxel formats. This conversion may be accomplished through the application of a reversible function f: [symbol] ³→ [symbol] ³, which may be subsequently refined via sparse raster structures to mitigate memory overhead. To manage large voxel grids efficiently while preserving geometric fidelity and topological consistency, the system may employ Morton codes or similar space-filling curve indices. This sophisticated approach may drastically reduce the complexity of point and element lookups while maintaining the integrity of the underlying geometric structure.

The graph construction module 1902 may form the mathematical foundation for constructing an adjacency matrix A and incidence matrices M. These matrices may together define the discrete analogs of differential operators, working in concert with the Differential Operators Engine 1903 to implement the gradient G, divergence D, and Laplace-Beltrami L operators. These operators may then be employed within the platform's finite-element or finite-volume frameworks to solve partial differential equations or to evaluate topological measures across the voxelized geometry with high accuracy and efficiency.

The Mesh Integration System 1904 may combine generated voxel-based operators with dynamic mesh movement and space-time stabilization methods. This hybrid approach may allow users to selectively deploy voxel grids in regions that may benefit from uniform sampling, such as near complex internal voids, while simultaneously preserving advanced unstructured meshes or body-fitted meshes elsewhere. The computational efficiency of graph-based PDE solvers, which may be particularly amenable to parallelization on GPUs or multi-node clusters, may thus be combined with the geometric flexibility of novel small-volume bodies of constant width or other user-defined anisotropic geometries. The load balancing system 1905 may represent a sophisticated orchestration layer, implemented through MPI-based distributed processing, that may continuously monitor regions of elevated computational intensity. In areas experiencing high stress during topology optimization, the system may adaptively subdivide and refine the voxel data in local neighborhoods. This dynamic refinement may ensure that additional compute resources are allocated precisely where they may be needed for fine-grained PDE updates, optimizing both performance and accuracy.

The Topology Optimization Engine 1906 may seamlessly integrate with the voxel operators, enabling rapid evolution of interior structures toward application-specific mechanical or thermal objectives. The GPU-accelerated solver may leverage the adjacency and incidence matrices derived from the voxel grid to perform compliance minimization under various constraints, including minimum thickness and volumetric usage requirements. During each optimization iteration, the platform's intelligence layer, which may employ reinforcement learning or gradient-based sensitivity analysis, may update voxel occupancy to reduce local material usage in low-stress regions while preserving or thickening critical load-bearing paths. A significant performance advantage may be achieved through the platform's voxel-to-graph mapping approach. The matrix assembly and factorization steps in the PDE solver may exhibit approximately linear scaling in the number of non-empty voxels, rather than scaling with total volumetric dimension. This improvement in solver efficiency may enable the processing of models comprising tens of millions of voxels, achieving near-interactive rates for high-fidelity mechanical or thermal optimization tasks. Such performance may have previously been attainable only on high-performance computing clusters but may now be achieved on standard desktop computers through careful optimization of memory usage and computational procedures.

The Fabrication Constraint Manager 1907 may maintain comprehensive compatibility with fabrication constraints and mechanical performance requirements. Users may incorporate explicit printability rules directly into the voxel domain, ensuring that optimized structures may remain physically realizable. The system may support the application of shape constraints through intelligent masking or cloning of voxel neighborhoods, enabling design features to comply with user-defined symmetry planes or repetition frequencies. This may result in high-resolution, topology-optimized parts that may be not only numerically stable for PDE-driven simulations but also immediately suitable for additive manufacturing processes. Through integration of high-performance GPU computation with mathematically rigorous topology preservation, the system may achieve both practical efficiency and theoretical correctness. This combination of capabilities may enable the processing of extremely high-resolution models while maintaining topological accuracy throughout the optimization process. The platform's approach to combining theoretical guarantees with practical performance optimization may make it particularly well-suited for advanced industrial applications that demand both precision and computational efficiency.

According to an aspect of an embodiment, the platform may leverage specialized mesh geometries in conjunction with voxel-based representations to facilitate comprehensive multi-physics simulation spanning magnetism, electricity, thermal conduction, fluid flow, fluid-structure interaction, and structural analysis. The platform may maintain distinct simulation meshes or discretization schemes for each physical domain, such as a specialized tetrahedral mesh for electromagnetic field calculations, a hex-or poly-prismatic mesh for computational fluid dynamics, and an unstructured triangular or quadrilateral surface mesh for mechanical finite element analysis (FEA). To unify and transfer information among these heterogeneous models, the system may create an auxiliary voxel “overlay” or “coupling grid,” wherein each voxel cell may serve as a localized data structure capturing state variables from different simulation domains.

The system may begin by generating or importing discrete meshes tailored to each domain's specific requirements. Where advantageous, small volume bodies of constant width (SVBCW) or user-defined shapes may be embedded in certain mesh regions to improve mesh quality, reduce cell count, or handle complex geometry transitions. An adaptive mesh engine, incorporating time-dependent stabilizations when required, may further refine local cells around high-gradient zones while simultaneously accommodating the geometric integrity of these novel shape elements. Through its sophisticated mathematical framework and optimized computational approach, the platform may construct either uniform or sparse voxel grids spanning the same geometric bounding box used by the domain-specific meshes. Each voxel may be assigned a unique spatial index through Morton or Hilbert curves, and a reversible mapping may ensure topological consistency throughout the process. This voxel grid may be adaptively refined in sub-regions of high interest and may be associated with an adjacency graph or hypergraph that may support a comprehensive set of algebraic operators for various analytical and simulation purposes.

The coupling of domain-specific mesh data to the voxel overlay may be accomplished through careful interpolation and projection steps. Field variables may be interpolated onto voxels that spatially overlap with mesh elements, and this data may be mapped back onto other meshes as needed. This bidirectional data exchange may be facilitated by discrete operators or incidence matrices defined on the voxel graph, ensuring that domain-agnostic PDEs may be evaluated or partially solved on a uniform grid when beneficial to the overall simulation process.

The platform's architecture may exhibit natural extensibility to a wide range of coupled multiphysics scenarios, where each solver may operate on an optimized domain representation while maintaining the ability to exchange physical fields through an intermediary voxel graph. This integration of specialized mesh geometries with a topological voxel-based overlay may provide a flexible, high-performance framework for multi-domain analyses. The system may ensure that local refinements, advanced shape-based meshing strategies, and global PDE solves may remain coherently synchronized through a uniform voxel coordination layer.

Consider a magneto-thermal-structural simulation as an example of this integration in practice. The platform may begin by running an electromagnetic solver on a structured or unstructured mesh specifically tailored to coil geometry, capturing magnetic flux density and eddy currents in conductive regions. The resulting volumetric heating rate or power density distribution may be transferred onto the voxel grid through cell-averaging or nodal interpolation. A thermal solver may then compute temperature evolution using PDEs, potentially operating on either a different mesh or the voxel grid itself. The updated temperature field may be mapped back to a mechanical FEA mesh for thermal expansion or stress evaluation. If geometric changes are required, such as shape warping, these deformations may be captured in the voxel layer to update boundary conditions for subsequent electromagnetic solution steps. In fluid-structure interaction scenarios, the system may demonstrate even more sophisticated coupling capabilities. Small volume bodies of constant width may be embedded into structural meshes to reduce spurious mesh distortion, particularly at interfaces experiencing large deformations. The voxel-based data exchange system may facilitate the transfer of transient fluid pressure or velocity fields from the CFD mesh to the structural solver. As structures move or deform, the voxel mapping may be dynamically updated to reflect new node positions, maintaining accurate pressure load interpolation throughout the simulation.

This integrated approach may offer several key advantages. First, the decoupling of domain-specific mesh details through a common voxel layer may reduce the complexity of direct node-to-node mapping among multiple physics meshes, with Morton code indexing supporting efficient parallel data redistributions on GPU clusters or HPC nodes. Second, novel shape-based elements in each domain-specific mesh may remain specialized to their respective physics domains without forcing identical meshing strategies across all models. Third, the platform may selectively deploy higher fidelity meshes where needed while relying on voxel-based uniform grids in less critical domains. Finally, for domains undergoing significant geometric changes, the voxel mapping may be quickly recomputed to reflect new positions or deformations without requiring complete regeneration of domain-specific meshes. The architecture may naturally extend to additional physics couplings, such as electromagnetic-chemical or electrostatic-mechanical interactions, where specialized solvers may operate on optimized domain representations while exchanging physical fields through the intermediary voxel graph. This comprehensive approach to multi-physics integration may enable the platform to tackle increasingly complex engineering challenges while maintaining both computational efficiency and solution accuracy.

### Detailed Description of Exemplary Aspects

The methods and processes described herein are illustrative examples and should not be construed as limiting the scope or applicability of the advanced materials design platform. These exemplary implementations serve to demonstrate the versatility and adaptability of the platform. It is important to note that the described methods may be executed with varying numbers of steps, potentially including additional steps not explicitly outlined or omitting certain described steps, while still maintaining core functionality. The modular and flexible nature of the advanced materials design platform allows for numerous alternative implementations and variations tailored to specific use cases or technological environments. As the field evolves, it is anticipated that novel methods and applications will emerge, leveraging the fundamental principles and components of the platform in innovative ways. Therefore, the examples provided should be viewed as a foundation upon which further innovations may be built, rather than an exhaustive representation of the platform's capabilities.

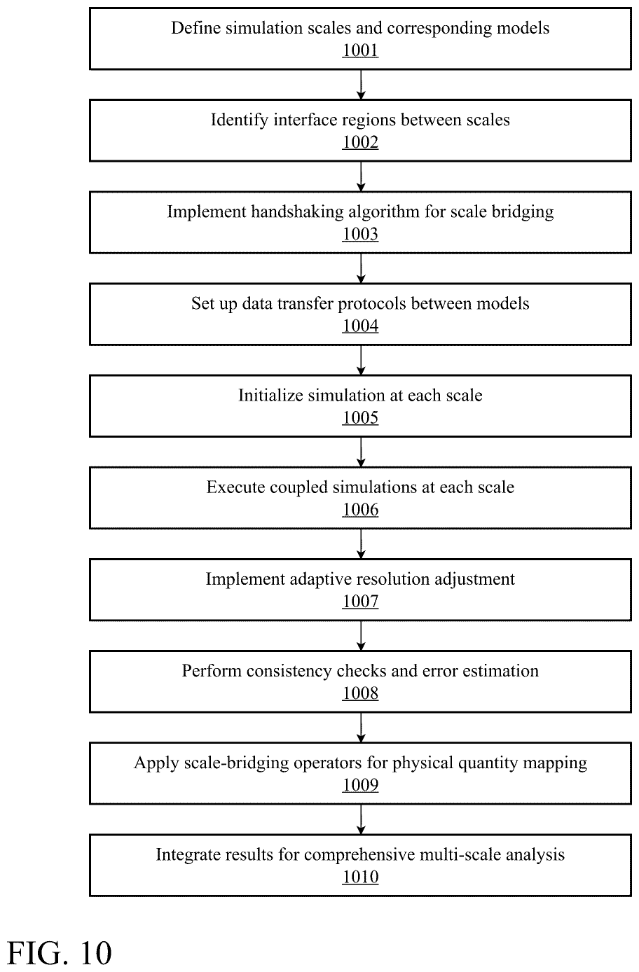

FIG. 10 is a flow diagram illustrating an exemplary method for multi-scale modeling integration, according to an embodiment. This integration with advanced materials design platform enables seamless coupling of simulations across multiple length and time scales. According to the embodiment, the process begins at step 1001 by defining the relevant simulation scales and corresponding models, such as density functional theory for atomic scale, molecular dynamics for nanoscale, and finite element analysis for macroscale. Interface regions between these scales are then identified at step 1002, where information exchange will occur. An important component is the implementation of a handshaking algorithm at step 1003 that bridges different scales, ensuring consistent representation of physical quantities across scale boundaries. Data transfer protocols are established to facilitate efficient communication between models at step 1004. The system initializes simulations at each scale with appropriate boundary conditions and initial states at step 1005. The coupled simulations are then executed with iterative feedback loops at step 1006, allowing information to flow bidirectionally between scales. Meshes, boundaries, interfaces, variable space-time stabilization, and fidelity convergence may be optimized or adjusted on an ongoing basis (e.g., to balance the information gain associated with incremental simulation runs at various fidelities or techniques against their marginal costs). Such optimization may be direct or indirect, improving specific model outputs of particular interest to the modeling, design, or experimental evaluation at hand. It should be appreciated that such optimization may also be based on indirect goals, such as reducing fundamental knowledge gaps in knowledge corpora (e.g., the knowledge graph for chemistry, proteins, atoms, and molecules), addressing training data shortcomings for specific physics or numerical models, or enhancing process-centric simulation models like discrete event system simulation with dynamical system model improvements. As the simulation progresses, the platform implements adaptive resolution adjustment at step 1007, dynamically refining or coarsening the model resolution based on evolving system behavior. Consistency checks and error estimation procedures at step 1008 are continuously performed to ensure the validity and accuracy of the multi-scale integration. At step 1009, scale-bridging operators are applied to map physical quantities between different scales, maintaining physical consistency. Finally, the results from all scales are integrated at step 1010 to provide a comprehensive multi-scale analysis of the material system.

An example application of this method in the advanced materials design platform is in the simulation of a GAA transistor with a novel SVBOCW channel. The atomic-scale DFT simulations may model the electronic structure of the channel material and its interfaces with the gate dielectric. This information may be passed to MD simulations modeling the atomic-scale processes at the semiconductor-insulator interface. The handshaking algorithm may then couple these atomistic results with continuum-level FEA models of the channel and surrounding device structure. As the simulation progresses, areas of high electron density or stress might be identified, triggering adaptive refinement in those regions. The platform may continuously check for consistency between the quantum mechanical description of electron behavior and the continuum representation of charge distribution. Scale-bridging operators may map quantities like charge density and potential between the atomic and device scales. The final integrated results may provide insights into how atomic-scale phenomena influence the overall transistor performance, enabling optimization of the SVBOCW geometry for enhanced device characteristics.

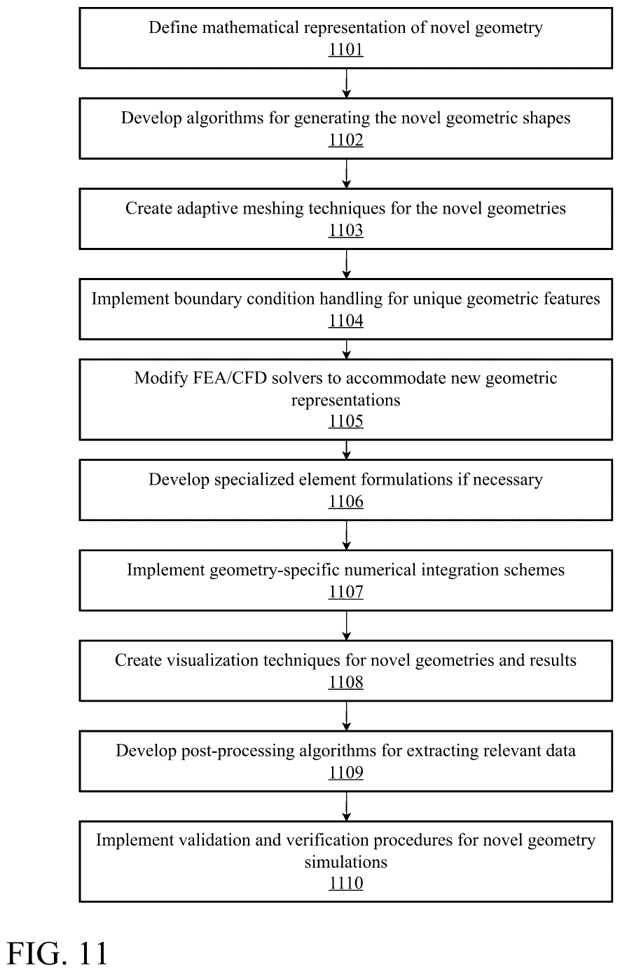

FIG. 11 is a flow diagram illustrating an exemplary method for novel geometry implementation in FEA and CFD, according to an embodiment. According to the embodiment, the process begins at step 1101 with defining a precise mathematical representation of the novel geometry, such as small volume bodies of constant width. This is followed by developing and implementing robust algorithms to generate these complex shapes within the simulation environment at step 1102. The platform then creates adaptive meshing techniques specifically designed to handle the unique features of these geometries, ensuring accurate discretization while maintaining computational efficiency at step 1103. Special attention is given to implementing boundary condition handling that accounts for the distinct characteristics of these novel shapes, such as constant width properties at step 1104. The core FEA and CFD solvers are modified to accommodate these new geometric representations, including updates to element connectivity and matrix assembly procedures at step 1105. In some cases, specialized element formulations may need to be developed to accurately capture the behavior of materials within these novel geometries at step 1106. The platform implements geometry-specific numerical integration schemes to ensure accurate calculation of element matrices and load vectors at step 1107. New visualization techniques are created to effectively display these complex geometries and the resulting simulation data at step 1108. Post-processing algorithms are developed to extract relevant engineering data from the simulation results, accounting for the unique aspects of the novel geometries at step 1109. At step 1110, rigorous validation and verification procedures are implemented to ensure the accuracy and reliability of simulations involving these new geometric representations.

As an example, consider the implementation of SVBOCW geometries in the design of a heat sink for advanced semiconductor devices. The platform may start by generating a SVBOCW-based fin structure for the heat sink using the developed algorithms. The adaptive meshing technique may create a high-quality mesh that captures the complex curvatures of the SVBOCW geometry while optimizing element density in critical areas. The CFD solver, modified to handle these novel shapes, may simulate the airflow around the fins, with special boundary condition handling at the constant-width surfaces. Specialized element formulations may be used to accurately model heat transfer at the interface between the SVBOCW fins and the base plate. The platform may employ custom numerical integration schemes to calculate heat flux and fluid drag on the unique surfaces. Advanced visualization techniques may allow designers to observe temperature distributions and flow patterns around the complex fin structures. Post-processing algorithms may extract key performance metrics like heat dissipation efficiency and pressure drop across the heat sink. Through this process, the platform may optimize the SVBOCW-based heat sink design, potentially achieving higher cooling performance and material efficiency compared to traditional designs. The implemented validation procedures may ensure the reliability of these novel simulation results, providing confidence in the performance predictions of this advanced heat sink design.

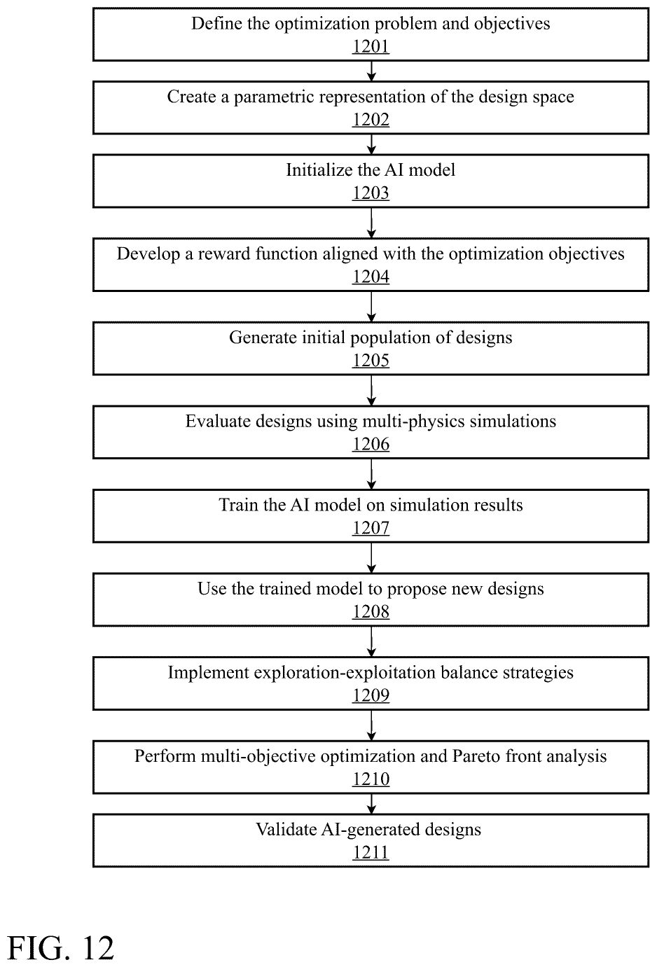

FIG. 12 is a flow diagram illustrating an exemplary method for AI-driven optimization method in the advanced materials design platform, according to an embodiment. AI-driven optimization is a sophisticated process that leverages artificial intelligence to efficiently navigate complex design spaces and discover optimal material configurations. According to the embodiment, the process begins at step 1201 by clearly defining the optimization problem and its objectives, which may comprise multiple, often competing, goals such as maximizing performance while minimizing cost or environmental impact. A parametric representation of the design space is then created at step 1202, encoding material compositions, structural parameters, and processing conditions into a format suitable for AI manipulation. The AI model, typically (but not always) a reinforcement learning agent like those using PPO, is initialized at step 1203 with an architecture suited to the complexity of the design space. A step 1204 a reward function that accurately reflects the optimization objectives, potentially comprising weighted combinations of performance metrics, cost factors, and manufacturability indices.

The process continues with the generation of an initial population of designs at step 1205, for example either through random sampling or informed by prior knowledge. These designs are then evaluated using the platform's multi-physics simulation capabilities at step 1206, providing a rich dataset for initial AI training. The AI model is trained on these simulation results (and other possible training input) at step 1207, learning to associate design parameters with performance outcomes. The trained model is then used to propose new, potentially improved designs at step 1208. Throughout the optimization process, the platform implements strategies to balance exploration of the design space with exploitation of promising regions at step 1209, which may be implemented using techniques like epsilon-greedy selection or upper confidence bound algorithms.

For complex materials design problems, the platform performs multi-objective optimization, generating Pareto fronts to visualize trade-offs between competing objectives at step 1210. The optimization process may be enhanced by integration with uncertainty quantification methods, allowing the AI to account for variabilities in material properties or manufacturing processes. Adaptive sampling techniques may also be implemented to efficiently allocate computational resources, focusing on regions of the design space that are either promising or highly uncertain. In some embodiments, the platform incorporates domain-specific constraints and manufacturing limitations to ensure that AI-generated designs are practically realizable. Sensitivity analysis may be performed on the optimized designs to understand the robustness of the solutions and identify critical parameters. At step 1211, the most promising AI-generated designs are validated through targeted high-fidelity simulations or experimental testing.

An example application of this AI-driven optimization method in the advanced materials design platform may be directed to the development of a novel thermoelectric material for energy harvesting. The optimization objectives might include maximizing the thermoelectric figure of merit (ZT), minimizing material cost, and ensuring mechanical stability. The design space may encompass parameters like chemical composition, dopant concentrations, and nanostructure configurations. The AI model, implemented (in this embodiment) as a deep reinforcement learning agent, may be trained on initial simulations that combine quantum mechanical calculations of electronic properties with continuum-level thermal transport models. The reward function may be a weighted combination of ZT, estimated material cost, and predicted mechanical strength. As the AI explores the design space, it may discover unconventional material compositions or nanostructure geometries that synergistically enhance electron transport while impeding phonon propagation. The multi-objective optimization may generate a Pareto front showing trade-offs between performance, cost, and durability. Uncertainty quantification may account for variabilities in dopant distribution and manufacturing precision. Domain-specific constraints may ensure that proposed compositions are thermodynamically stable and manufacturable. Through this process, the AI-driven optimization may potentially discover a new class of thermoelectric materials with significantly improved efficiency, guiding experimental efforts towards the most promising configurations and accelerating the development of high-performance energy harvesting devices.

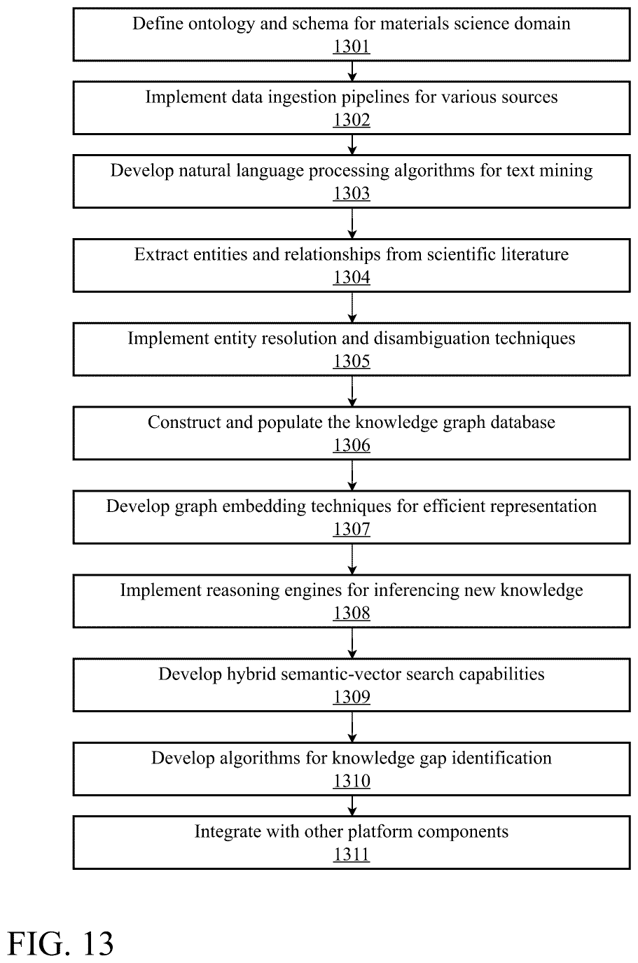

FIG. 13 is a flow diagram illustrating an exemplary method for knowledge graph construction and querying, according to an embodiment. The method of knowledge graph construction and querying in the advanced materials design platform is a comprehensive process that transforms diverse materials science information into a structured, interconnected, and queryable format. According to the embodiment, the process begins at step 1301 with defining a robust ontology and schema that captures the complex relationships in materials science, including concepts from atomic structure to macroscale properties and manufacturing processes. Data ingestion pipelines are implemented at step 1302 to continuously incorporate information from various sources, including, but not limited to, scientific publications, patents, experimental databases, and simulation results. Advanced natural language processing algorithms are developed at step 1303 to mine text data, extracting relevant materials science concepts and relationships. These algorithms may employ techniques such as named entity recognition and relationship extraction to identify materials, properties, synthesis methods, and their interconnections from unstructured text at step 1304.

At step 1305, sophisticated entity resolution and disambiguation techniques are implemented to ensure that extracted information is accurately mapped to unique entities in the knowledge graph, handling challenges like synonyms, abbreviations, and context-dependent meanings common in scientific literature. The knowledge graph is constructed and populated at step 1306 using a scalable graph database system, capable of handling the complex, highly connected nature of materials science data. To enhance querying efficiency and enable advanced analytics, graph embedding techniques are developed at step 1307, projecting the graph structure into a high-dimensional vector space while preserving semantic relationships.

The platform implements reasoning engines at step 1308 that may infer new knowledge from existing relationships, leveraging techniques like transitive reasoning and rule-based inference. At step 1309 the platform develops hybrid semantic-vector search capabilities, combining traditional semantic querying with vector similarity searches to enable flexible and efficient knowledge retrieval. User-friendly query interfaces may be created, supporting both structured query languages like SPARQL and GraphQL, as well as natural language queries, or graph queries (e.g., in Gremlin or Cypher). The platform may also provide advanced visualization tools for interactive exploration of the knowledge graph, allowing researchers to visually navigate complex relationships and discover non-obvious connections or to engage in deductive reasoning, or inference enabled by the structured corpora of data.

To drive continuous improvement, algorithms are developed to identify knowledge gaps in the graph at step 1310, highlighting areas where additional research or data collection is needed. The system implements mechanisms for continuous learning and graph updates, automatically incorporating new findings and adjusting relationships based on the latest research. Importantly, the knowledge graph is tightly integrated with other components of the platform at step 1311, such as AI optimization algorithms and simulation modules, enabling knowledge-driven materials design. Additionally, robust security and access control measures may be implemented to protect proprietary information while facilitating collaboration.

As an example, consider the development of advanced battery materials. The knowledge graph may capture information about various cathode, anode, and electrolyte materials, their atomic and crystal structures, electrochemical properties, synthesis methods, and performance characteristics. As new research on novel materials like solid-state electrolytes is published, the NLP algorithms may automatically extract relevant information and update the graph. Researchers may query the graph to find potential correlations between specific dopants and ionic conductivity, or to identify unexplored combinations of cathode materials and electrolytes. The reasoning engine may infer potential stability issues for a proposed material combination based on known chemical compatibilities. The hybrid semantic-vector search may help identify materials with similar performance characteristics to a promising but expensive compound, potentially leading to more cost-effective alternatives. By integrating this rich knowledge base with AI optimization algorithms, the platform may guide the design of new battery materials, suggesting compositions that balance multiple objectives like energy density, charge rate, and cycle life. This knowledge-driven approach may significantly accelerate the discovery and optimization of next-generation battery materials, leveraging the collective knowledge of the field to inform and guide innovative designs.

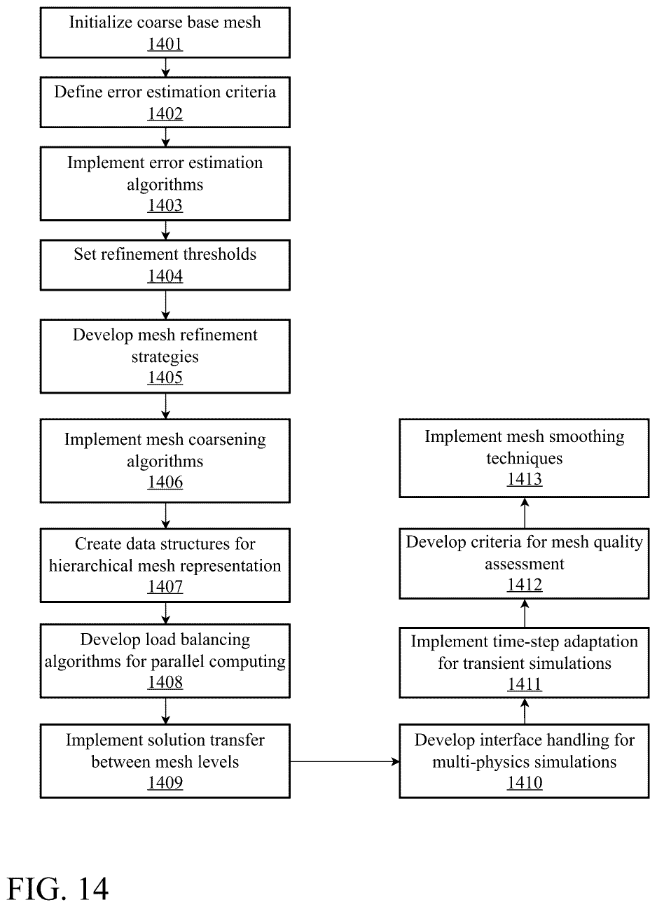

FIG. 14 is a flow diagram illustrating an exemplary method for performing adaptive mesh refinement, according to an embodiment. The method of adaptive mesh refinement in the advanced materials design platform is a sophisticated process that dynamically adjusts the simulation mesh to optimize computational resources while maintaining high accuracy in critical regions. According to the embodiment, the process begins at step 1401 with initializing a relatively coarse base mesh that covers the entire computational domain. Error estimation criteria are defined at step 1402, which may comprise solution gradients, curvature of field variables, or physics-based indicators specific to the problem at hand. Advanced error estimation algorithms are implemented at step 1403 to quantify the local error in the solution based on these criteria. Refinement thresholds are set at step 1404 to determine when and where mesh adaptation should occur.

At step 1405, the platform develops multiple mesh refinement strategies, including, but not limited to, h-refinement (subdividing elements), p-refinement (increasing polynomial order), and r-refinement (relocating mesh nodes), selecting the most appropriate method based on, for example, the problem characteristics and computational efficiency. Complementary to refinement, mesh coarsening algorithms are implemented at step 1406 to reduce resolution in areas where high accuracy is no longer needed, optimizing computational resources.

At step 1407, efficient data structures for hierarchical mesh representation are created, enabling seamless transitions between different levels of mesh refinement. For large-scale simulations, load balancing algorithms are developed at step 1408 to ensure efficient distribution of the adaptive mesh across parallel computing resources. The platform implements robust solution transfer methods at step 1409 to accurately interpolate solution data between different mesh levels during refinement or coarsening.

Special attention is given to interface handling in multi-physics simulations at step 1410, ensuring consistent mesh refinement across different physical domains. Advanced visualization techniques may be created to effectively display the adaptive mesh and solution results. For transient simulations, the platform implements time-step adaptation at step 1411 in conjunction with spatial mesh refinement to capture temporal variations efficiently.

The method includes the development of criteria for continuous mesh quality assessment at step 1412 to ensure that refinement and coarsening operations maintain element shapes suitable for accurate numerical calculations. Mesh smoothing techniques may be implemented at step 1413 to improve element quality when needed. Additionally, the platform may create and/or implement error control and convergence assessment methods to evaluate the overall effectiveness of the adaptive refinement process and determine when sufficient accuracy has been achieved.

According to another aspect of an embodiment, the platform employs multiple mesh quality metrics (including element aspect ratio, skewness, Jacobian ratio, and orthogonality) to guide automated corrective refinement near complex features. When threshold criteria are exceeded, indicating compromised accuracy or potential solver instability, the system triggers quality-based re-meshing or local improvement steps. This process ensures that highly curved surfaces—such as those encountered with bodies of constant width—do not degrade solution fidelity. The system implements various mesh improvement techniques, including local and global smoothing, edge swapping in 2D, face flipping in 3D, and selective element refinement or coarsening around sharp geometric or field gradients. Through integration with HPC-based parallel computations, these mesh operations may be executed rapidly, preserving numerical stability while enhancing the reliability of multi-physics analyses.

An example application of this adaptive mesh refinement process in the advanced materials design platform may be directed to the simulation of a novel nanostructured thermoelectric material. The simulation may start with a coarse mesh representing the bulk material structure. As the simulation progresses, the error estimation algorithms may identify regions requiring higher resolution, such as interfaces between different materials or areas with high temperature gradients. The platform may apply h-refinement to subdivide elements in these critical regions, providing a more detailed representation of the nanostructure and its effects on electron and phonon transport.

In areas where the solution exhibits high polynomial order behavior, such as complex electric field distributions, p-refinement may be applied to increase the order of the shape functions used in the finite element analysis. The hierarchical mesh representation may efficiently manage the transition between different refinement levels, while load balancing algorithms may distribute the computational load across available resources.

For the multi-physics aspects of the thermoelectric simulation, the interface handling algorithms may ensure consistent mesh refinement between the electrical and thermal domains. As the simulation evolves, some initially refined regions may become less critical, prompting the mesh coarsening algorithms to reduce resolution and save computational resources.

The adaptive process may continue iteratively, with error control and convergence assessment methods evaluating the accuracy of key parameters like the Seebeck coefficient and thermal conductivity. This adaptive approach may allow the platform to capture the complex interplay between nanostructure geometry and thermoelectric performance with high fidelity, while maintaining computational efficiency. The resulting optimized mesh may provide detailed insights into the material's behavior, guiding the design of more efficient thermoelectric devices.

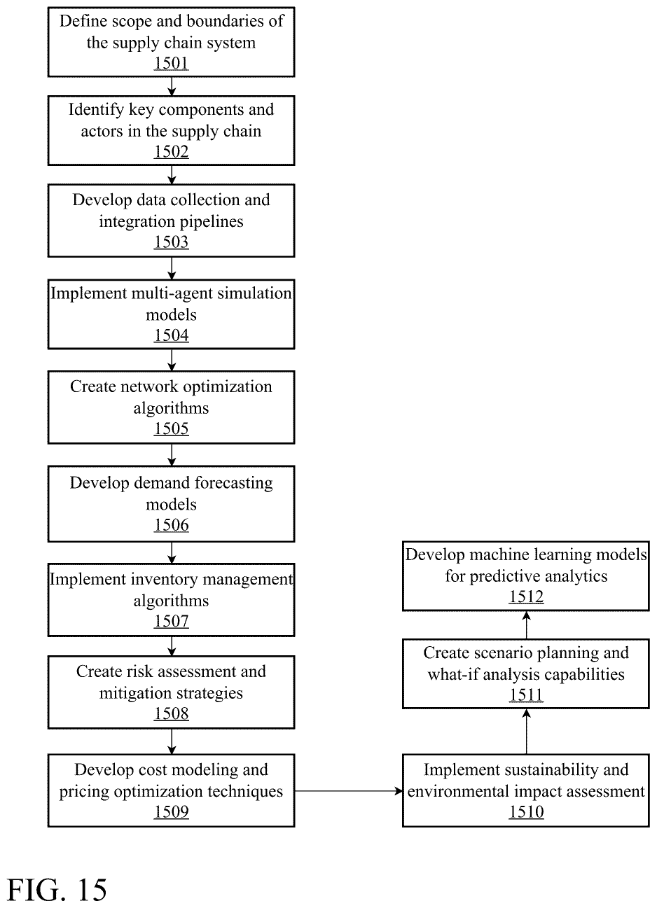

FIG. 15 is a flow diagram illustrating an exemplary method for supply chain and economic modeling, according to an embodiment. The method of supply chain and economic modeling in the advanced materials design platform is a comprehensive approach that combines advanced simulation techniques with data-driven analytics to provide a holistic view of material production and distribution economics. According to the embodiment, the process begins at step 1501 by defining the scope and boundaries of the supply chain system, encompassing raw material sourcing, manufacturing processes, distribution networks, and end-use applications. Key components and actors in the supply chain are identified at step 1502, including suppliers, manufacturers, distributors, and consumers.

Robust data collection and integration pipelines are developed at step 1503 to gather real-time and historical data from various sources, including, but not limited to, market databases, logistics systems, and production facilities. The platform implements sophisticated multi-agent simulation models at step 1504 (e.g., using frameworks like AnyLogic or Mesa), allowing for the modeling of complex interactions between different supply chain actors. These models employ agent-based modeling techniques to capture emergent behaviors and system dynamics.

Network optimization algorithms are created at step 1505 using techniques such as linear programming and genetic algorithms to optimize supply chain configurations, minimizing costs and delivery times. Advanced demand forecasting models are developed at step 1506 utilizing time series analysis methods like ARIMA (Autoregressive Integrated Moving Average) and machine learning techniques such as LSTM networks to predict future material demands accurately.

At step 1507, the platform implements inventory management algorithms based on, for example, stochastic optimization techniques to balance stock levels, production rates, and demand variability. Sophisticated risk assessment and mitigation strategies are developed at step 1508 using Monte Carlo simulations and Bayesian networks (among others) to model uncertainties and potential disruptions in the supply chain.

At step 1509, cost modeling and pricing optimization techniques are implemented using methods like activity-based costing and dynamic pricing algorithms to ensure economic viability. The platform incorporates sustainability and environmental impact assessment tools at step 1510 based on, for example, life cycle assessment methodologies to evaluate the ecological footprint of materials and processes.

Scenario planning and what-if analysis capabilities are created at step 1511 using techniques like discrete event simulation to explore various potential future scenarios and their impacts. Machine learning models for predictive analytics are developed at step 1512, employing techniques such as random forests and gradient boosting machines to identify patterns and predict future trends in supply chain performance.

According to some embodiments, the platform implements real-time data processing and update mechanisms using stream processing technologies like Apache Kafka to continuously refine and update the supply chain models. Advanced visualization and reporting tools may be created to provide intuitive, interactive dashboards for decision-makers.

Furthermore, the supply chain and economic modeling processes are tightly integrated with the materials design and optimization processes, ensuring that material innovations are evaluated not just for their technical performance but also for their economic viability and supply chain feasibility.

As an example, consider the development and production planning of a novel battery material for electric vehicles. The platform may model the entire supply chain, from raw material sourcing (e.g., lithium, cobalt, nickel) to battery production and distribution to automotive manufacturers. The multi-agent simulation may model interactions between mining companies, material processors, battery manufacturers, and car companies, capturing complex dynamics like price negotiations and supply-demand fluctuations.

Network optimization algorithms may determine the most efficient configuration of production facilities and distribution centers globally. Demand forecasting models may predict future needs for the battery material based on projected electric vehicle adoption rates and regulatory changes. Inventory management algorithms may optimize production schedules and stock levels across the supply chain to meet demand while minimizing costs.

Risk assessment tools may evaluate potential disruptions, such as geopolitical events affecting cobalt supply from specific regions, and suggest mitigation strategies like diversifying suppliers or developing alternative materials. Cost modeling may provide insights into the economic competitiveness of the new battery material compared to existing technologies, while sustainability assessments may quantify its environmental impact and carbon footprint.

The platform may enable scenario planning to explore the effects of various factors, such as breakthroughs in recycling technology or shifts in government policies on electric vehicle incentives. Machine learning models may analyze historical data and current trends to predict future raw material prices and supply chain bottlenecks.

By integrating this comprehensive supply chain and economic analysis with the material design process, the platform may guide researchers towards battery material innovations that are not only technically superior but also economically viable and resilient to supply chain challenges. This approach may significantly accelerate the development and market introduction of advanced battery technologies, balancing performance, cost, and sustainability considerations.

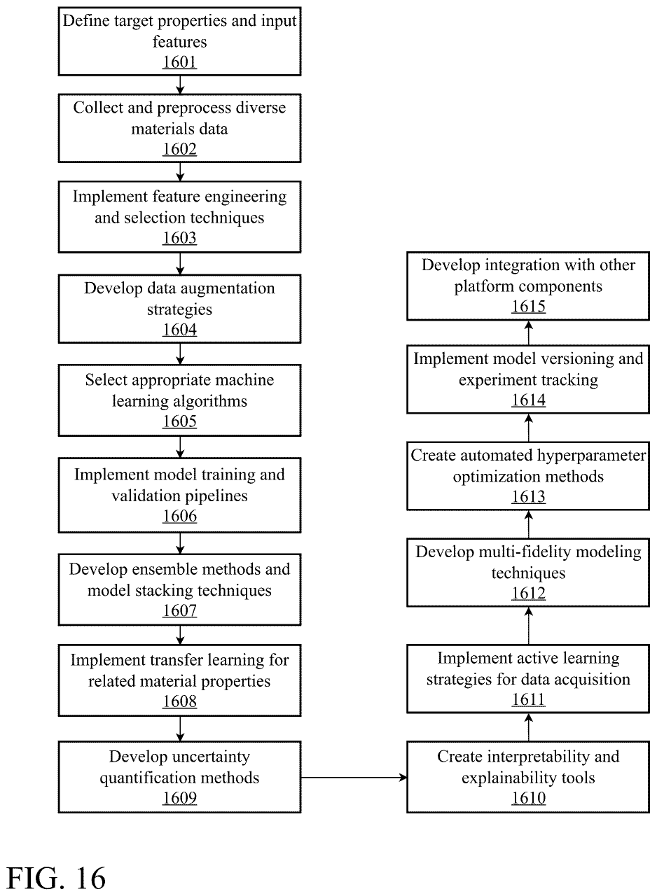

FIG. 16 is a flow diagram illustrating an exemplary method for machine and/or deep learning-based property prediction, according to an embodiment. The method of property prediction in the advanced materials design platform is a process that leverages state-of-the-art algorithms to accurately predict material properties from structural and compositional data. According to the embodiment, the process begins at step 1601 by clearly defining the target properties to be predicted and identifying relevant input features, which may comprise atomic structure, chemical composition, processing conditions, and other relevant parameters. A comprehensive dataset is collected and preprocessed at step 1602, incorporating data from experimental measurements, computational simulations, and scientific literature. This data undergoes rigorous cleaning, normalization, and standardization to ensure consistency and reliability.

At step 1603, advanced feature engineering and selection techniques are implemented, including, but not limited to, methods such as principal component analysis, autoencoder networks, and genetic algorithms to identify the most informative features for property prediction. To address data scarcity issues common in materials science, data augmentation strategies may be developed at step 1604, such as synthetic data generation using generative adversarial networks and/or physics-informed neural networks.

At step 1605 the platform implements a diverse array of machine learning algorithms, including, but not limited to, deep neural networks, gradient boosting machines, support vector machines, and Gaussian process regression. Each algorithm may be selected based on its suitability for specific types of material property predictions. Robust model training and validation pipelines are developed at step 1606, incorporating techniques like k-fold cross-validation and stratified sampling to ensure model generalizability.

To enhance prediction accuracy, the platform may implement ensemble methods and model stacking techniques at step 1607, combining predictions from multiple models to leverage their individual strengths. Transfer learning methods are developed 1608 to efficiently apply knowledge gained from predicting one property to related properties, significantly reducing the data requirements for new predictions.

At step 1609, the platform implements uncertainty quantification methods, such as Bayesian neural networks or dropout-based techniques, to provide confidence intervals for property predictions. The platform also creates interpretability and explainability tools at step 1610, including SHAP (SHapley Additive exPlanations) values and integrated gradients, to help researchers understand the factors driving the predictions.

To continuously improve prediction accuracy, active learning strategies are implemented at step 1611, intelligently selecting new data points for experimental measurement or high-fidelity simulation. The platform develops multi-fidelity modeling techniques at step 1612 to efficiently combine data from different sources of varying accuracy and cost.

Automated hyperparameter optimization methods, such as Bayesian optimization and genetic algorithms, are created at step 1613 to fine-tune model performance. The platform implements comprehensive model versioning and experiment tracking at step 1614 to ensure reproducibility and facilitate collaborative research. At step 1615, the machine learning models are integrated with other platform components, such as multi-scale simulations and optimization algorithms, to create a seamless materials design workflow.

As an example, consider the prediction of thermoelectric properties for novel materials. The target properties may include the Seebeck coefficient, electrical conductivity, and thermal conductivity, which together determine the thermoelectric figure of merit (ZT). Input features may comprise atomic structure descriptors, chemical composition, and processing parameters.

The platform may collect data from experimental measurements of known thermoelectric materials, high-throughput DFT calculations, and published literature. Feature engineering may comprise creating physics-informed descriptors that capture electronic structure characteristics relevant to thermoelectric performance. A combination of convolutional neural networks (for structural data) and gradient boosting machines (for composition and processing data) may be employed to predict the target properties.

Ensemble methods may combine these predictions with those from Gaussian process regression models, known for their effectiveness in materials science applications. Transfer learning may be applied to leverage knowledge gained from predicting electrical conductivity to improve predictions of the Seebeck coefficient, exploiting the physical relationships between these properties.

Uncertainty quantification may provide confidence intervals for the predicted ZT values, important for guiding experimental validation efforts. Interpretability tools may help researchers understand which material characteristics most strongly influence thermoelectric performance, potentially uncovering new design principles.

Active learning strategies may identify promising regions of the material design space for further exploration, suggesting new compositions or structures for experimental synthesis or high-fidelity simulation. Multi-fidelity modeling may efficiently combine quick, approximate DFT calculations with more accurate but expensive many-body perturbation theory results to enhance prediction accuracy.

By integrating these machine learning models with the platform's optimization algorithms, researchers may rapidly explore vast design spaces of potential thermoelectric materials, identifying promising maydidates that balance high ZT with other considerations like cost and manufacturability. This approach may significantly accelerate the discovery and development of next-generation thermoelectric materials for applications in waste heat recovery and solid-state cooling.

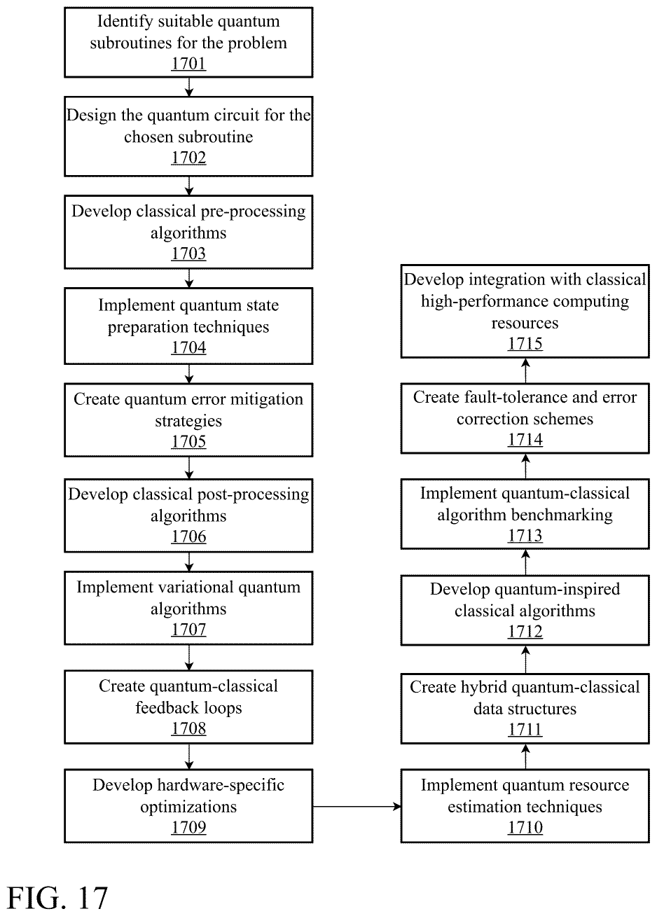

FIG. 17 is a flow diagram illustrating an exemplary method for implementing one or more quantum-classical hybrid algorithms, according to an embodiment. The method(s) for implementing one or more quantum-classical hybrid algorithms in the advanced materials design platform represents a sophisticated approach that leverages the strengths of both quantum and classical computing paradigms to tackle complex materials science problems. According to the embodiment, the process begins at step 1701 by identifying suitable quantum subroutines (Step 1) for specific computational bottlenecks in materials modeling, such as electronic structure calculations or molecular dynamics simulations. Quantum circuits are designed at step 1702 for these subroutines, optimized for the specific quantum hardware being used (e.g., superconducting qubits, trapped ions, or photonic systems).

At step 1703, classical pre-processing algorithms are developed to prepare input data and parameters for the quantum subroutines, including, but not limited to, techniques like problem decomposition and data encoding. Advanced quantum state preparation techniques are implemented at step 1704, such as quantum approximate optimization algorithm (QAOA) analyses or hardware-efficient trial states, to efficiently encode problem information into quantum states.

At step 1705, quantum error mitigation strategies are created, comprising zero-noise extrapolation, probabilistic error cancellation, and dynamical decoupling, to mitigate the effects of noise and decoherence in near-term quantum devices. Complementary classical post-processing algorithms are developed at step 1706 to interpret and refine the results obtained from quantum measurements.

The platform implements variational quantum algorithms at step 1707, such as the variational quantum Eigensolver for electronic structure problems or quantum machine learning models for property prediction. These algorithms are designed with quantum-classical feedback loops at step 1708, allowing for iterative optimization of quantum circuits based on classical analysis of measurement outcomes.

At step 1709, hardware-specific optimizations are developed to maximize the performance of quantum subroutines on particular quantum computing architectures, including, for example, pulse-level control and qubit connectivity optimizations. Quantum resource estimation techniques are implemented at step 1710 to predict the qubit and gate requirements for scaling algorithms to larger problem sizes.

The method further comprises the creation of hybrid quantum-classical data structures at step 1711 that efficiently represent and manipulate information across both computing paradigms. Quantum-inspired classical algorithms are developed at step 1712, leveraging insights from quantum computation to enhance classical simulation techniques.

Rigorous quantum-classical algorithm benchmarking procedures are implemented at step 1713 to assess the performance and accuracy of hybrid approaches compared to purely classical methods. As quantum hardware advances, fault-tolerance and error correction schemes are developed and integrated at step 1714 to enable longer and more complex quantum computations.

At step 1715, the platform develops seamless integration with classical high-performance computing resources, allowing for efficient distribution of workload between quantum and classical processors in large-scale materials simulations.

As an example, consider the simulation of complex catalytic materials for hydrogen production. The platform may employ a hybrid approach for electronic structure calculations of catalyst surfaces. A variational quantum Eigensolver (VQE) algorithm may be used to compute the ground state energy of active sites on the catalyst surface, potentially capturing strong electron correlation effects more accurately than classical methods.

The classical pre-processing may involve decomposing the catalyst surface into manageable subsystems and encoding the relevant molecular orbitals into qubit states. Quantum state preparation may utilize hardware-efficient analyses optimized for the specific quantum processor being used. Error mitigation techniques like zero-noise extrapolation may be applied to improve the accuracy of quantum measurements.

A quantum-classical feedback loop may iteratively refine the VQE ansatz parameters, with classical optimization algorithms like gradient descent guiding the search for the optimal ground state. Quantum-inspired tensor network methods may be used to efficiently represent the electronic wavefunction in classical memory, informed by the entanglement structure observed in the quantum computations.

The hybrid approach may be benchmarked against state-of-the-art classical density functional theory (DFT) calculations, quantifying any quantum advantage in accuracy or computational efficiency. As the simulation scales to larger catalyst systems, quantum resource estimation may guide the allocation of computational resources between quantum and classical processors.

By integrating this hybrid quantum-classical approach with other components of the platform, such as machine learning models for property prediction and optimization algorithms for catalyst design, the advanced materials design platform may accelerate the discovery of highly efficient catalysts for clean hydrogen production. This approach may potentially uncover novel catalyst designs that exploit quantum effects for enhanced performance, pushing the boundaries of classical simulation capabilities in materials science.

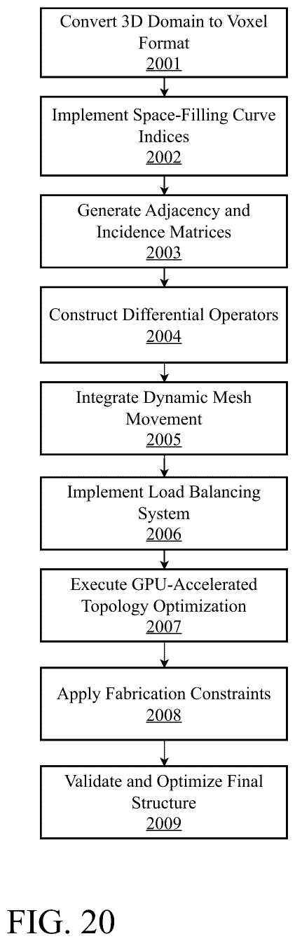

FIG. 20 is a flow diagram illustrating an exemplary method for implementing topological voxelization and graph-based differential operators, according to an embodiment. In a step 2001, the system may convert three-dimensional domain representations into a consistent voxel format through a sophisticated transformation process. This may be accomplished by applying a reversible function f: [symbol] ³→ [symbol] ³, which may map continuous space to discrete voxel coordinates. The conversion process may carefully preserve geometric features while establishing the foundational discrete representation necessary for subsequent analysis steps. This initial transformation may be refined via sparse raster structures, which may help mitigate memory overhead and ensure efficient data storage.

Following the initial conversion, step 2002 may implement space-filling curve indices, particularly Morton codes or similar approaches, to establish an efficient ordering and access pattern for the voxel grid. This indexing scheme may drastically reduce the complexity of point and element lookups while maintaining geometric fidelity and topological consistency. The space-filling curves may create a linearized representation of the three-dimensional structure that preserves spatial locality, enabling efficient parallel processing and data access patterns. The next step 2003 may focus on generating the mathematical framework through the construction of adjacency matrix A and incidence matrices M. These matrices may capture the topological relationships between voxel elements and may serve as the foundation for defining discrete differential operators. The careful construction of these matrices may ensure proper connectivity representation and may enable accurate numerical computations in subsequent steps. The following step 2004 may implement the construction of differential operators, including gradient G, divergence D, and Laplace-Beltrami L operators. These operators may be defined using the previously generated matrices and may be specifically tailored for use within finite-element or finite-volume frameworks. This step may be crucial for enabling accurate solution of partial differential equations and evaluation of topological measures across the voxelized geometry. The system then may integrate dynamic mesh movement capabilities 2005 with space-time stabilization methods. This integration may allow for selective deployment of voxel grids in regions that benefit from uniform sampling while preserving advanced unstructured meshes elsewhere. The hybrid approach may combine the computational efficiency of graph-based PDE solvers with the geometric flexibility of novel shape representations. The next step may implement a sophisticated load balancing system 2006 using MPI-based distributed processing. This may continuously monitor computational demands and may adaptively allocate resources across the processing infrastructure. The system may particularly focus on regions of elevated computational intensity, ensuring efficient distribution of workload during complex analyses. The next step 2007 may execute GPU-accelerated topology optimization processes. This step may leverage the adjacency and incidence matrices to perform compliance minimization under various constraints, including minimum thickness and volumetric usage requirements. The optimization may employ reinforcement learning or gradient-based sensitivity analysis to update voxel occupancy, reducing material usage in low-stress regions while preserving critical load-bearing paths.

Next, the system may apply fabrication constraints 2008 directly within the voxel domain. This may include implementing explicit printability rules and ensuring that optimized structures remain physically realizable. The system may support intelligent masking or cloning of voxel neighborhoods to enforce shape constraints, enabling design features to comply with user-defined symmetry planes or repetition frequencies. The final step 2009 may focus on validation and optimization of the final structure. This step may ensure that the resulting design meets both numerical stability requirements for PDE-driven simulations and practical manufacturability constraints. The process may include final refinements to achieve optimal performance while maintaining fabrication feasibility. Throughout this methodological sequence, the system may maintain approximately linear scaling in the number of non-empty voxels rather than total volumetric dimension, enabling the processing of models comprising tens of millions of voxels at near-interactive rates. The carefully orchestrated workflow may enable efficient exploration of design spaces while maintaining both theoretical correctness and practical applicability, particularly for advanced industrial applications requiring high precision and computational efficiency.

### Exemplary Computing Environment

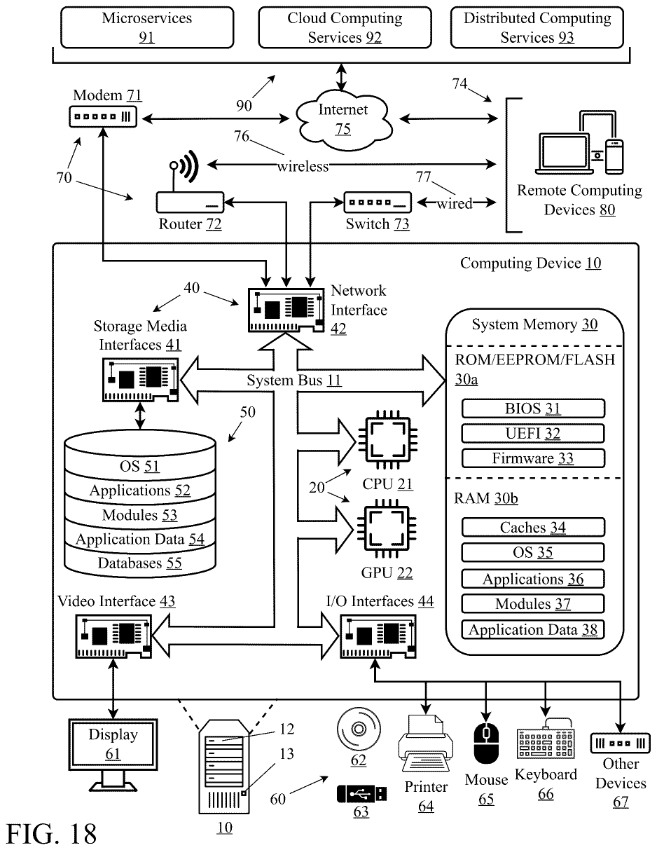

FIG. 18 illustrates an exemplary computing environment on which an embodiment described herein may be implemented, in full or in part. This exemplary computing environment describes computer-related components and processes supporting enabling disclosure of computer-implemented embodiments. Inclusion in this exemplary computing environment of well-known processes and computer components, if any, is not a suggestion or admission that any embodiment is no more than an aggregation of such processes or components. Rather, implementation of an embodiment using processes and components described in this exemplary computing environment will involve programming or configuration of such processes and components resulting in a machine specially programmed or configured for such implementation. The exemplary computing environment described herein is only one example of such an environment and other configurations of the components and processes are possible, including other relationships between and among components, and/or absence of some processes or components described. Further, the exemplary computing environment described herein is not intended to suggest any limitation as to the scope of use or functionality of any embodiment implemented, in whole or in part, on components or processes described herein.

The exemplary computing environment described herein comprises a computing device 10 (further comprising a system bus 11, one or more processors 20, a system memory 30, one or more interfaces 40, one or more non-volatile data storage devices 50), external peripherals and accessories 60, external communication devices 70, remote computing devices 80, and cloud-based services 90.

System bus 11 couples the various system components, coordinating operation of and data transmission between those various system components. System bus 11 represents one or more of any type or combination of types of wired or wireless bus structures including, but not limited to, memory busses or memory controllers, point-to-point connections, switching fabrics, peripheral busses, accelerated graphics ports, and local busses using any of a variety of bus architectures. By way of example, such architectures include, but are not limited to, Industry Standard Architecture (ISA) busses, Micro Channel Architecture (MCA) busses, Enhanced ISA (EISA) busses, Video Electronics Standards Association (VESA) local busses, a Peripheral Component Interconnects (PCI) busses also known as a Mezzanine busses, or any selection of, or combination of, such busses. Depending on the specific physical implementation, one or more of the processors 20, system memory 30 and other components of the computing device 10 can be physically co-located or integrated into a single physical component, such as on a single chip. In such a case, some or all of system bus 11 can be electrical pathways within a single chip structure.

Computing device may further comprise externally-accessible data input and storage devices 12 such as compact disc read-only memory (CD-ROM) drives, digital versatile discs (DVD), or other optical disc storage for reading and/or writing optical discs 62; magnetic cassettes, magnetic tape, magnetic disk storage, or other magnetic storage devices; or any other medium which can be used to store the desired content and which can be accessed by the computing device 10. Computing device may further comprise externally-accessible data ports or connections 12 such as serial ports, parallel ports, universal serial bus (USB) ports, and infrared ports and/or transmitter/receivers. Computing device may further comprise hardware for wireless communication with external devices such as IEEE 1394 (“Firewire”) interfaces, IEEE 802.11 wireless interfaces, BLUETOOTH® wireless interfaces, and so forth. Such ports and interfaces may be used to connect any number of external peripherals and accessories 60 such as visual displays, monitors, and touch-sensitive screens 61, USB solid state memory data storage drives (commonly known as “flash drives” or “thumb drives”) 63, printers 64, pointers and manipulators such as mice 65, keyboards 66, and other devices 67 such as joysticks and gaming pads, touchpads, additional displays and monitors, and external hard drives (whether solid state or disc-based), microphones, speakers, cameras, and optical scanners.

Processors 20 are logic circuitry capable of receiving programming instructions and processing (or executing) those instructions to perform computer operations such as retrieving data, storing data, and performing mathematical calculations. Processors 20 are not limited by the materials from which they are formed or the processing mechanisms employed therein, but are typically comprised of semiconductor materials into which many transistors are formed together into logic gates on a chip (i.e., an integrated circuit or IC). The term processor includes any device capable of receiving and processing instructions including, but not limited to, processors operating on the basis of quantum computing, optical computing, mechanical computing (e.g., using nanotechnology entities to transfer data), and so forth. Depending on configuration, computing device 10 may comprise more than one processor. For example, computing device 10 may comprise one or more central processing units (CPUs) 21, each of which itself has multiple processors or multiple processing cores, each capable of independently or semi-independently processing programming instructions. Further, computing device 10 may comprise one or more specialized processors such as a graphics processing unit (GPU) 22 configured to accelerate processing of computer graphics and images via a large array of specialized processing cores arranged in parallel. The term processor may further include: neural processing units (NPUs) or neural computing units optimized for machine learning and artificial intelligence workloads using specialized architectures and data paths; tensor processing units (TPUs) designed to efficiently perform matrix multiplication and convolution operations used heavily in neural networks and deep learning applications; application-specific integrated circuits (ASICs) implementing custom logic for domain-specific tasks; application-specific instruction set processors (ASIPs) with instruction sets tailored for particular applications; field-programmable gate arrays (FPGAs) providing reconfigurable logic fabric that can be customized for specific processing tasks; processors operating on emerging computing paradigms such as quantum computing, optical computing, mechanical computing (e.g., using nanotechnology entities to transfer data), and so forth. Depending on configuration, computing device 10 may comprise one or more of any of the above types of processors in order to efficiently handle a variety of general purpose and specialized computing tasks. The specific processor configuration may be selected based on performance, power, cost, or other design constraints relevant to the intended application of computing device 10.

System memory 30 is processor-accessible data storage in the form of volatile and/or nonvolatile memory. System memory 30 may be either or both of two types: non-volatile memory and volatile memory. Non-volatile memory 30a is not erased when power to the memory is removed, and includes memory types such as read only memory (ROM), electronically-erasable programmable memory (EEPROM), and rewritable solid state memory (commonly known as “flash memory”). Non-volatile memory 30a is typically used for long-term storage of a basic input/output system (BIOS) 31, containing the basic instructions, typically loaded during computer startup, for transfer of information between components within computing device, or a unified extensible firmware interface (UEFI), which is a modern replacement for BIOS that supports larger hard drives, faster boot times, more security features, and provides native support for graphics and mouse cursors. Non-volatile memory 30a may also be used to store firmware comprising a complete operating system 35 and applications 36 for operating computer-controlled devices. The firmware approach is often used for purpose-specific computer-controlled devices such as appliances and Internet-of-Things (IoT) devices where processing power and data storage space is limited. Volatile memory 30b is erased when power to the memory is removed and is typically used for short-term storage of data for processing. Volatile memory 30b includes memory types such as random-access memory (RAM), and is normally the primary operating memory into which the operating system 35, applications 36, program modules 37, and application data 38 are loaded for execution by processors 20. Volatile memory 30b is generally faster than non-volatile memory 30a due to its electrical characteristics and is directly accessible to processors 20 for processing of instructions and data storage and retrieval. Volatile memory 30b may comprise one or more smaller cache memories which operate at a higher clock speed and are typically placed on the same IC as the processors to improve performance.

Interfaces 40 may include, but are not limited to, storage media interfaces 41, network interfaces 42, display interfaces 43, and input/output interfaces 44. Storage media interface 41 provides the necessary hardware interface for loading data from non-volatile data storage devices 50 into system memory 30 and storage data from system memory 30 to non-volatile data storage device 50. Network interface 42 provides the necessary hardware interface for computing device 10 to communicate with remote computing devices 80 and cloud-based services 90 via one or more external communication devices 70. Display interface 43 allows for connection of displays 61, monitors, touchscreens, and other visual input/output devices. Display interface 43 may include a graphics card for processing graphics-intensive calculations and for handling demanding display requirements. Typically, a graphics card includes a graphics processing unit (GPU) and video RAM (VRAM) to accelerate display of graphics. One or more input/output (I/O) interfaces 44 provide the necessary support for communications between computing device 10 and any external peripherals and accessories 60. For wireless communications, the necessary radio-frequency hardware and firmware may be connected to I/O interface 44 or may be integrated into I/O interface 44.

Non-volatile data storage devices 50 are typically used for long-term storage of data. Data on non-volatile data storage devices 50 is not erased when power to the non-volatile data storage devices 50 is removed. Non-volatile data storage devices 50 may be implemented using any technology for non-volatile storage of content including, but not limited to, CD-ROM drives, digital versatile discs (DVD), or other optical disc storage; magnetic cassettes, magnetic tape, magnetic disc storage, or other magnetic storage devices; solid state memory technologies such as EEPROM or flash memory; or other memory technology or any other medium which can be used to store data without requiring power to retain the data after it is written. Non-volatile data storage devices 50 may be non-removable from computing device 10 as in the case of internal hard drives, removable from computing device 10 as in the case of external USB hard drives, or a combination thereof, but computing device will typically comprise one or more internal, non-removable hard drives using either magnetic disc or solid state memory technology. Non-volatile data storage devices 50 may store any type of data including, but not limited to, an operating system 51 for providing low-level and mid-level functionality of computing device 10, applications 52 for providing high-level functionality of computing device 10, program modules 53 such as containerized programs or applications, or other modular content or modular programming, application data 54, and databases 55 such as relational databases, non-relational databases, object oriented databases, BOSQL databases, and graph databases.

Applications (also known as computer software or software applications) are sets of programming instructions designed to perform specific tasks or provide specific functionality on a computer or other computing devices. Applications are typically written in high-level programming languages such as C++, Java, and Python, which are then either interpreted at runtime or compiled into low-level, binary, processor-executable instructions operable on processors 20. Applications may be containerized so that they can be run on any computer hardware running any known operating system. Containerization of computer software is a method of packaging and deploying applications along with their operating system dependencies into self-contained, isolated units known as containers. Containers provide a lightweight and consistent runtime environment that allows applications to run reliably across different computing environments, such as development, testing, and production systems.

The memories and non-volatile data storage devices described herein do not include communication media. Communication media are means of transmission of information such as modulated electromagnetic waves or modulated data signals configured to transmit, not store, information. By way of example, and not limitation, communication media includes wired communications such as sound signals transmitted to a speaker via a speaker wire, and wireless communications such as acoustic waves, radio frequency (RF) transmissions, infrared emissions, and other wireless media.

External communication devices 70 are devices that facilitate communications between computing device and either remote computing devices 80, or cloud-based services 90, or both. External communication devices 70 include, but are not limited to, data modems 71 which facilitate data transmission between computing device and the Internet 75 via a common carrier such as a telephone company or internet service provider (ISP), routers 72 which facilitate data transmission between computing device and other devices, and switches 73 which provide direct data communications between devices on a network. Here, modem 71 is shown connecting computing device 10 to both remote computing devices 80 and cloud-based services 90 via the Internet 75. While modem 71, router 72, and switch 73 are shown here as being connected to network interface 42, many different network configurations using external communication devices 70 are possible. Using external communication devices 70, networks may be configured as local area networks (LANs) for a single location, building, or campus, wide area networks (WANs) comprising data networks that extend over a larger geographical area, and virtual private networks (VPNs) which can be of any size but connect computers via encrypted communications over public networks such as the Internet 75. As just one exemplary network configuration, network interface 42 may be connected to switch 73 which is connected to router 72 which is connected to modem 71 which provides access for computing device 10 to the Internet 75. Further, any combination of wired 77 or wireless 76 communications between and among computing device 10, external communication devices 70, remote computing devices 80, and cloud-based services 90 may be used. Remote computing devices 80, for example, may communicate with computing device through a variety of communication channels 74 such as through switch 73 via a wired 77 connection, through router 72 via a wireless connection 76, or through modem 71 via the Internet 75. Furthermore, while not shown here, other hardware that is specifically designed for servers may be employed. For example, secure socket layer (SSL) acceleration cards can be used to offload SSL encryption computations, and transmission control protocol/internet protocol (TCP/IP) offload hardware and/or packet classifiers on network interfaces 42 may be installed and used at server devices.

In a networked environment, certain components of computing device 10 may be fully or partially implemented on remote computing devices 80 or cloud-based services 90. Data stored in non-volatile data storage device 50 may be received from, shared with, duplicated on, or offloaded to a non-volatile data storage device on one or more remote computing devices 80 or in a cloud computing service 92. Processing by processors 20 may be received from, shared with, duplicated on, or offloaded to processors of one or more remote computing devices 80 or in a distributed computing service 93. By way of example, data may reside on a cloud computing service 92, but may be usable or otherwise accessible for use by computing device 10. Also, certain processing subtasks may be sent to a microservice 91 for processing with the result being transmitted to computing device 10 for incorporation into a larger processing task. Also, while components and processes of the exemplary computing environment are illustrated herein as discrete units (e.g., OS 51 being stored on non-volatile data storage device 51 and loaded into system memory 35 for use) such processes and components may reside or be processed at various times in different components of computing device 10, remote computing devices 80, and/or cloud-based services 90.

In an implementation, the disclosed systems and methods may utilize, at least in part, containerization techniques to execute one or more processes and/or steps disclosed herein. Containerization is a lightweight and efficient virtualization technique that allows you to package and run applications and their dependencies in isolated environments called containers. One of the most popular containerization platforms is Docker, which is widely used in software development and deployment. Containerization, particularly with open-source technologies like Docker and container orchestration systems like Kubernetes, is a common approach for deploying and managing applications. Containers are created from images, which are lightweight, standalone, and executable packages that include application code, libraries, dependencies, and runtime. Images are often built from a Dockerfile or similar, which contains instructions for assembling the image. Dockerfiles are configuration files that specify how to build a Docker image. Systems like Kubernetes also support containerd or CRI-O. They include commands for installing dependencies, copying files, setting environment variables, and defining runtime configurations. Docker images are stored in repositories, which can be public or private. Docker Hub is an exemplary public registry, and organizations often set up private registries for security and version control using tools such as Hub, JFrog Artifactory and Bintray, Github Packages or Container registries. Containers can communicate with each other and the external world through networking. Docker provides a bridge network by default, but can be used with custom networks. Containers within the same network can communicate using container names or IP addresses.

Remote computing devices 80 are any computing devices not part of computing device 10. Remote computing devices 80 include, but are not limited to, personal computers, server computers, thin clients, thick clients, personal digital assistants (PDAs), mobile telephones, watches, tablet computers, laptop computers, multiprocessor systems, microprocessor based systems, set-top boxes, programmable consumer electronics, video game machines, game consoles, portable or handheld gaming units, network terminals, desktop personal computers (PCs), minicomputers, main frame computers, network nodes, virtual reality or augmented reality devices and wearables, and distributed or multi-processing computing environments. While remote computing devices 80 are shown for clarity as being separate from cloud-based services 90, cloud-based services 90 are implemented on collections of networked remote computing devices 80.

Cloud-based services 90 are Internet-accessible services implemented on collections of networked remote computing devices 80. Cloud-based services are typically accessed via application programming interfaces (APIs) which are software interfaces which provide access to computing services within the cloud-based service via API calls, which are pre-defined protocols for requesting a computing service and receiving the results of that computing service. While cloud-based services may comprise any type of computer processing or storage, three common categories of cloud-based services 90 are microservices 91, cloud computing services 92, and distributed computing services 93.

Microservices 91 are collections of small, loosely coupled, and independently deployable computing services. Each microservice represents a specific computing functionality and runs as a separate process or container. Microservices promote the decomposition of complex applications into smaller, manageable services that can be developed, deployed, and scaled independently. These services communicate with each other through well-defined application programming interfaces (APIs), typically using lightweight protocols like HTTP, gRPC, or message queues such as Kafka. Microservices 91 can be combined to perform more complex processing tasks.

Cloud computing services 92 are delivery of computing resources and services over the Internet 75 from a remote location. Cloud computing services 92 provide additional computer hardware and storage on as-needed or subscription basis. Cloud computing services 92 can provide large amounts of scalable data storage, access to sophisticated software and powerful server-based processing, or entire computing infrastructures and platforms. For example, cloud computing services can provide virtualized computing resources such as virtual machines, storage, and networks, platforms for developing, running, and managing applications without the complexity of infrastructure management, and complete software applications over the Internet on a subscription basis.

Distributed computing services 93 provide large-scale processing using multiple interconnected computers or nodes to solve computational problems or perform tasks collectively. In distributed computing, the processing and storage capabilities of multiple machines are leveraged to work together as a unified system. Distributed computing services are designed to address problems that cannot be efficiently solved by a single computer or that require large-scale computational power. These services enable parallel processing, fault tolerance, and scalability by distributing tasks across multiple nodes.

Although described above as a physical device, computing device 10 can be a virtual computing device, in which case the functionality of the physical components herein described, such as processors 20, system memory 30, network interfaces 40, and other like components can be provided by computer-executable instructions. Such computer-executable instructions can execute on a single physical computing device, or can be distributed across multiple physical computing devices, including being distributed across multiple physical computing devices in a dynamic manner such that the specific, physical computing devices hosting such computer-executable instructions can dynamically change over time depending upon need and availability. In the situation where computing device 10 is a virtualized device, the underlying physical computing devices hosting such a virtualized computing device can, themselves, comprise physical components analogous to those described above, and operating in a like manner. Furthermore, virtual computing devices can be utilized in multiple layers with one virtual computing device executing within the construct of another virtual computing device. Thus, computing device 10 may be either a physical computing device or a virtualized computing device within which computer-executable instructions can be executed in a manner consistent with their execution by a physical computing device. Similarly, terms referring to physical components of the computing device, as utilized herein, mean either those physical components or virtualizations thereof performing the same or equivalent functions.

The skilled person will be aware of a range of possible modifications of the various aspects described above. Accordingly, the present invention is defined by the claims and their equivalents.

What is claimed is:

1. A computing system for enhanced finite element analysis using novel geometries employing an advanced materials design platform, the computing system comprising:
one or more hardware processors configured for:
generating and manipulating novel geometric shapes, the novel shapes comprising at least bodies of constant width;
performing multi-physics simulations using the novel geometric shapes;
optimizing material designs incorporating the novel geometric shapes;
adaptively refining one or more simulation meshes based on the novel geometric shapes; and
integrating the novel geometric shapes into material design processes to enhance performance and efficiency.

2. The computing system of claim 1, wherein the one or more hardware processors are further configured for:
implementing custom tessellation algorithms for bodies of constant width;
adaptively refining meshes based on view distance and curvature of the novel geometric shapes; and
preserving geometric features of the novel shapes while optimizing element quality in mesh generation.

3. The computing system of claim 1, wherein the one or more hardware processors are further configured for:
implementing multi-scale modeling using the novel geometric shapes from atomic to macroscopic scales;
transitioning between atomic-scale representations and continuum-level visualizations; and
simulating quantum confinement effects using the novel geometric shapes in semiconductor device modeling.

4. The computing system of claim 1, wherein the one or more hardware processors are further configured for:
applying reinforcement learning algorithms to optimize designs incorporating the novel geometric shapes;
using Monte Carlo tree search and upper confidence bounds for exploring design spaces with novel geometries; and
balancing multiple objectives comprising performance, cost, and manufacturability in the context of designs using novel geometric shapes.

5. The computing system of claim 1, wherein the one or more hardware processors are further configured for:
representing relationships between novel geometric shapes and material properties in a knowledge graph;
inferring new material properties based on similarities in geometric structures; and
facilitating reasoning about material design using the novel shapes across multiple domains of materials science.

6. A computer-implemented method executed on an advanced materials design platform for enhanced finite element analysis using novel geometries, the computer-implemented method comprising:
generating and manipulating novel geometric shapes, the novel shapes comprising at least bodies of constant width;
performing multi-physics simulations using the novel geometric shapes;
optimizing material designs incorporating the novel geometric shapes;
adaptively refining one or more simulation meshes based on the novel geometric shapes; and
integrating the novel geometric shapes into material design processes to enhance performance and efficiency.

7. The computer-implemented method of claim 6, further comprising:
implementing custom tessellation algorithms for bodies of constant width;
adaptively refining meshes based on view distance and curvature of the novel geometric shapes; and
preserving geometric features of the novel shapes while optimizing element quality in mesh generation.

8. The computer-implemented method of claim 6, further comprising:
implementing multi-scale modeling using the novel geometric shapes from atomic to macroscopic scales;
transitioning between atomic-scale representations and continuum-level visualizations; and
simulating quantum confinement effects using the novel geometric shapes in semiconductor device modeling.

9. The computer-implemented method of claim 6, further comprising:
applying reinforcement learning algorithms to optimize designs incorporating the novel geometric shapes;
using Monte Carlo tree search and upper confidence bounds for exploring design spaces with novel geometries; and
balancing multiple objectives comprising performance, cost, and manufacturability in the context of designs using novel geometric shapes.

10. The computer-implemented method of claim 6, further comprising:
representing relationships between novel geometric shapes and material properties in a knowledge graph;
inferring new material properties based on similarities in geometric structures; and
facilitating reasoning about material design using the novel shapes across multiple domains of materials science.

11. A system for enhanced finite element analysis using novel geometries employing an advanced materials design platform, comprising one or more computers with executable instructions that, when executed, cause the system to:
generate and manipulate novel geometric shapes, the novel shapes comprising at least bodies of constant width;
perform multi-physics simulations using the novel geometric shapes;
optimize material designs incorporating the novel geometric shapes;
adaptively refine one or more simulation meshes based on the novel geometric shapes; and
integrate the novel geometric shapes into material design processes to enhance performance and efficiency.

12. The system of claim 11, wherein the system is further caused to:
implement custom tessellation algorithms for bodies of constant width;
adaptively refine meshes based on view distance and curvature of the novel geometric shapes; and
preserve geometric features of the novel shapes while optimizing element quality in mesh generation.

13. The system of claim 11, wherein the system is further caused to:
implement multi-scale modeling using the novel geometric shapes from atomic to macroscopic scales;
transition between atomic-scale representations and continuum-level visualizations; and
simulate quantum confinement effects using the novel geometric shapes in semiconductor device modeling.

14. The system of claim 11, wherein the system is further caused to:
apply reinforcement learning algorithms to optimize designs incorporating the novel geometric shapes;
use Monte Carlo tree search and upper confidence bounds for exploring design spaces with novel geometries; and
balance multiple objectives comprising performance, cost, and manufacturability in the context of designs using novel geometric shapes.

15. The system of claim 11, wherein the system is further caused to:
represent relationships between novel geometric shapes and material properties in a knowledge graph;
infer new material properties based on similarities in geometric structures; and
facilitate reasoning about material design using the novel shapes across multiple domains of materials science.

16. Non-transitory, computer-readable storage media having computer-executable instructions embodied thereon that, when executed by one or more processors of a computing system employing an advanced materials design platform for enhanced finite element analysis using novel geometries, cause the computing system to:
generate and manipulate novel geometric shapes, the novel shapes comprising at least bodies of constant width;
perform multi-physics simulations using the novel geometric shapes;
optimize material designs incorporating the novel geometric shapes;
adaptively refine one or more simulation meshes based on the novel geometric shapes; and
integrate the novel geometric shapes into material design processes to enhance performance and efficiency.

17. The non-transitory, computer-readable storage media of claim 16, wherein the computing system is further caused to:
implement custom tessellation algorithms for bodies of constant width;
adaptively refine meshes based on view distance and curvature of the novel geometric shapes; and
preserve geometric features of the novel shapes while optimizing element quality in mesh generation.

18. The non-transitory, computer-readable storage media of claim 16, wherein the computing system is further caused to:
implement multi-scale modeling using the novel geometric shapes from atomic to macroscopic scales;
transition between atomic-scale representations and continuum-level visualizations; and
simulate quantum confinement effects using the novel geometric shapes in semiconductor device modeling.

19. The non-transitory, computer-readable storage media of claim 16, wherein the computing system is further caused to:
apply reinforcement learning algorithms to optimize designs incorporating the novel geometric shapes;
use Monte Carlo tree search and upper confidence bounds for exploring design spaces with novel geometries; and
balance multiple objectives comprising performance, cost, and manufacturability in the context of designs using novel geometric shapes.

20. The non-transitory, computer-readable storage media of claim 16, wherein the computing system is further caused to:
represent relationships between novel geometric shapes and material properties in a knowledge graph;
infer new material properties based on similarities in geometric structures; and
facilitate reasoning about material design using the novel shapes across multiple domains of materials science.
